(19) United States
(12) Patent Application Publication
(10) Pub. No.: US 2006/0022289 A1
(43) Pub. Date: Feb. 2, 2006

(54) Electro-optical circuitry having integrated connector and methods for the production thereof

(75) Inventors: Avner Badhei, Mobile Post Harei Yehuda (IL); Sylvie Rockman, Zichron Ya'akov (IL)

Correspondence Address: DARBY & DARBY P.C., P. O. BOX 5257, NEW YORK, NY, 10150-5257, US

(73) Assignee: XLOOM Photonics, Ltd., Tel Aviv (IL)

(21) Appl. No.: 10/510,263

(22) PCT Filed:
(86) PCT No.: PCT/IL03/00308

Related U.S. Application Data
(63) Continuation-in-part of application No. 10/314,088, filed on Dec. 6, 2002.
(60) Provisional application No. 60/373,415, filed on Apr. 16, 2002.
(60) Provisional application No. 60/442,948, filed on Jan. 27, 2003.

(51) Int. Cl. H01L 31/0232; H01L 21/00

(52) U.S. Cl. 257/432; 438/65

(57) ABSTRACT

An electro-optic integrated circuit including an integrated circuit substrate, at least one optical signal providing element and at least one discrete reflecting optical element, mounted onto the integrated circuit substrate, cooperating with the at least one optical signal providing element and being operative to direct light from the at least one optical signal providing element. An electro-optic integrated circuit including an integrated circuit substrate, at least one optical signal receiving element and at least one discrete reflecting optical element, mounted onto the integrated circuit substrate, cooperating with the at least one optical signal receiving element and being operative to direct light to the at least one optical signal receiving element.

### REFERENCE TO CO-PENDING APPLICATIONS

Applicant hereby claims priority of U.S. Provisional Patent Application Ser. No. 60/373,415, filed on Apr. 16, 2002, entitled “Electro-Optic Integrated Circuits and Methods for the Production Thereof”, U.S. patent application Ser. No. 10/314,088, filed Dec. 6, 2002, entitled “Electro-Optic Integrated Circuits with Connectors and Methods for the Production Thereof” and U.S. Provisional Patent Application Ser. No. 60/442,948, filed on Jan. 27, 2003, entitled “Direct Optical Connection”.

### FIELD OF THE INVENTION

The present invention relates to high speed integrated circuits interconnection, electro-optic integrated circuits and methods for the production thereof generally and more particularly to wafer level manufacture of chip level electro-optic integrated circuits with integrated optical connectors and optical interconnections means to transfer data between semiconductor integrated circuits.

### BACKGROUND OF THE INVENTION

The following U.S. patents of the present inventor represent the current state of the art:

U.S. Pat. Nos. 6,117,707; 6,040,235; 6,022,758; 5,980,663; 5,716,759; 5,547,906 and 5,455,455.

The following U.S. patents represent the current state of the art relevant to stud bump mounting of electrical circuits:

U.S. Pat. Nos. 6,214,642; 6,103,551; 5,844,320; 5,641,996; 5,550,408 and 5,436,503.

Additionally, the following patents are believed to represent the current state of the art:

U.S. Pat. Nos. 4,168,883; 4,351,051; 4,386,821; 4,399,541; 4,615,031; 4,810,053; 4,988,159; 4,989,930; 4,989,943; 5,044,720; 5,231,686; 5,841,591; 6,052,498; 6,058,228; 6,234,688; 5,886,971; 5,912,872; 5,933,551; 6,061,169; 6,071,652; 6,096,155; 6,104,690; 6,235,141; 6,295,156; 5,771,218 and 5,872,762.

### SUMMARY OF THE INVENTION

The present invention seeks to provide improved optical interconnections means to transfer high speed data between semiconductor integrated circuits, electro-optic integrated circuits and methods for production thereof.

There is thus provided, in accordance with a preferred embodiment of the present invention, an electro-optic integrated circuit including an integrated circuit substrate, at least one optical signal providing element and at least one discrete reflecting optical element, mounted onto the integrated circuit substrate, cooperating with the at least one optical signal providing element and being operative to direct light from the at least one optical signal providing element.

There is also provided, in accordance with another preferred embodiment of the present invention, an electro-optic integrated circuit including an integrated circuit substrate, at least one optical signal receiving element and at least one discrete reflecting optical element mounted onto the integrated circuit substrate and cooperating with the at least one optical signal receiving element and being operative to direct light to the at least one optical signal receiving element.

There is further provided, in accordance with yet another preferred embodiment of the present invention, an electro-optic integrated circuit including an integrated circuit substrate defining a planar surface, at least one optical signal providing element and at least one reflecting optical element having an optical axis which is neither parallel nor perpendicular to the planar surface, the element cooperating with the at least one optical signal providing element and being operative to direct light from the at least one optical signal providing element.

There is also provided, in accordance with still another preferred embodiment of the present invention, an electro-optic integrated circuit including an integrated circuit substrate defining a planar surface, at least one optical signal receiving element and at least one reflecting optical element having an optical axis which is neither parallel nor perpendicular to the planar surface, the element cooperating with the at least one optical signal receiving element and being operative to direct light to the at least one optical signal receiving element.

There is further provided, in accordance with another preferred embodiment of the present invention, a method for producing an electro-optic integrated circuit including providing an integrated circuit substrate, mounting at least one optical signal providing element onto the integrated circuit substrate, mounting at least one optical signal receiving element onto the integrated circuit substrate and providing optical alignment, between the at least one optical signal providing element and the at least one optical signal receiving element, subsequent to mounting thereof, by suitable positioning along an optical path extending there between, an intermediate optical element and fixing the intermediate optical element to the integrated circuit substrate.

In accordance with a further preferred embodiment of the present invention, the intermediate optical element, when fixed to the substrate, has an optical axis, which is neither parallel nor perpendicular to a planar surface of the integrated circuit substrate.

There is also provided, in accordance with yet another preferred embodiment of the present invention, a method for producing an electro-optic integrated circuit including providing an integrated circuit substrate, mounting at least one optical signal providing element on the integrated circuit substrate and mounting at least one discrete reflecting optical element onto the integrated circuit substrate to cooperate with the at least one optical signal providing element and to direct light from the at least one optical signal providing element.

There is further provided, in accordance with still another preferred embodiment of the present invention, a method for producing an electro-optic integrated circuit including providing an integrated circuit substrate, mounting at least one optical signal receiving element on the integrated circuit substrate and mounting at least one discrete reflecting optical element onto the integrated circuit substrate to cooperate with the at least one optical signal receiving element and to direct light to the at least one optical signal receiving element.

There is also provided, in accordance with another preferred embodiment of the present invention, a method for producing an electro-optic integrated circuit including providing an integrated circuit substrate defining a planar surface, mounting at least one optical signal providing element on the integrated circuit substrate and mounting at least one reflecting optical element onto the integrated circuit substrate to cooperate with the at least one optical signal providing element and to direct light from the at least one optical signal providing element, wherein an optical axis of the at least one reflecting optical element is neither parallel nor perpendicular to the planar surface.

There is further provided, in accordance with yet another preferred embodiment of the present invention, a method for producing an electro-optic integrated circuit including providing an integrated circuit substrate defining a planar surface, mounting at least one optical signal receiving element on the integrated circuit substrate and mounting at least one reflecting optical element onto the integrated circuit substrate to cooperate with the at least one optical signal receiving element and to direct light to the at least one optical signal receiving element, wherein an optical axis of the at least one reflecting optical element is neither parallel nor perpendicular to the planar surface.

In accordance with a preferred embodiment of the present invention, the at least one optical element includes a flat reflective surface. Additionally, the at least one optical element includes a concave mirror. Alternatively, the at least one optical element includes a partially flat and partially concave mirror. Additionally, the partially concave mirror includes a mirror with multiple concave reflective surfaces.

In accordance with another preferred embodiment, the at least one optical element includes a reflective grating. Additionally, the at least one optical element includes reflective elements formed on opposite surfaces of an optical substrate. Preferably, at least one of the reflective elements includes a flat reflective surface. Alternatively, at least one of the reflective elements includes a concave mirror. Alternatively or additionally, at least one of the reflective elements includes a partially flat and partially concave mirror. Additionally, the mirror includes a mirror with multiple concave reflective surfaces. Alternatively, at least one of the reflective elements includes a reflective grating.

Preferably, the at least one optical element is operative to focus light received from the optical signal providing element. Alternatively, the at least one optical element is operative to collimate light received from the optical signal providing element. In accordance with another preferred embodiment, the at least one optical element is operative to focus at least one of multiple colors of light received from the optical signal providing element. Additionally or alternatively, the at least one optical element is operative to collimate at least one of multiple colors of light received from the optical signal providing element. In accordance with another preferred embodiment, the at least one optical element is operative to enhance the optical properties of light received from the optical signal providing element.

In accordance with a preferred embodiment, the optical signal-providing element includes an optical fiber. Alternatively, the optical signal-providing element includes a laser diode. Additionally or alternatively, the optical signal-providing element includes a waveguide. In accordance with another preferred embodiment, the optical signal-providing element includes an array waveguide grating. Alternatively, the optical signal-providing element includes a semiconductor optical amplifier.

Preferably, the optical signal-providing element is operative to convert an electrical signal to an optical signal. Alternatively, the optical signal-providing element is operative to transmit an optical signal. Additionally, the optical signal-providing element also includes an optical signal-receiving element. In accordance with another preferred embodiment, the optical signal-providing element is operative to generate an optical signal.

In accordance with a preferred embodiment of the present invention, the integrated circuit substrate includes Silicon, Silicon Germanium, and gallium arsenide. Alternatively, the integrated circuit substrate includes indium phosphide.

In accordance with another preferred embodiment of the present invention, the integrated circuit includes at least one optical signal providing element and at least one optical element receiving element, the at least one discrete reflecting optical element cooperating with the at least one optical signal providing element and the at least one optical signal receiving element and being operative to direct light from the at least one signal providing element to the at least one optical signal receiving element.

Preferably, the at least one optical signal receiving element includes an optical fiber. Alternatively, the at least one optical signal receiving element includes a laser diode. Additionally or alternatively, the at least one optical signal receiving element includes a diode detector.

In accordance with a preferred embodiment of the present invention, the at least one optical signal receiving element is operative to convert an optical signal to an electrical signal. Additionally, the at least one optical signal receiving element is operative to transmit an optical signal. Alternatively, the at least one optical signal receiving element also includes an optical signal providing element.

Preferably, the at least one reflecting optical element is operative to focus light received by the optical signal-receiving element. Alternatively, the at least one reflecting optical element is operative to collimate light received by the optical signal-receiving element. In accordance with another preferred embodiment, the at least one reflecting optical element is operative to focus at least one of multiple colors of light received by the optical signal-receiving element. Additionally or alternatively, the at least one reflecting optical element is operative to collimate at least one of multiple colors of light received by the optical signal receiving element. In accordance with another preferred embodiment, the at least one reflecting optical element is operative to enhance the optical properties of light received by the optical signal-receiving element.

There is also provided, in accordance with another preferred embodiment of the present invention, an integrated circuit including a first integrated circuit substrate having first and second planar surfaces, the first planar surface having first electrical circuitry formed thereon and the second planar surface having formed therein at least one recess, filling the recess with clear material to form an optical via through the semiconductor substrate, and at least one second integrated circuit substrate having second electrical circuitry formed thereon, the at least one second integrated circuit substrate being located at least partially above the at least one recess, the second electrical circuitry communicating with the first electrical circuitry.

There is also provided, in accordance with another preferred embodiment of the present invention, an integrated circuit including a first integrated circuit substrate having first and second planar surfaces, the first planar surface having first electrical circuitry formed thereon and the second planar surface having formed therein at least one recess, filling the recess with clear material to form an optical via through the semiconductor substrate, and at least one second integrated circuit substrate having second electrical circuitry formed thereon, the at least one second integrated circuit substrate being located at least partially above the at least one recess, the second electrical circuitry communicating with the first electrical circuitry.

Preferably, the first electrical circuitry includes electronic components and optical waveguides. Additionally, the second electrical circuitry includes electro-optic components. In accordance with a preferred embodiment, the second electrical circuitry communicating with the first electrical circuitry optical waveguides includes communicating via an optical communication path. Additionally, the optical communication path includes optical coupling through free space.

There is also provided, in accordance with still another preferred embodiment of the present invention, an integrated circuit including a first integrated circuit substrate having first and second planar surfaces, the first planar surface having first electrical circuitry formed thereon and the second planar surface having formed therein at least one recess and at least one second substrate, the at least one second substrate being located at least partially above the at least one recess, the second substrate containing at least one element communicating with the first electrical circuitry.

There is further provided, in accordance with another preferred embodiment, an integrated circuit including a first integrated circuit substrate, having electrical circuitry formed thereon and having formed therein at least one recess and at least one second substrate, the at least one second substrate being located at least partially above the at least one recess, the second substrate containing at least one element communicating with the electrical circuitry.

There is also provided, in accordance with yet another preferred embodiment, a method for producing an integrated circuit including providing a first integrated circuit substrate, with first and second planar surfaces, forming first electrical circuitry on the first planar surface, forming at least one recess in the second planar surface, providing at least one second substrate and locating the at least one second substrate at least partially above the at least one recess, the second substrate containing at least one element communicating with the first electrical circuitry.

There is further provided, in accordance with still another preferred embodiment, a method for producing an integrated circuit including providing a first integrated circuit substrate, forming electrical circuitry on the first substrate, forming at least one recess in the first substrate, providing at least one second substrate and locating the at least one second substrate at least partially above the at least one recess, the second substrate containing at least one element communicating with the electrical circuitry.

In accordance with a preferred embodiment, the first electrical circuitry includes electronic components. Additionally, the at least one element includes electro-optic components. Preferably, the at least one element communicating with the first electrical circuitry includes communicating via an optical communication path. Additionally, the optical communication path includes optical coupling through free space.

There is yet further provided, in accordance with another preferred embodiment of the present invention, an integrated circuit including a silicon integrated circuit substrate having electrical signal processing circuitry formed thereon and at least one discrete optical element mounted thereon, the electrical signal processing circuitry including an electrical signal input and an electrical signal output and the at least one discrete optical element including an optical input and an optical output.

There is also provided, in accordance with yet another preferred embodiment of the present invention, a method for producing an integrated circuit including providing a silicon integrated circuit substrate, forming electrical signal processing circuitry on the substrate and mounting at least one discrete optical element on the substrate, the electrical signal processing circuitry including an electrical signal input and an electrical signal output and the at least one discrete optical element including an optical input and an optical output.

Preferably, the optical element is operative to convert the electrical signal output into the optical input. Alternatively, the electrical signal processing circuitry is operative to convert the optical output into the electrical signal input. In accordance with another preferred embodiment, the electrical signal processing circuitry and the discrete optical element are located on a single planar surface of the substrate. Alternatively, the electrical signal processing circuitry and the discrete optical element are located on different planar surfaces of the substrate.

There is yet further provided, in accordance with another preferred embodiment of the present invention, an integrated circuit including a silicon integrated circuit substrate having electrical signal processing circuitry formed thereon and at least one discrete optical element mounted thereon, the electrical signal processing circuitry including an electrical signal input and an electrical signal output and the at least one discrete optical element including an optical input and an optical output, the integrated circuit including at least one optical connector including a plurality of optical elements defining at least one optical input path and at least one optical output path.

There is further provided in accordance with another preferred embodiment of the present invention, a method for producing an integrated circuit including a silicon integrated circuit substrate having electrical signal processing circuitry formed thereon and at least one discrete optical element mounted thereon, the electrical signal processing circuitry including an electrical signal input and an electrical signal output and the at least one discrete optical element including an optical input and an optical output, the integrated circuit also including at least one optical connector including a plurality of optical elements defining at least one optical input path and at least one optical output path an optical connector including providing a plurality of optical elements, defining at least one optical input path through at least one of the plurality of optical elements and defining at least one optical output path through at least one of the plurality of optical elements.

Preferably, at least one of the plurality of optical elements includes a flat reflective surface. Additionally, at least one of the plurality of optical elements includes a concave mirror. Additionally or alternatively, at least one of the plurality of optical elements includes a partially flat and partially concave mirror. Alternatively, at least one of the plurality of optical elements includes a mirror with multiple concave reflective surfaces. Additionally or alternatively, at least one of the plurality of optical elements includes a reflective grating. Additionally, at least one of the plurality of optical elements includes reflective elements formed on opposite surfaces of an optical substrate.

In accordance with a preferred embodiment, at least one of the plurality of optical elements is operative to focus light. Alternatively, at least one of the plurality of optical elements is operative to collimate light. Additionally, at least one of the plurality of optical elements is operative to focus at least one of multiple colors of light. Additionally or alternatively, at least one of the plurality of optical elements is operative to collimate at least one of multiple colors of light. Alternatively, at least one of the plurality of optical elements is operative to enhance the optical properties of light.

Preferably, at least one of the plurality of optical elements includes an optical fiber. Additionally, at least one of the plurality of optical elements includes a laser diode. Alternatively, at least one of the plurality of optical elements includes a diode detector.

There is further provided in accordance with still another preferred embodiment of the present invention an optical reflector including an optical substrate, at least one microlens formed on a surface of the optical substrate and a first reflective surface formed over the at least one microlens.

There is still further provided in accordance with yet another preferred embodiment of the present invention a method for producing an optical reflector including providing an optical substrate, forming at least one microlens on a surface of the optical substrate, coating the at least one microlens with a reflective material and dicing the substrate.

Preferably, the first reflective surface is also formed over at least a portion of the surface of the optical substrate. Alternatively, at least a portion of the first reflective surface includes a grating. Preferably, the first reflective surface includes aluminum.

In accordance with another preferred embodiment, the optical reflector also includes at least one second reflective surface formed on at least a portion of an opposite surface of the substrate. Additionally, at least a portion of the second reflective surface includes a grating. Preferably, the second reflective surface includes aluminum.

In accordance with yet another preferred embodiment, the optical reflector also includes a notch formed in the opposite surface of the substrate.

Preferably, the at least one microlens includes photoresist. Alternatively, the at least one microlens is formed by photolithography and thermal reflow forming. Additionally, the at least one microlens is formed by photolithography using a grey scale mask forming. Alternatively, the at least one microlens is formed by jet printing formation.

In accordance with still another preferred embodiment, the at least one microlens has an index of refraction which is identical to that of the optical substrate. Alternatively, the at least one microlens has an index of refraction which closely approximates that of the optical substrate.

There is also provided in accordance with another preferred embodiment of the present invention a packaged electro-optical integrated circuit having integrally formed therein an optical connector to an optical fiber.

Preferably, the optical connector includes a pair of elongate locating pin sockets formed over a silicon substrate of the integrated circuit, and extending generally parallel to a surface thereof. Additionally, the optical connector includes a linear array of optical fiber ends arranged to have abutment surfaces generally coplanar with an edge of the packaged electro-optical integrated circuit.

There is further provided in accordance with yet another preferred embodiment of the present invention a method for wafer scale production of an electro-optic circuit having integrally formed therein an optical connector and electrical connections including wafer scale formation of a multiplicity of electro-optical circuits onto a substrate, wafer scale provision of at least one optical waveguide on the substrate, wafer scale mounting of at least one integrated circuit component onto the substrate, wafer scale formation of at least one optical pathway providing an optical connection between the at least one integrated circuit component and the at least one optical waveguide, wafer scale formation of at least one mechanical alignment bore on the substrate, wafer scale formation of at least one packaging layer over at least one surface of the substrate and thereafter, dicing of the substrate to define a multiplicity of electro-optic circuits, each having integrally formed therein an optical connector.

Preferably, an end of the at least one optical waveguide defines an optical connector interface. Additionally, the substrate includes a silicon substrate having formed thereon a multiplicity of integrated circuits.

There is still further provided in accordance with still another preferred embodiment of the present invention a method of mounting an integrated circuit onto an electrical circuit including forming an integrated circuit with a multiplicity of electrical connection pads which generally lie along a mounting surface of the integrated circuit, forming an electrical circuit with a multiplicity of electrical connection contacts which generally protrude from a mounting surface of the electrical circuit and employing at least a conductive adhesive to electrically and mechanically join the multiplicity of electrical connection pads to the multiplicity of electrical connection contacts.

Preferably, the integrated circuit is an electro-optical circuit, and the method also includes providing an optically transparent underfill layer intermediate the mounting surface of the integrated circuit and the mounting surface of the electrical circuit.

There is also provided in accordance with another preferred embodiment of the present invention a method for wafer scale production of an electro-optical circuit including wafer scale formation of a multiplicity of electro-optical circuits onto an active surface of a substrate and wafer scale provision of at least one optical via on the substrate.

Preferably, the wafer scale provision of the at least one optical via includes etching the substrate on a non-active surface thereof at a location opposite a region of the active surface generally free of circuitry, thereby to define at least one cavity whose bottom surface is translucent and filling the at least one cavity with a transparent material.

Additionally, the method also includes attaching a semiconductor element in optical engagement with the at least one optical via.

In accordance with yet another preferred embodiment of the present invention the transparent material has an index of refraction similar to that employed along at least one optical path in the electro-optical circuit communicating therewith.

There is further provided in accordance with still another preferred embodiment of the present invention a method for wafer level production of a electro-optical circuit including forming electrical circuitry on a first side of a wafer, forming an optical assembly on a second side of the wafer and forming an optical connection between the first and second sides of the wafer, through the wafer, thereby providing optical communication between the electrical circuitry and the optical assembly through the wafer.

Preferably, the method also includes dicing the wafer to define a multiplicity of integrated circuits each having formed thereon electrical circuitry on a first side of the integrated circuit, an optical assembly on a second side of the integrated circuit and an optical connection between the first and second sides of the integrated circuit, thereby providing optical communication between the electrical circuitry and the optical assembly.

### BRIEF DESCRIPTION OF THE DRAWINGS

The present invention will be appreciated more fully from the following detailed description, taken in conjunction with the drawings in which:

FIGS. 1A, 1B, 1C, 1D and 1E are simplified pictorial illustrations of initial stages in the production of an electro-optic integrated circuit constructed and operative in accordance with a preferred embodiment of the present invention;

FIGS. 2A, 2B, 2C, and 2D are simplified sectional illustrations of further stages in the production of the electro-optic integrated circuit referenced in FIGS. 1A-1E;

FIG. 3 is an enlarged simplified optical illustration of a portion of FIG. 2D;

FIGS. 4A, 4B, 4C, 4D and 4E are simplified pictorial illustrations of initial stages in the production of an electro-optic integrated circuit constructed and operative in accordance with another preferred embodiment of the present invention;

FIGS. 5A, 5B, 5C and 5D are simplified sectional illustrations of further stages in the production of the electro-optic integrated circuit referenced in FIGS. 4A-4E;

FIGS. 6A, 6B and 6C are enlarged simplified optical illustrations of a portion of FIG. 5D in accordance with preferred embodiments of the present invention;

FIG. 7 is a simplified sectional illustration of an electro-optic integrated circuit constructed and operative in accordance with yet another preferred embodiment of the present invention;

FIGS. 8A, 8B and 8C are enlarged simplified optical illustrations of a portion of FIG. 7 in accordance with other embodiments of the present invention;

FIGS. 9A, 9B, 9C, 9D and 9E are simplified pictorial illustrations of initial stages in the production of an electro-optic integrated circuit constructed and operative in accordance with yet another preferred embodiment of the present invention;

FIGS. 10A, 10B, 10C and 10D are simplified sectional illustrations of further stages in the production of the electro-optic integrated circuit referenced in FIGS. 9A-9E;

FIGS. 11A, 11B and 11C are enlarged simplified optical illustrations of a portion of FIG. 10D in accordance with preferred embodiments of the present invention;

FIG. 12 is a simplified sectional illustration of an electro-optic integrated circuit constructed and operative in accordance with yet another preferred embodiment of the present invention;

FIGS. 13A, 13B and 13C are enlarged simplified optical illustrations of a portion of FIG. 12 in accordance with further preferred embodiments of the present invention;

FIGS. 14A, 14B, 14C and 14D are simplified sectional illustrations of stages in the production an electro-optic integrated circuit in accordance with another embodiment of the present invention;

FIGS. 15A, 15B and 15C are simplified optical illustrations of FIG. 14D in accordance with preferred embodiments of the present invention;

FIG. 16 is a simplified sectional illustration of an electro-optic integrated circuit constructed and operative in accordance with yet another preferred embodiment of the present invention;

FIGS. 17A, 17B and 17C are enlarged simplified optical illustrations of a portion of FIG. 16 in accordance with further embodiments of the present invention;

FIGS. 18A, 18B, 18C and 18D are simplified illustrations of a method for fabricating optical elements employed in the embodiments of FIGS. 4A-6C in accordance with one embodiment of the present invention;

FIGS. 19A, 19B, 19C, 19D and 19E are simplified illustrations of a method for fabricating optical elements employed in the embodiments of FIGS. 1A-6C in accordance with another embodiment of the present invention;

FIGS. 20A, 20B, 20C, 20D, 20E and 20F are simplified illustrations of a method for fabricating optical elements employed in the embodiments of FIGS. 9A-17C in accordance with yet another embodiment of the present invention;

FIGS. 21A, 21B, 21C, 21D, 21E and 21F are simplified illustrations of a method for fabricating optical elements employed in the embodiments of FIGS. 1A-17C in accordance with still another embodiment of the present invention;

FIGS. 22A, 22B, 22C, 22D, 22E, 22F and 22G are simplified illustrations of a method for fabricating optical elements employed in the embodiments of FIGS. 1A-8C in accordance with a further embodiment of the present invention;

FIGS. 23A, 23B, 23C, 23D, 23E, 23F and 23G are simplified illustrations of a method for fabricating optical elements employed in the embodiments of FIGS. 9A-17C in accordance with yet a further embodiment of the present invention;

FIGS. 24A, 24B, 24C, 24D, 24E, 24F and 24G are simplified illustrations of a method for fabricating optical elements employed in the embodiments of FIGS. 1A-17C in accordance with a still further embodiment of the present invention;

FIGS. 25A, 25B, 25C and 25D are simplified illustrations of multiple stages in the production of a multi-chip module in accordance with a preferred embodiment of the present invention;

FIG. 26 is a simplified illustration of a multi-chip module of the type referenced in FIGS. 25A-25D, including a laser light source;

FIG. 27 is a simplified illustration of a multi-chip module of the type referenced in FIGS. 25A-25D, including an optical detector;

FIG. 28 is a simplified illustration of a multi-chip module of the type referenced in FIGS. 25A-25D, including an electrical element;

FIG. 29 is a simplified illustration of a multi-chip module of the type referenced in FIGS. 25A-25D, including multiple elements located in multiple recesses formed within a substrate;

FIG. 30 is a simplified illustration of a multi-chip module of the type referenced in FIGS. 25A-25D, including multiple stacked elements located in recesses formed within substrates;

FIGS. 31A, 31B, 31C and 31D are simplified sectional illustrations of stages in the production of an electro-optic integrated assembly in accordance with a preferred embodiment of the present invention;

FIG. 32 is an enlarged simplified optical illustration of a portion of FIG. 31D;

FIGS. 33A, 33B, 33C and 33D are simplified sectional illustrations of stages in the production of an electro-optic integrated assembly in accordance with another preferred embodiment of the present invention;

FIG. 34 is an enlarged simplified optical illustration of a portion of FIG. 33D;

FIGS. 35A, 35B, 35C and 35D are simplified sectional illustrations of stages in the production of an electro-optic integrated assembly in accordance with a preferred embodiment of the present invention;

FIG. 36 is an enlarged simplified optical illustration of a portion of FIG. 35D;

FIGS. 37A, 37B, 37C and 37D are simplified sectional illustrations of stages in the production of an electro-optic integrated assembly in accordance with another preferred embodiment of the present invention;

FIG. 38 is an enlarged simplified optical illustration of a portion of FIG. 37D;

FIGS. 39A, 39B, 39C and 39D are simplified sectional illustrations of stages in the production of an electro-optic integrated assembly in accordance with yet another preferred embodiment of the present invention;

FIG. 40 is a simplified optical illustration of FIG. 39D;

FIGS. 41A, 41B, 41C and 41D are simplified sectional illustrations of stages in the production of an electro-optic integrated assembly in accordance with still another preferred embodiment of the present invention;

FIG. 42 is a simplified optical illustration of FIG. 41D;

FIG. 43 is a simplified optical illustration of optical communication between connectors of the types shown in FIGS. 40 and 42;

FIG. 44 is a simplified optical illustration of optical communication between two connectors of the type shown in FIG. 40;

FIG. 45 is a simplified optical illustration of optical communication between two connectors of the type shown in FIG. 42;

FIGS. 46A, 46B, 46C and 46D are simplified illustrations of stages in the production of an electro-optic integrated circuit in accordance with another preferred embodiment of the present invention;

FIG. 47 is an enlarged simplified optical illustration of a portion of FIG. 46D;

FIG. 48 is a simplified optical illustration of optical communication between an electro-optic integrated circuit and an electro-optic integrated circuit in accordance with another preferred embodiment of the present invention;

FIG. 49 is a simplified optical illustration of optical communication between an optic integrated circuit and an electro-optic integrated circuit in accordance with a preferred embodiment of the present invention;

FIGS. 50A, 50B, 50C, 50D and 50E are simplified pictorial illustrations of stages in the production of an electro-optic integrated circuit constructed and operative in accordance with still another preferred embodiment of the present invention;

FIG. 51 is a simplified functional illustration of a preferred embodiment of the structure of FIG. 50E;

FIGS. 52A and 52B are simplified pictorial illustrations of a packaged electro-optic circuit having integrally formed therein an optical connector and electrical connections, alone and in conjunction with a conventional optical connector;

FIGS. 53A, 53B, 53C, 53D, 53E and 53F are simplified pictorial and sectional illustrations of a first plurality of stages in the manufacture of the packaged electro-optic circuit of FIGS. 52A and 52B;

FIGS. 54A, 54B, 54C, 54D, 54E, 54F, 54G, 54H, 541 and 54J are simplified pictorial and sectional illustrations of a second plurality of stages in the manufacture of the packaged electro-optic circuit of FIGS. 52A and 52B;

FIGS. 55A, 55B, 55C and 55D are simplified pictorial and sectional illustrations of a third plurality of stages in the manufacture of the packaged electro-optic circuit of FIGS. 52A and 52B;

FIGS. 56A, 56B and 56C are enlarged simplified optical illustrations of a portion of FIG. 55D in accordance with various preferred embodiments of the present invention;

FIG. 57 is a simplified sectional illustration of an electro-optic circuit constructed and operative in accordance with another preferred embodiment of the present invention;

FIGS. 58A, 58B and 58C are enlarged simplified optical illustrations of a portion of FIG. 57 in accordance with various other preferred embodiments of the present invention;

FIG. 59 is a simplified pictorial illustration corresponding to sectional illustration 55D;

FIGS. 60A, 60B, 60C, 60D, 60E and 60F are simplified pictorial and sectional illustrations of a fourth plurality of stages in the manufacture of the packaged electro-optic circuit of FIGS. 52A and 52B; and

FIG. 61 is a simplified illustration of incorporation of packaged electro-optic circuits of the type shown in FIGS. 52A and 52B as parts of a larger electrical circuit.

FIG. 62 is a simplified pictorial illustration of an initial stage in the production of an electro-optic integrated circuit constructed and operative in accordance with a preferred embodiment of the present invention;

FIGS. 63A, 63B, 63C, 63D and 63E are simplified sectional illustrations of further stages in the production of the electro-optic integrated circuit of FIG. 62;

FIG. 64 is a simplified illustration of an integrated circuit module of the type referenced in FIGS. 63A-63E, including a laser light source;

FIG. 65 is a simplified illustration of an integrated circuit module of the type referenced in FIGS. 63A-63E, including an optical detector;

FIG. 66 is a simplified illustration of an integrated circuit module of the type referenced in FIGS. 63A-63E, including multiple elements located in multiple recesses formed within a substrate;

FIGS. 67A, 67B, 67C and 67D are simplified pictorial illustrations of additional stages in the production of an electro-optic integrated circuit constructed and operative in accordance with the preferred embodiment of the present invention;

FIGS. 68A, 68B, 68C and 68D are simplified sectional illustrations of additional stages in the production of an electro-optic integrated circuit referenced in FIGS. 67A-67D.

FIGS. 69A, 69B and 69C are enlarged simplified optical illustrations of a portion of FIG. 68D in accordance with a preferred embodiments of the present invention;

FIG. 70 is a simplified sectional illustration of an electro-optic integrated circuit constructed and operative in accordance with yet another preferred embodiment of the present invention;

FIGS. 71A, 71B and 71C are enlarged simplified optical illustrations of a portion of FIG. 70 in accordance with other embodiments of the present invention;

FIGS. 72A, 72B, 72C, 72D and 72E are simplified pictorial illustrations of stages in the production of an electro-optic integrated circuit constructed and operative in accordance with still another preferred embodiment of the present invention;

FIG. 73 is a simplified functional illustration of a preferred embodiment of the structure of FIG. 72E;

FIGS. 74A, 74B, 74C, 74D and 74E are simplified illustrations of a method for fabricating optical elements employed in the embodiments of FIGS. 62-73 and FIGS. 81A-87 in accordance with different embodiments of the present invention;

FIGS. 75A, 75B, 75C, 75D, 75E and 75F are simplified illustrations of a method for fabricating optical elements employed in the embodiments of FIGS. 62-73 and FIGS. 81A-87 in accordance with other embodiments of the present invention;

FIGS. 76A, 76B, 76C, 76D, 76E, 76F and 76G are simplified illustrations of a method for fabricating optical elements employed in the embodiments of FIGS. 62-73 and FIGS. 81A-87 in accordance with yet other embodiments of the present invention;

FIGS. 77A, 77B, 77C, 77D, 77E, 77F and 77G are simplified illustrations of a method for fabricating optical elements employed in the embodiments of FIGS. 62-73 and FIGS. 81A-87 in accordance with still another embodiment of the present invention;

FIGS. 78A, 78B, 78C, 78D, 78E, 78F, 78G and 78H are simplified illustrations of a method for fabricating optical elements employed in the embodiments of FIGS. 62-73 and FIGS. 81A-87 in accordance with a further embodiment of the present invention;

FIGS. 79A, 79B, 79C, 79D, 79E, 79F, 79G and 79H are simplified illustrations of a method for fabricating optical elements employed in the embodiments of FIGS. 62-73 and FIGS. 81A-87 in accordance with yet a further embodiment of the present invention;

FIGS. 80A, 80B, 80C, 80D, 80E, 80F, 80G and 80H are simplified illustrations of a method for fabricating optical elements employed in the embodiments of FIGS. 62-73 and FIGS. 81A-87 in accordance with still a further embodiment of the present invention;

FIGS. 81A and 81B are simplified pictorial illustrations of a packaged electro-optic circuit having integrally formed therein an optical connector and electrical connections, alone and in conjunction with a conventional optical connector;

FIGS. 82A, 82B, 82C, 82D, 82E, 82F and 82G are simplified pictorial and sectional illustrations of a plurality of stages in the manufacture of the packaged electro-optic circuit of FIGS. 81A and 81B;

FIGS. 83A, 83B, 83C, 83D and 83E are simplified pictorial and sectional illustrations of a further plurality of stages in the manufacture of the packaged electro-optic circuit of FIGS. 81A and 81B;

FIG. 84 is a simplified pictorial illustration corresponding to sectional illustration 68B;

FIG. 85 is a simplified pictorial illustration corresponding to sectional illustrations 68C, 68D and 70;

FIGS. 86A, 86B, 86C, 86D, 86E and 86F are simplified pictorial and sectional illustrations of a further plurality of stages in the manufacture of the packaged electro-optic circuit of FIGS. 81A and 81B; and

FIG. 87 is a simplified illustration of incorporation of packaged electro-optic circuits of the type shown in FIGS. 81A and 81B as parts of a larger electrical circuit.

### DETAILED DESCRIPTION OF PREFERRED EMBODIMENTS

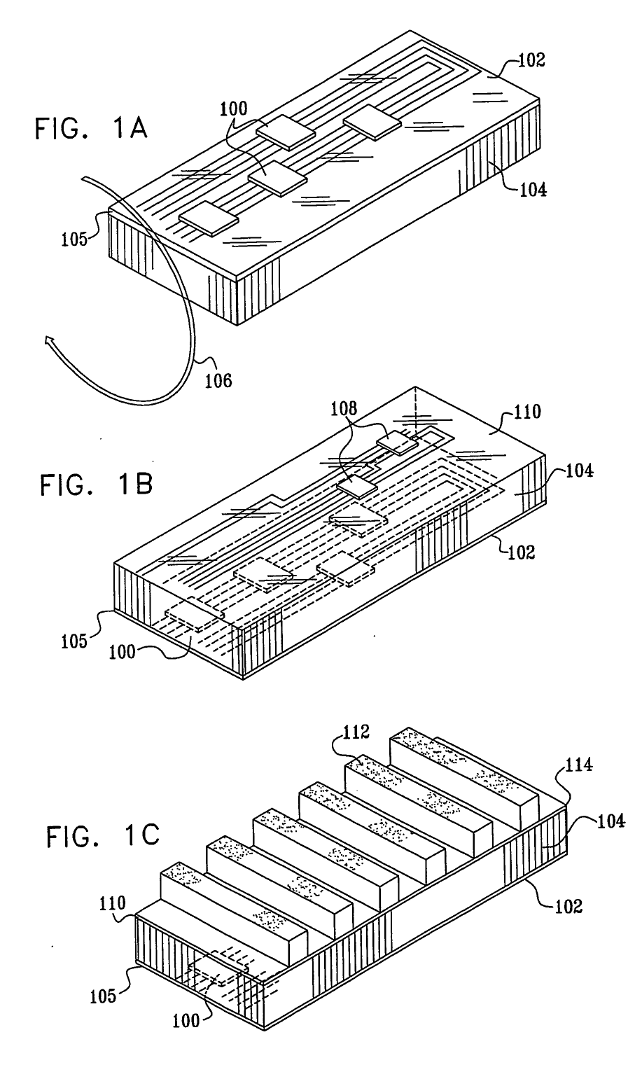

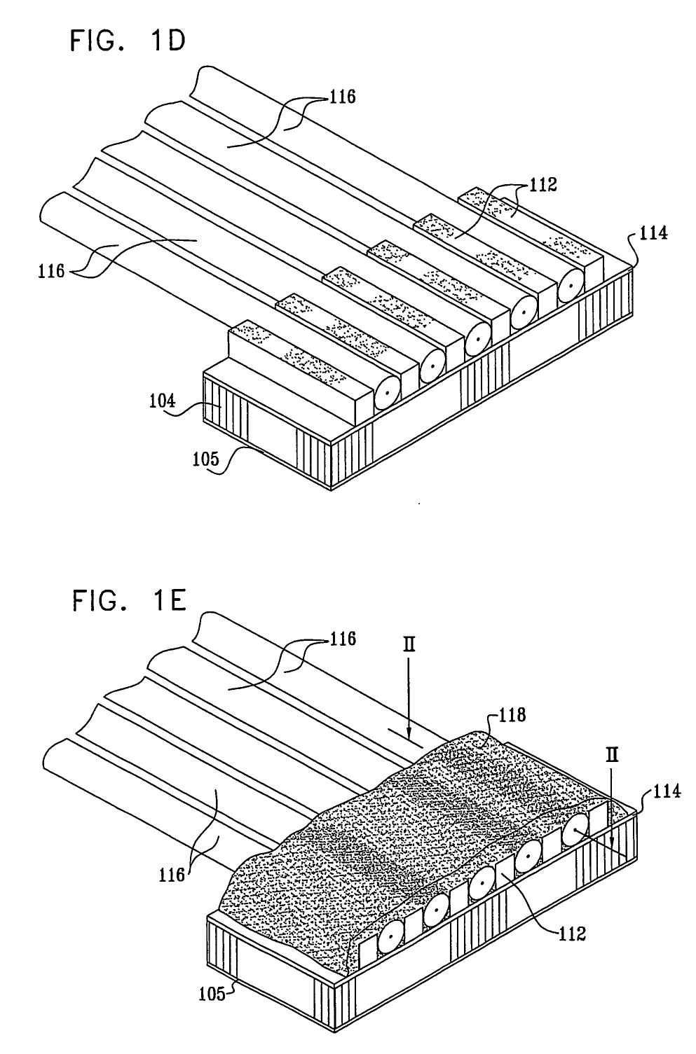

Reference is now made to FIGS. 1A, 1B, 1C, 1D and 1E, which are simplified pictorial illustrations of initial stages in the production of an electro-optic integrated circuit constructed and operative in accordance with a preferred embodiment of the present invention. As seen in FIG. 1A, one or more electrical circuits 100 are preferably formed onto a first surface 102 of a substrate 104, preferably a silicon substrate or a substrate that is generally transparent to light within at least part of the wavelength range of 600-1650 nm, typically of thickness between 200-800 microns. The electrical circuits 100 are preferably formed by conventional photolithographic techniques employed in the production of integrated circuits, and included within a planarized layer 105 formed onto substrate 104. The substrate preferably is then turned over, as indicated by an arrow 106, and one or more electrical circuits 108 are formed on an opposite surface 110 of substrate 104, as shown in FIG. 1B.

Referring now to FIG. 1C, preferably, following formation of electrical circuits 100 and 108 on respective surfaces 102 and 110 of substrate 104, an array of parallel, spaced, elongate optical fiber positioning elements 112 is preferably formed, such as by conventional photolithographic techniques, over a planarized layer 114 including electrical circuits 108 (FIG. 1B). As seen in FIG. 1D, an array of optical fibers 116 is disposed over layer 114, each fiber being positioned between adjacent positioning elements 112. The fibers are fixed in place relative to positioning elements 112 and to layer 114 of substrate 104 by means of a suitable adhesive 118, preferably epoxy, as seen in FIG. 1E.

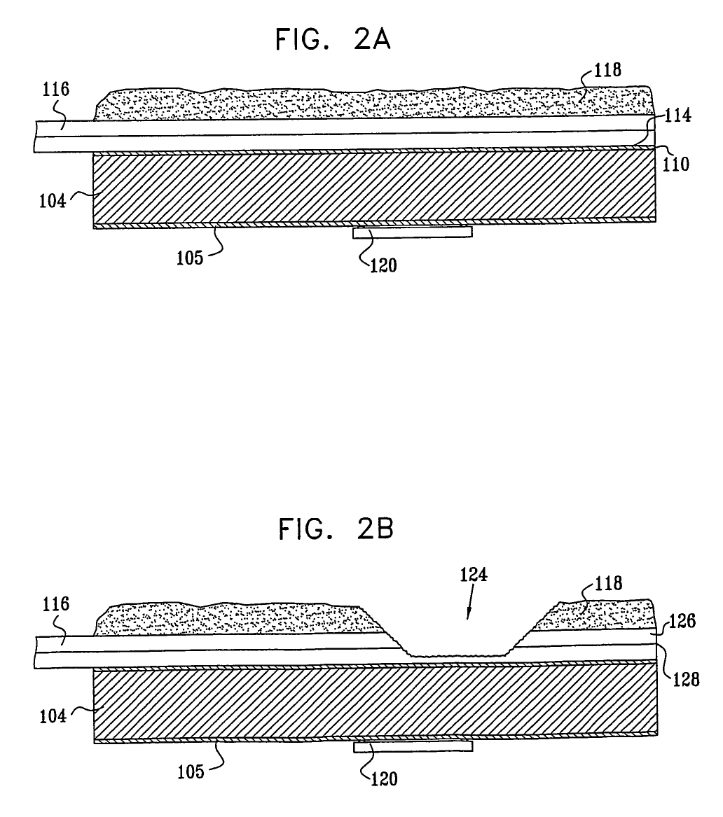

Reference is now made to FIGS. 2A, 2B, 2C, and 2D, which are simplified sectional illustrations, taken along the lines II-II in FIG. 1E, of further stages in the production of an electro-optic integrated circuit. As seen in FIG. 2A, electro-optic components 120, such as diode lasers, are mounted onto electrical circuit 100 (not shown), included within planarized layer 105. It is appreciated that electro-optic components 120 may be any suitable electro-optic component, such as a laser diode, diode detector, waveguide, array waveguide grating or a semiconductor optical amplifier.

As shown in FIG. 2B, a transverse notch 124 is preferably formed, at least partially overlapping the locations of the electro-optic components 120 and extending through the adhesive 118 and partially through each optical fiber 116. Specifically, in this embodiment, the notch 124 extends through part of the cladding 126 of each fiber 116 and entirely through the core 128 of each fiber. It is appreciated that the surfaces defined by the notch 124 are relatively rough, as shown.

Turning now to FIG. 2C, it is seen that a mirror 130 is preferably mounted parallel to one of the rough inclined surfaces 132 defined by notch 124. Mirror 130 preferably comprises a glass substrate 134, with a surface 135 facing surface 132 defined by notch 124, having formed on an opposite surface 136 thereof, a metallic layer or a dichroic filter layer 138. As seen in FIG. 2D, preferably, the mirror 130 is securely held in place partially by any suitable adhesive 139, such as epoxy, and partially by an optical adhesive 140, such as OG 146, manufactured by Epoxy Technology, 14 Fortune Drive, Billerica, Mass. 01821, USA, whose refractive index, preferably, is precisely matched to that of the cores 128 of the optical fibers 116. It is appreciated that optical adhesive 140 may be employed throughout instead of adhesive 139. The adhesive 140 preferably fills the interstices between the roughened surface 132 defined by notch 124 and surface 135 of mirror 130.

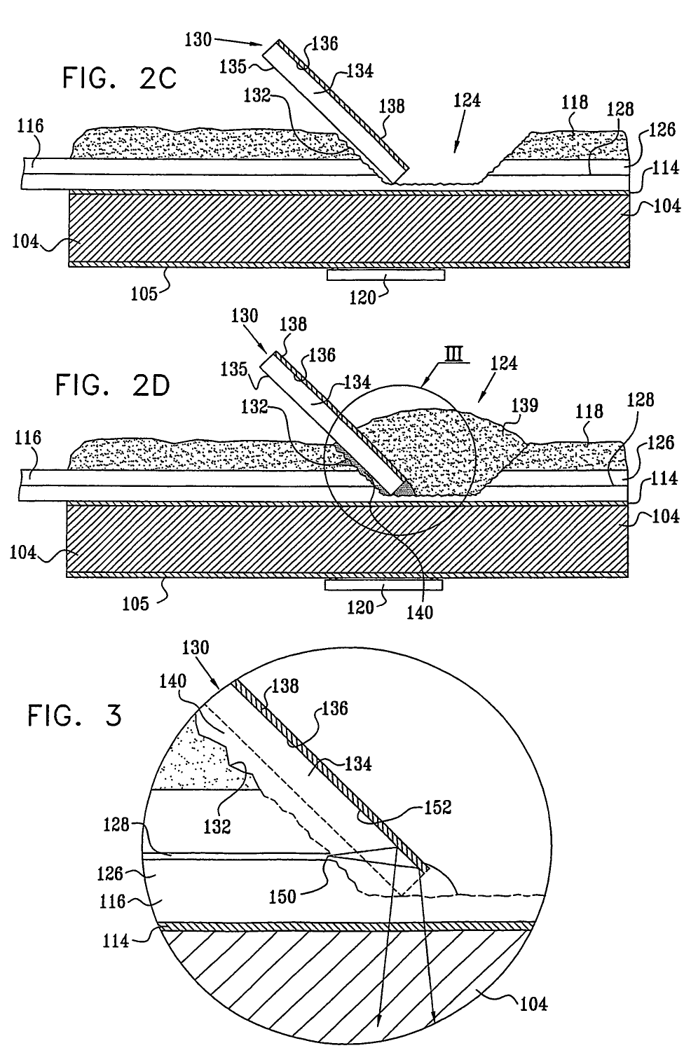

Reference is now made to FIG. 3, which is an enlarged simplified optical illustration of a portion of FIG. 2D. Here it is seen that a generally uninterrupted optical path is defined for light, preferably in the wavelength range of 600-1650 nm, from an end 150 of a core 128, through adhesive 140 and substrate 134 to a reflective surface 152 of layer 138 of mirror 130 and thence through substrate 134, adhesive 140 and cladding 126, through layer 114 and substrate 104, which are substantially transparent to this light. It is noted that the index of refraction of adhesive 140 is close to but not identical to that of cladding 126 and substrate 134. It is noted that mirror 130 typically reflects light onto electro-optic component 120 (FIG. 2D), without focusing or collimating the light.

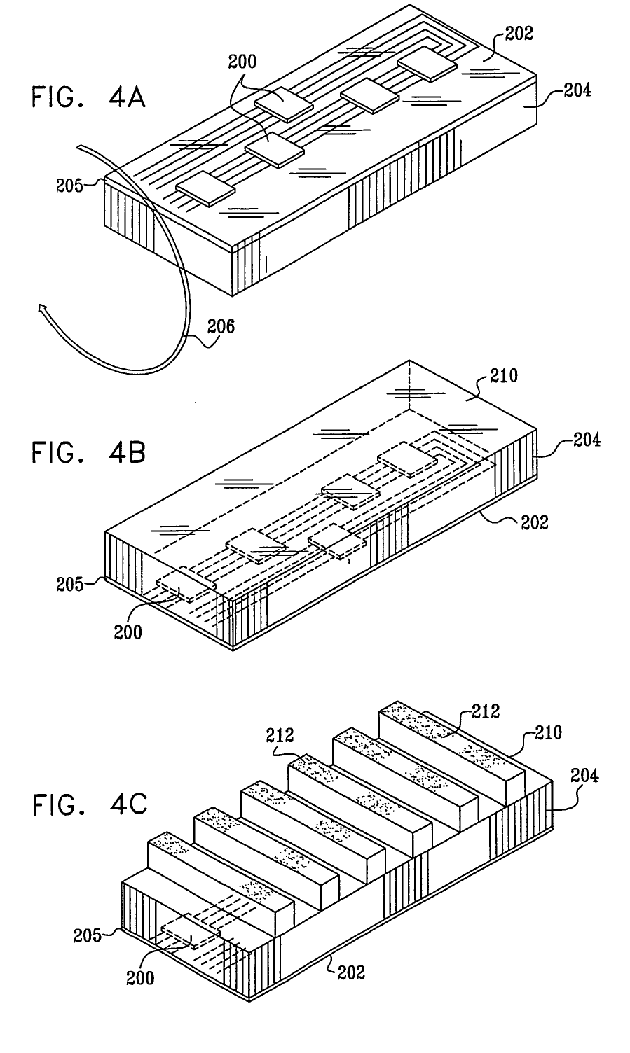

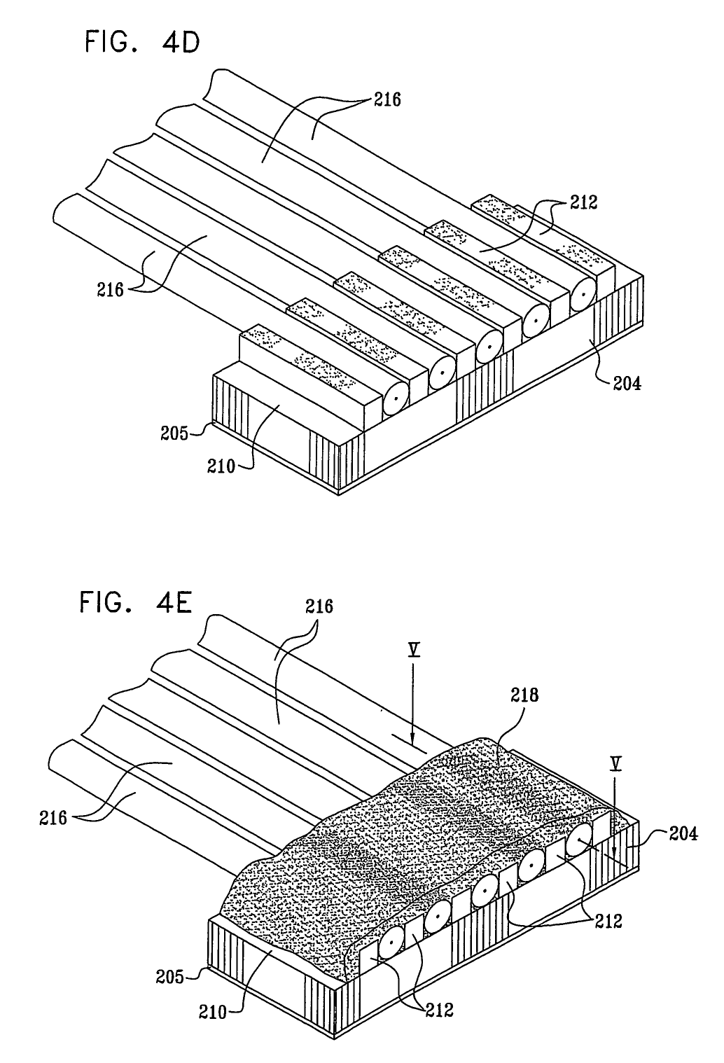

Reference is now made to FIGS. 4A, 4B, 4C, 4D and 4E, which are simplified pictorial illustrations of initial stages in the production of an electro-optic integrated circuit constructed and operative in accordance with a preferred embodiment of the present invention. As seen in FIG. 4A, one or more electrical circuits 200 are preferably formed onto a first surface 202 of a substrate 204, preferably a substrate that is generally transparent to light within at least part of the wavelength range of 400-1650 nm, typically of thickness between 200-1000 microns. The electrical circuits 200 are preferably formed by conventional photolithographic techniques employed in the production of integrated circuits, and included within a planarized layer 205 formed onto substrate 404. The substrate preferably is then turned over, as indicated by an arrow 206, and as shown in FIG. 4B.

Referring now to FIG. 4C, preferably, following formation of electrical circuits 200 on surface 202 of substrate 204, an array of parallel, spaced, elongate optical fiber positioning elements 212 is preferably formed, such as by conventional photolithographic techniques, over an opposite surface 210 of substrate 204. As seen in FIG. 4D, an array of optical fibers 216 is disposed over surface 210 of substrate 204, each fiber being positioned between adjacent positioning elements 212. The fibers 216 are fixed in place relative to positioning elements 212 and to surface 210 of substrate 204 by means of a suitable adhesive 218, preferably epoxy, as seen in FIG. 4E.

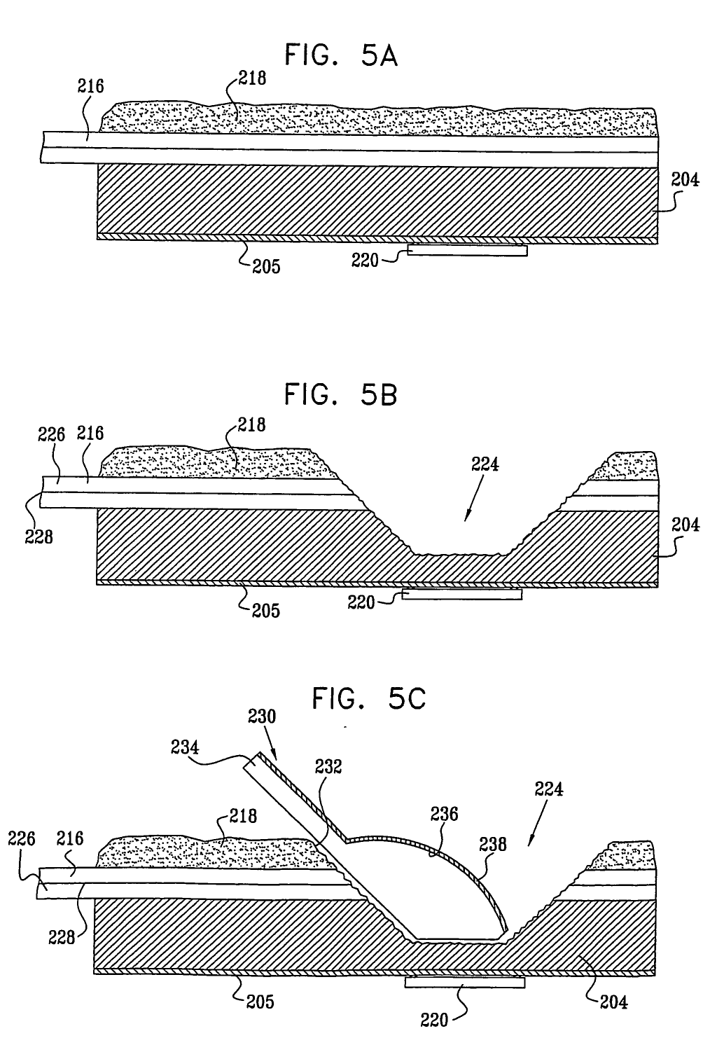

Reference is now made to FIGS. 5A, 5B, 5C, and 5D, which are simplified sectional illustrations, taken along the lines V-V in FIG. 4E, of further stages in the production of an electro-optic integrated circuit. As seen in FIG. 5A, electro-optic components 220, such as diode lasers, are mounted onto electrical circuit 200 (not shown), included within planarized layer 205. It is appreciated that electro-optic components 220 may be any suitable electro-optic component, such as a laser diode, diode detector, waveguide, array waveguide grating or a semiconductor optical amplifier.

As shown in FIG. 5B, a transverse notch 224 is preferably formed, at least partially overlapping the locations of the electro-optic components 220 and extending through the adhesive 218, entirely through each optical fiber 216 and partially into substrate 204. Specifically, in this embodiment, the notch 224 extends through all of cladding 226 of each fiber 216 and entirely through the core 228 of each fiber. It is appreciated that the surfaces defined by the notch 224 are relatively rough, as shown.

Turning now to FIG. 5C, it is seen that a partially flat and partially concave mirror 230 is preferably mounted parallel to one of the rough inclined surfaces 32 defined by notch 224. Mirror 230 preferably comprises a glass substrate 234 having formed thereon a curved portion 236 over which is formed a curved metallic layer or a dichroic filter layer 238. As seen in FIG. 5D, preferably, the mirror 230 is securely held in place partially by any suitable adhesive 239, such as epoxy, and partially by an optical adhesive 240, such as OG 146, manufactured by Epoxy Technology, 14 Fortune Drive, Billerica, Mass. 01821, USA, whose refractive index preferably is precisely matched to that of the cores 228 of the optical fibers 216. It is appreciated that optical adhesive 240 may be employed throughout instead of adhesive 239. Optical adhesive 240 preferably fills the interstices between the roughened surface 232 defined by notch 224 and a surface 242 of mirror 230.

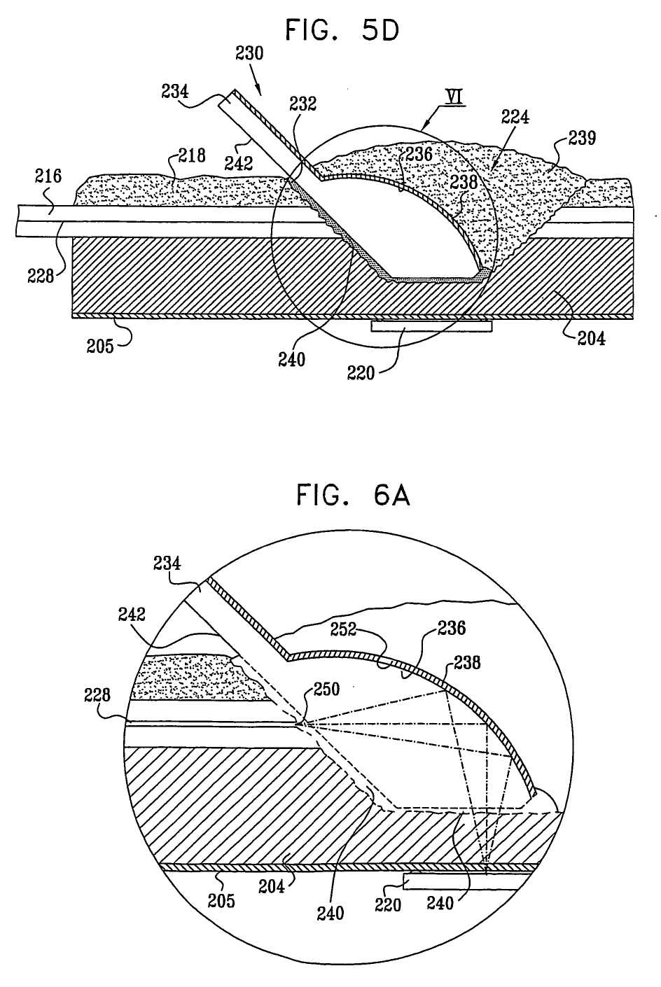

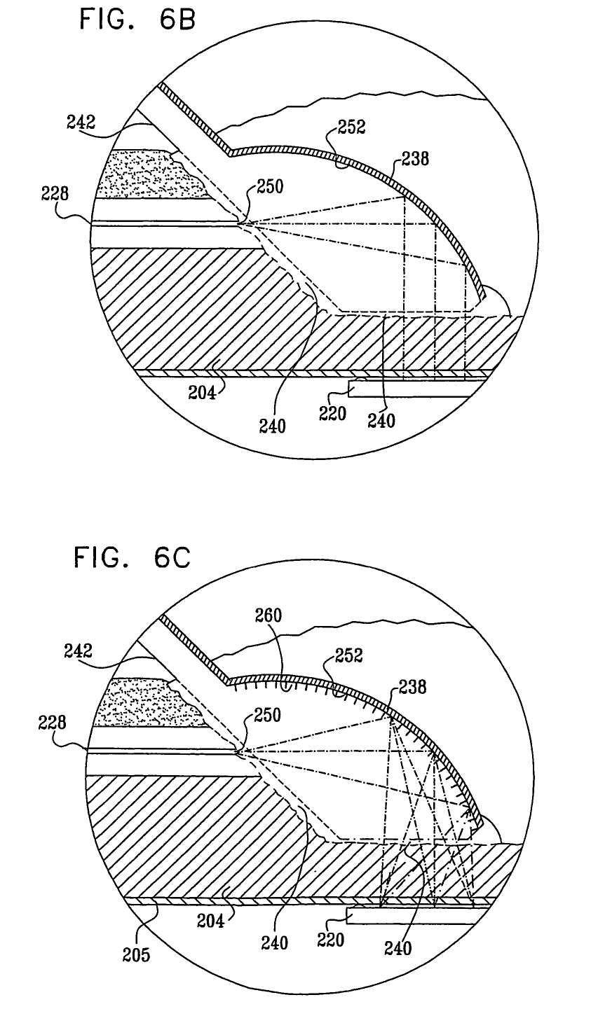

Reference is now made to FIG. 6A, which is an enlarged simplified optical illustration of a portion of FIG. 5D. Here it is seen that a generally uninterrupted optical path is defined for light, preferably in the wavelength range of 400-1650 nm, from an end 250 of a core 228, through adhesive 240, substrate 234 and curved portion 236 to a reflective surface 252 of layer 238 and thence through curved portion 236, adhesive 240, substrate 204 and layer 205 which are substantially transparent to this light. It is noted that the index of refraction of adhesive 240 is close to but not identical to that of curved portion 236 and substrates 204 and 234. In the embodiment of FIG. 6A, the operation of curved layer 238 is to focus light exiting from end 250 of core 228 onto the electro-optic component 220.

Reference is now made to FIG. 6B, which is an enlarged simplified optical illustration of a portion of FIG. 5D in accordance with a further embodiment of the present invention. In this embodiment, the curvature of curved layer 238 produces collimation rather than focusing of the light exiting from end 250 of core 228 onto the electro-optic component 220.

Reference is now made to FIG. 6C, which is an enlarged simplified optical illustration of a portion of FIG. 5D in accordance with yet another embodiment of the present invention wherein a grating 260 is added to curved layer 238. The additional provision of grating 260 causes separation of light impinging thereon according to its wavelength, such that multispectral light exiting from end 250 of core 228 is focused at multiple locations on electro-optic component 220 in accordance with the wavelengths of components thereof.

Reference is now made to FIG. 7, which is a simplified sectional illustration of an electro-optic integrated circuit constructed and operative in accordance with yet another preferred embodiment of the present invention. The embodiment of FIG. 7 corresponds generally to that described hereinabove with respect to FIG. 5D other than in that a mirror with multiple concave reflective surfaces is provided rather than a mirror with a single such reflective surface. As seen in FIG. 7, it is seen that light from optical fiber 316 is directed onto an electro-optic component 320 by a partially flat and partially concave mirror assembly 330, preferably mounted parallel to one of the rough inclined surfaces 332 defined by notch 324. Mirror assembly 330 preferably comprises a glass substrate 334 having formed thereon a plurality of curved portions 336 over which are formed a curved metallic layer or a dichroic filter layer 338. Mirror assembly 330 also defines a reflective surface 340, which is disposed on a planar surface 342 generally opposite layer 338. Preferably, the mirror assembly 330 is securely held in place partially by any suitable adhesive 343, such as epoxy, and partially by an optical adhesive 344, such as OG 146, manufactured by Epoxy Technology, 14 Fortune Drive, Billerica, Mass. 01821, USA, whose refractive index preferably is precisely matched to that of the cores 328 of the optical fibers 316. It is appreciated that optical adhesive 344 may be employed throughout instead of adhesive 343. The optical adhesive 344 preferably fills the interstices between the roughened surface 332 defined by notch 324 and surface 342 of mirror assembly 330.

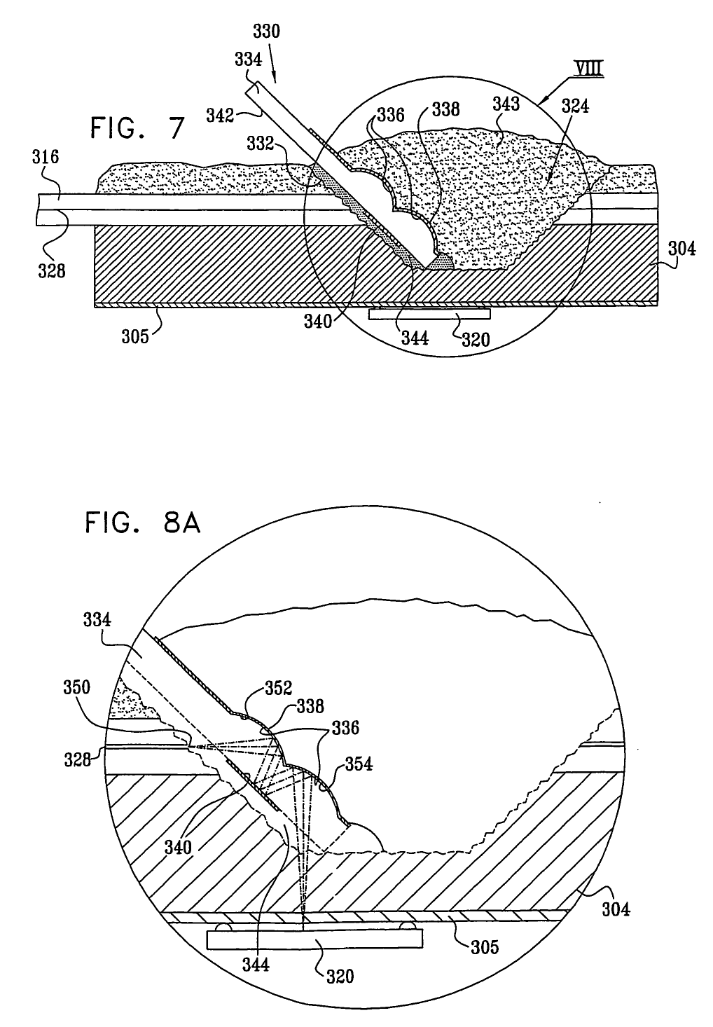

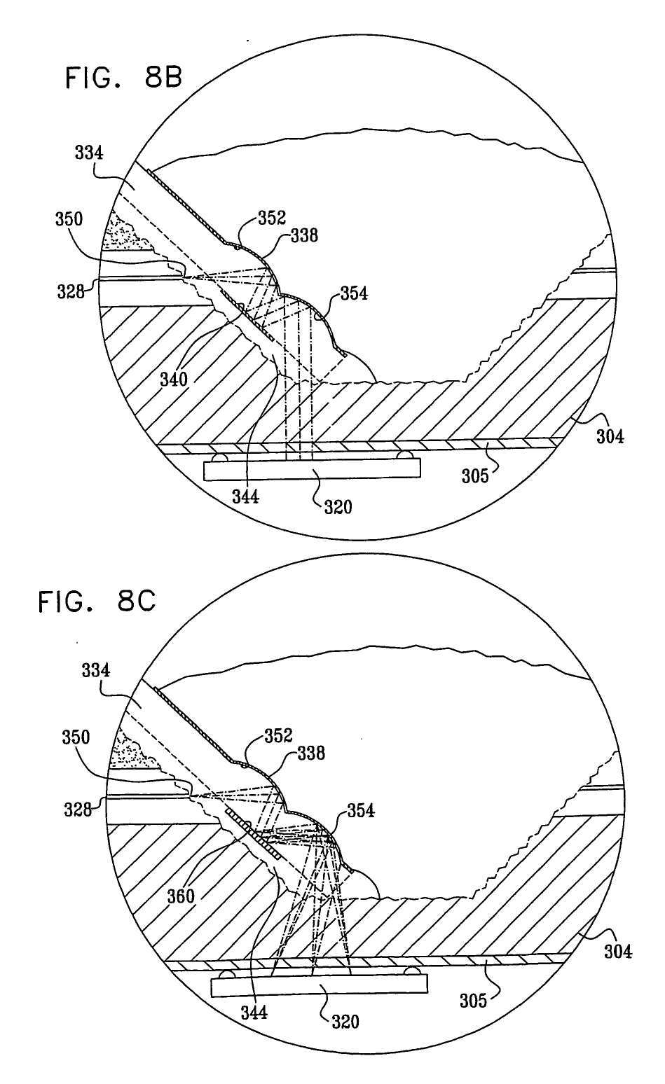

Reference is now made to FIG. 8A, which is an enlarged simplified optical illustration of a portion of FIG. 7. Here it is seen that a generally uninterrupted optical path is defined for light, preferably in the wavelength range of 400-1650 nm, from an end 350 of a core 328, through adhesive 344, substrate 334 and first curved portion 336, to a curved reflective surface 352 of layer 338 and thence through first curved portion 336 and substrate 334 to reflective surface 340, from reflective surface 340 through substrate 334 and second curved portion 336 to another curved reflective surface 354 of layer 338 and thence through second curved portion 336, substrate 334, adhesive 344, substrate 304 and layer 305, which are substantially transparent to this light. It is noted that the index of refraction of adhesive 344 is close to but not identical to that of substrates 304 and 334. In the embodiment of FIG. 8A, the operation of curved layer 338 and reflective surface 340 is to focus light exiting from end 350 of core 328 onto the electro-optic component 320.

Reference is now made to FIG. 8B, which is an enlarged simplified optical illustration of a portion of FIG. 7 in accordance with a further embodiment of the present invention. In this embodiment, the curvature of curved layer 338 produces collimation rather than focusing of the light exiting from end 350 of core 328 onto the electro-optic component 320.

Reference is now made to FIG. 8C, which is an enlarged simplified optical illustration of a portion of FIG. 7 in accordance with yet another embodiment of the present invention wherein a reflective grating 360 replaces reflective surface 340. The additional provision of grating 360 causes separation of light impinging thereon according to its wavelength, such that multispectral light existing from end 350 of core 328 is focused at multiple locations on electro-optic component 320 in accordance with the wavelengths of components thereof.

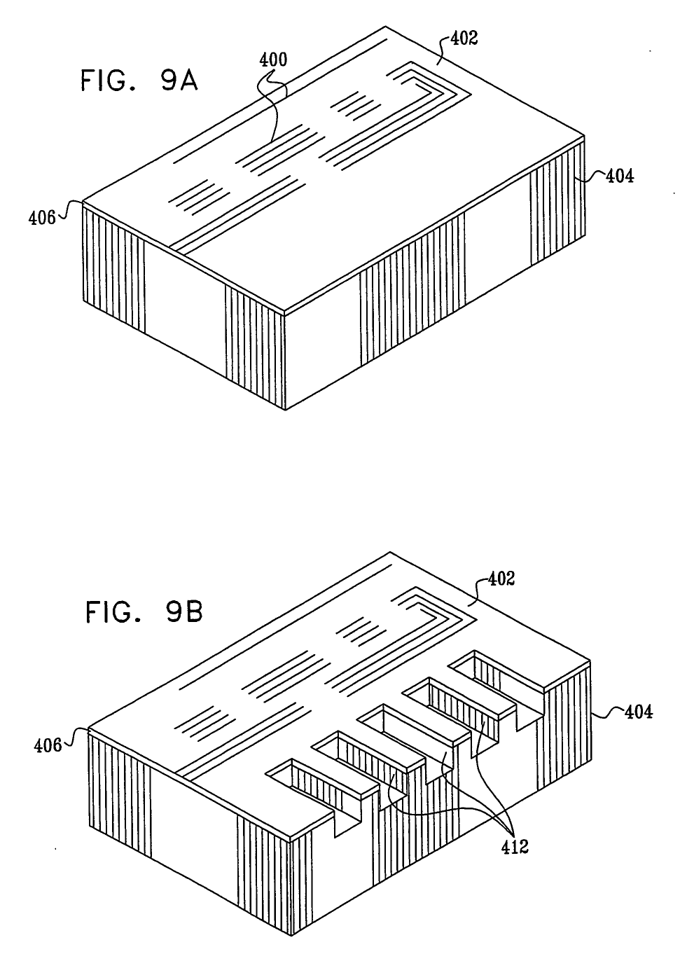

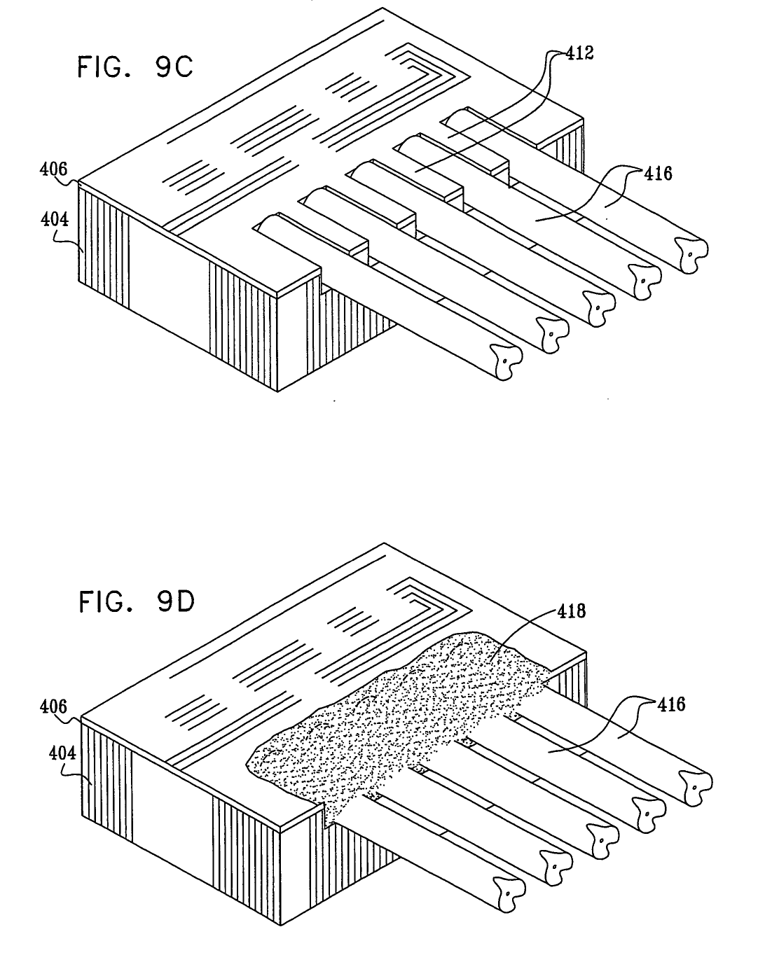

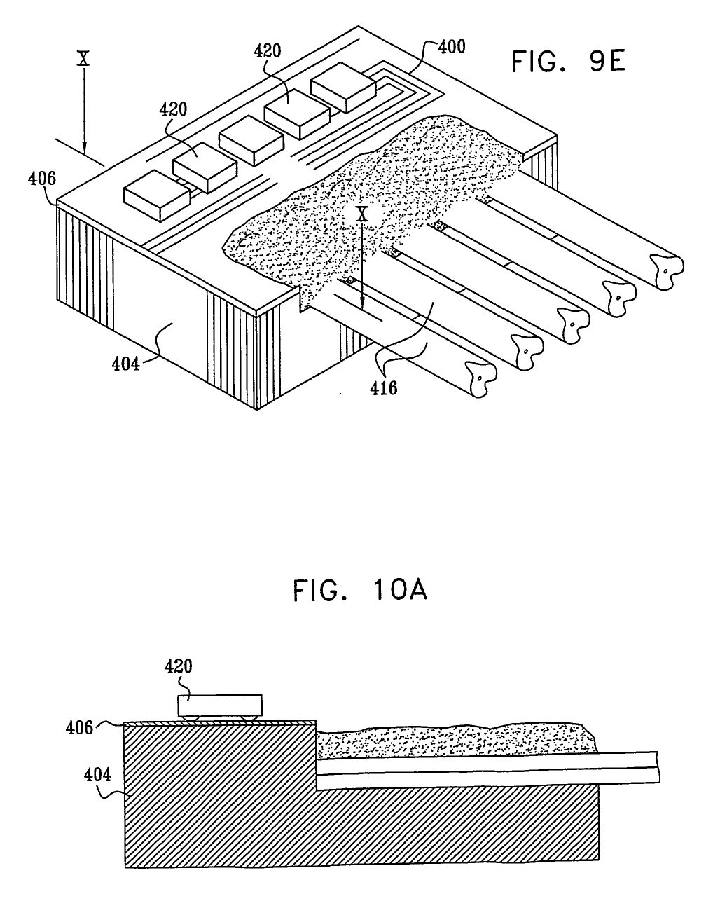

Reference is now made to FIGS. 9A, 9B, 9C, 9D and 9E, which are simplified pictorial illustrations of initial stages in the production of an electro-optic integrated circuit constructed and operative in accordance with yet another preferred embodiment of the present invention. As seen in FIG. 9A, one or more electrical circuits 400 are preferably formed onto a portion of a surface 402 of a substrate 404, preferably a glass, silicon or ceramic substrate, typically of thickness between 300-1000 microns. The electrical circuits 400 are preferably formed by conventional photolithographic techniques employed in the production of integrated circuits, and included within a planarized layer 406 formed onto substrate 404.

Turning now to FIG. 9B, it is seen that another portion of the surface 402 is formed with an array of parallel, spaced, elongate optical fiber positioning elements 412 by any suitable technique, such as etching or notching. As seen in FIG. 9C, an array of optical fibers 416 is engaged with substrate 404, each fiber being positioned between adjacent positioning elements 412. The fibers are fixed in place relative to positioning elements 412 and to substrate 404 by means of a suitable adhesive 418, preferably epoxy, as seen in FIG. 9D. As seen in FIG. 9E, a plurality of electro-optic components 420, such as diode lasers, are mounted in operative engagement with electrical circuits 400, each electro-optic component 420 preferably being aligned with a corresponding fiber 416. It is appreciated that electro-optic component 420 may be any suitable electro-optic component, such as a laser diode, diode detector, waveguide, array waveguide grating or a semiconductor optical amplifier.

Reference is now made to FIGS. 10A, 10B, 10C, and 10D, which are simplified sectional illustrations, taken along the lines X-X in FIG. 9E, of further stages in the production of an electro-optic integrated circuit. As seen in FIG. 10A, which corresponds to FIG. 9E, electro-optic components 420 are each mounted onto an electrical circuit (not shown), included within planarized layer 406 formed onto substrate 404. As shown in FIG. 10B, a transverse notch 424 is preferably formed to extend through the adhesive 418 entirely through each optical fiber 416 and partially into substrate 404. Specifically, in this embodiment, the notch 424 extends through all of cladding 426 of each fiber 416 and entirely through the core 428 of each fiber. It is appreciated that the surfaces defined by the notch 424 are relatively rough, as shown.

Turning now to FIG. 10C, it is seen that a partially flat and partially concave mirror assembly 430 is preferably mounted parallel to one of the rough inclined surfaces 432 defined by notch 424. Mirror assembly 430 preferably comprises a glass substrate 434 having formed thereon a curved portion 436 over which is formed a curved metallic layer or a dichroic filter layer 438. Mirror assembly 430 also defines a planar surface 440, generally opposite layer 438, having formed thereon a metallic layer or a dichroic filter layer 442 underlying part of the curved portion 436.

As seen in FIG. 10D, preferably, the mirror assembly 430 is securely held in place partially by any suitable adhesive 444, such as epoxy, and partially by an optical adhesive 446, such as OG 146, manufactured by Epoxy Technology, 14 Fortune Drive, Billerica, Mass. 01821, USA, whose refractive index preferably is precisely matched to that of the cores 428 of the optical fibers 416. It is appreciated that optical adhesive 446 may be employed throughout instead of adhesive 444.

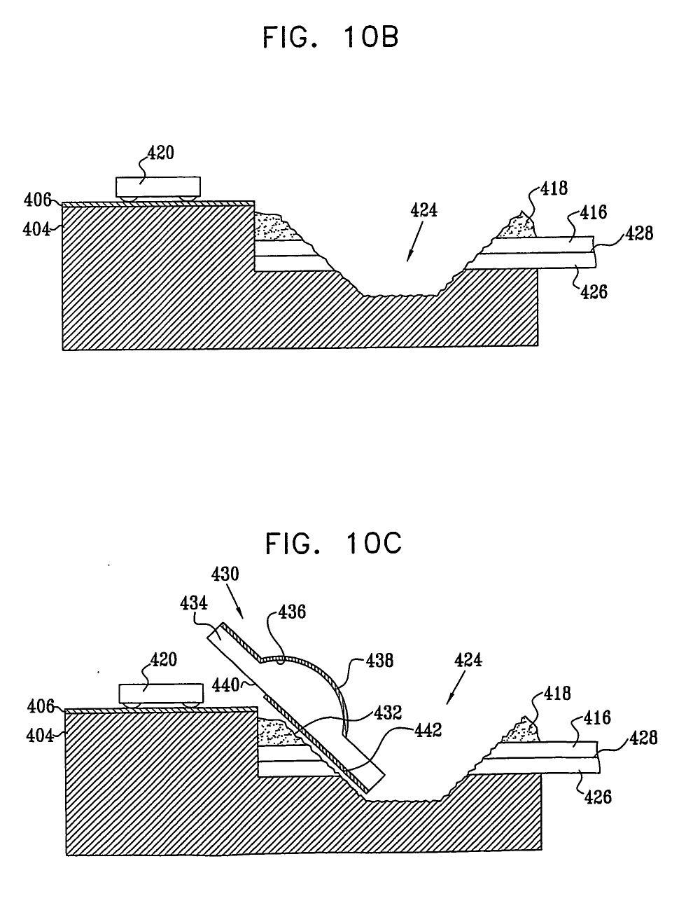

Reference is now made to FIG. 11A, which is an enlarged simplified optical illustration of a portion of FIG. 10D. Here it is seen that a generally uninterrupted optical path is defined for light, preferably in the wavelength range of 400-1650 nm, from each electro-optic component 420 through glass substrate 434 and curved portion 436 of mirror assembly 430 into reflective engagement with layer 438 and thence through curved portion 436 and substrate 434 to layer 442 and reflected from layer 442 through substrate 434 and adhesive 446 to focus at an end 450 of a core 428. In the embodiment of FIG. 11A, the operation of curved layer 438 is to focus light exiting from electro-optic component 420 onto end 450 of core 428.

Reference is now made to FIG. 11B, which is an enlarged simplified optical illustration of a portion of FIG. 10D in accordance with a further embodiment of the present invention. In this embodiment, the curvature of curved layer 438 produces collimation rather than focusing of the light exiting from electro-optic component 420 onto end 450 of core 428.

Reference is now made to FIG. 11C, which is an enlarged simplified optical illustration of a portion of FIG. 10D in accordance with yet another embodiment of the present invention wherein a grating 460 is added to curved layer 438. The additional provision of grating 460 causes separation of light impinging thereon according to its wavelength, such that only one component of multispectral light exiting electro-optic component 420 is focused on end 450 of core 428.

Reference is now made to FIG. 12, which is a simplified sectional illustration of an electro-optic integrated circuit constructed and operative in accordance with yet another preferred embodiment of the present invention. The embodiment of FIG. 12 corresponds generally to that described hereinabove with respect to FIG. 10D other than in that a mirror with multiple concave reflective surfaces is provided rather than a mirror with a single such reflective surface. As seen in FIG. 12, it is seen that light from an electro-optic component 520, such as a laser diode, is directed onto a partially flat and partially concave mirror assembly 530, preferably mounted parallel to one of the rough inclined surfaces 532 defined by notch 524. It is appreciated that electro-optic component 520 may be any suitable electro-optic component, such as a laser diode, diode detector, waveguide, array waveguide grating or a semiconductor optical amplifier. Mirror assembly 530 preferably comprises a glass substrate 534 having formed thereon a plurality of curved portions 536 over which are formed a curved metallic layer or a dichroic filter layer 538. Mirror assembly 530 also defines a reflective surface 540, which is disposed on a planar surface 542 generally opposite layer 538.

Preferably, the mirror assembly 530 is securely held in place partially by any suitable adhesive 544, such as epoxy, and partially by an optical adhesive 546, such as OG 146, manufactured by Epoxy Technology, 14 Fortune Drive, Billerica, Mass. 01821, USA, whose refractive index preferably is precisely matched to that of the cores 528 of the optical fibers 516. It is appreciated that optical adhesive 546 may be employed throughout instead of adhesive 544.

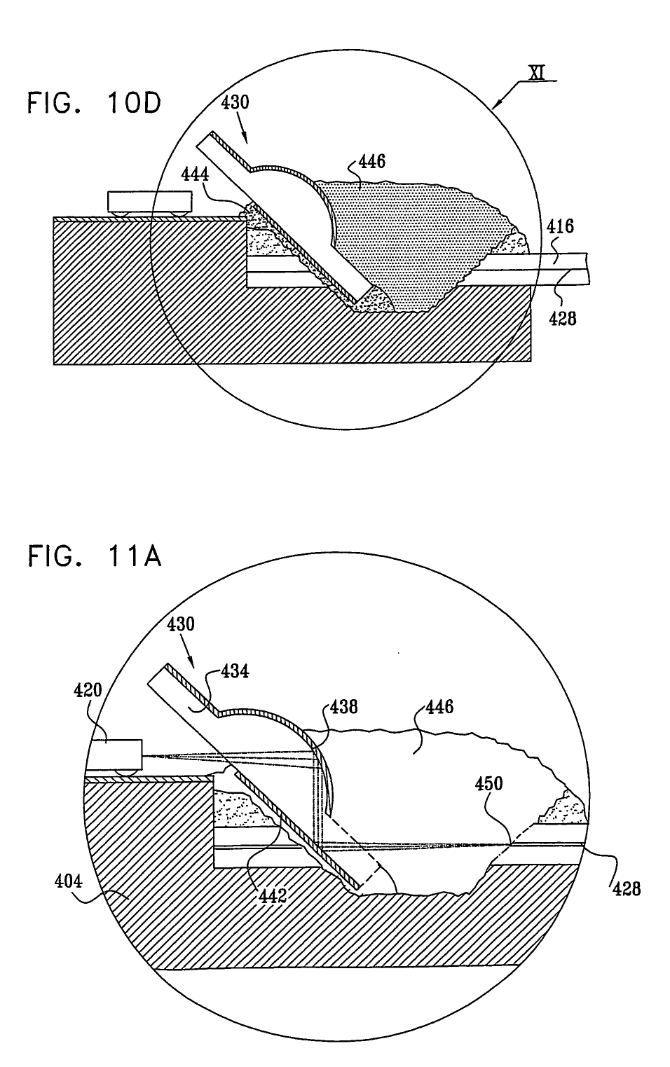

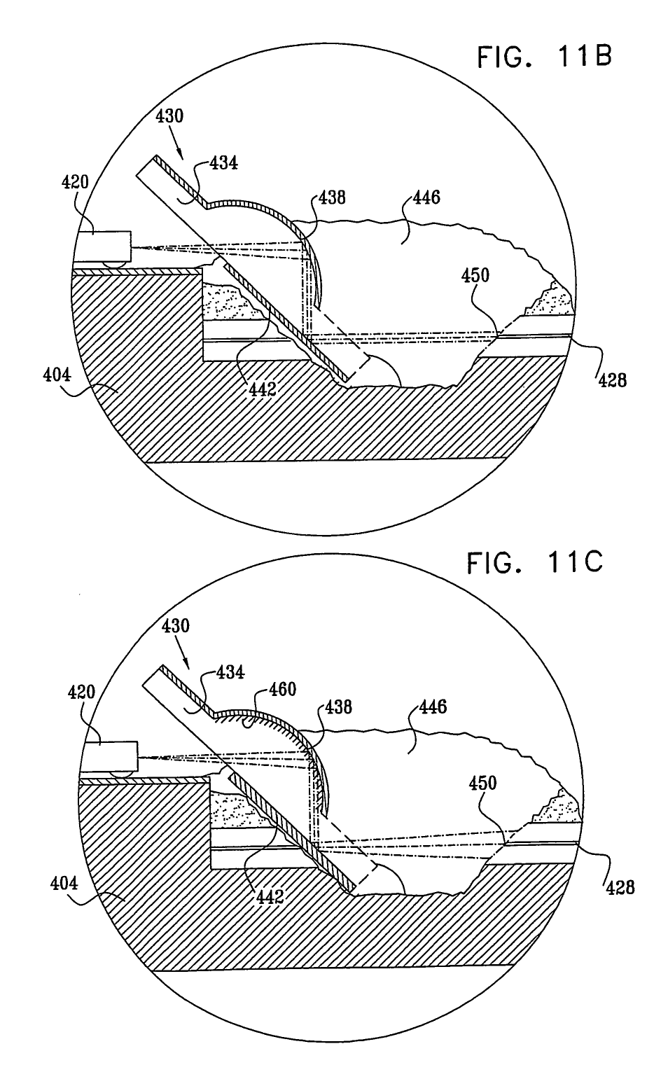

Reference is now made to FIG. 13A, which is an enlarged simplified optical illustration of a portion of FIG. 12. Here it is seen that a generally uninterrupted optical path is defined for light, preferably in the wavelength range of 400-1650 nm, from each electro-optic component 520 through substrate 534 and a first curved portion 536 of mirror assembly 530 into reflective engagement with a part of layer 538 overlying first curved portion 536 and thence through first curved portion 536 and substrate 534 to reflective surface 540, where it is reflected back through substrate 534 and a second curved portion 536 to another part of layer 538 overlying second curved portion 536 and is reflected back through second curved portion 536 and substrate 534 to reflective surface 540 and thence through substrate 534 and adhesive 546 to focus at an end 550 of a core 528. In the embodiment of FIG. 13A, the operation of curved layer 538 overlying first and second curved portions 536 is to focus light exiting from electro-optic component 520 onto end 550 of core 528, with enhanced optical properties.

Reference is now made to FIG. 13B, which is an enlarged simplified optical illustration of a portion of FIG. 12 in accordance with a further embodiment of the present invention. In this embodiment, the curvature of curved layer 538 produces collimation rather than focusing of the light exiting from electro-optic component 520 onto end 550 of core 528.

Reference is now made to FIG. 13C, which is an enlarged simplified optical illustration of a portion of FIG. 12 in accordance with yet another embodiment of the present invention wherein a reflective grating 560 replaces part of reflective surface 540. The additional provision of grating 560 causes separation of light impinging thereon according to its wavelength, such that only one component of multispectral light exiting electro-optic component 520 is focused on end 550 of core 528.

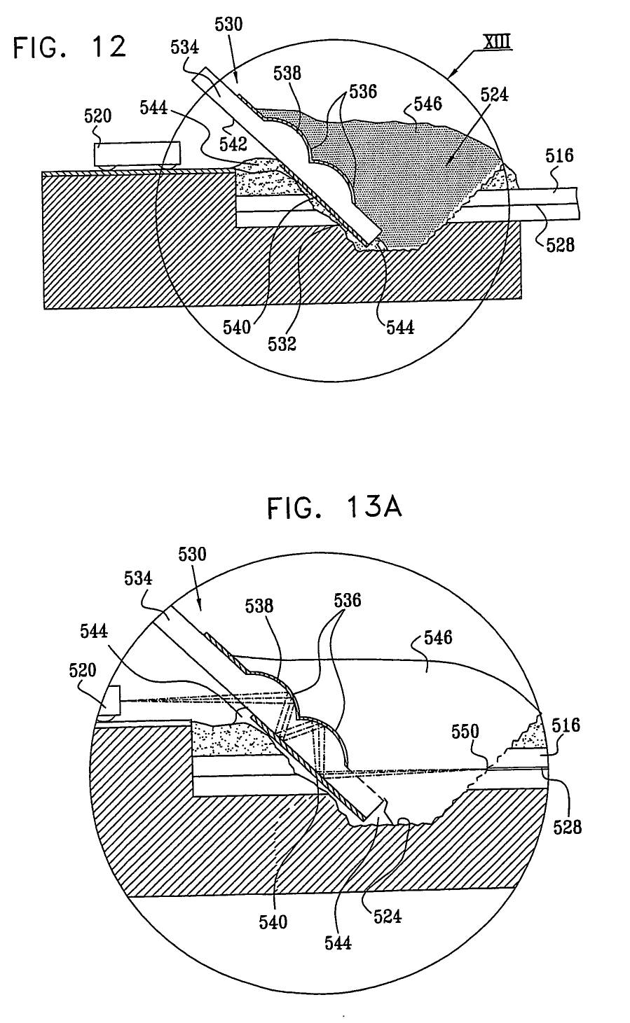

Reference is now made to FIGS. 14A, 14B, 14C and 14D, which are simplified pictorial illustrations of further stages in the production of an electro-optic integrated circuit constructed and operative in accordance with yet another preferred embodiment of the present invention. As seen in FIG. 14A, similarly to that shown in FIG. 5A, electro-optic components 600, such as edge emitting diode lasers, are mounted onto an electrical circuit (not shown), included within a planarized layer 602 formed onto a surface 603 of a substrate 604, at the opposite surface 606 of which are mounted optical fibers 616 by means of adhesive 618. It is appreciated that electro-optic components 600 may be any suitable electro-optic component, such as a laser diode, diode detector, waveguide, array waveguide grating or a semiconductor optical amplifier.

As shown in FIG. 14B, a transverse notch 624 is preferably formed, extending completely through substrate 604 and entirely through each optical fiber 616 and partially into adhesive 618. Specifically, in this embodiment, the notch 624 extends through all of cladding 626 of each fiber 616 and entirely through the core 628 of each fiber. It is appreciated that the surfaces defined by the notch 624 are relatively rough, as shown.

Turning now to FIG. 14C, it is seen that a partially flat and partially concave mirror assembly 630 is preferably mounted parallel to one of the rough inclined surfaces 632 defined by notch 624. Mirror assembly 630 preferably comprises a glass substrate 634 having formed thereon a curved portion 636. A partially planar and partially curved metallic layer or a dichroic filter layer 638 is formed over a surface 640 of substrate 634 and curved portion 636 formed thereon. A reflective layer 642 is formed on an opposite surface 643 of substrate 634 opposite layer 638.

As seen in FIG. 14D, preferably, the mirror assembly 630 is securely held in place partially by any suitable adhesive 644, such as epoxy, and partially by an optical adhesive 646, such as OG 146, manufactured by Epoxy Technology, 14 Fortune Drive, Billerica, Mass. 01821, USA, whose refractive index preferably is precisely matched to that of the cores 628 of the optical fibers 616. It is appreciated that optical adhesive 646 may be employed throughout instead of adhesive 644.

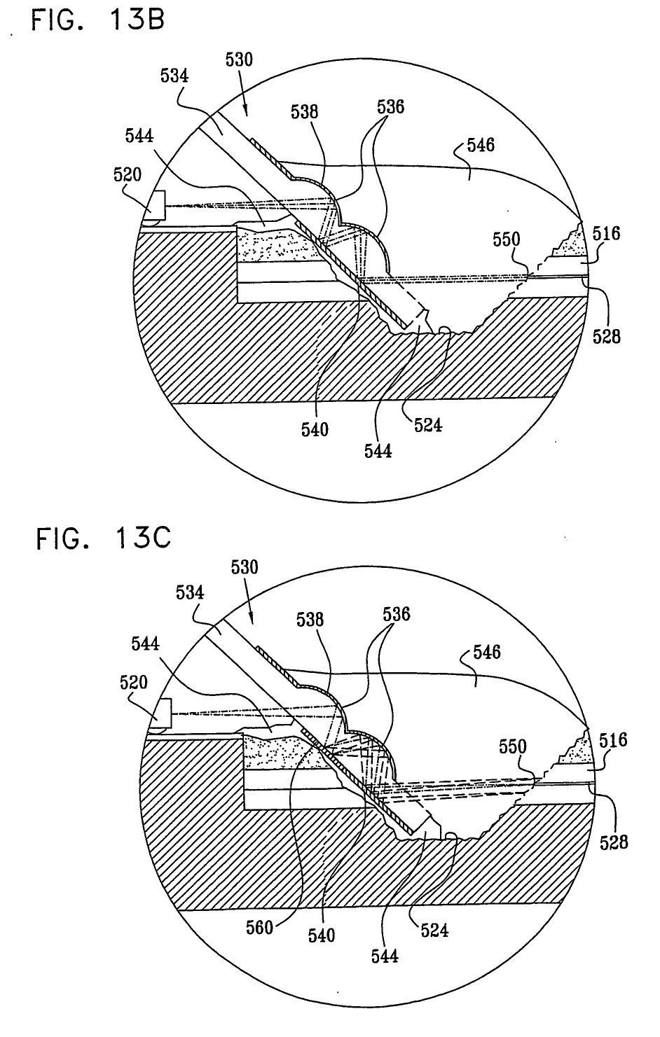

Reference is now made to FIG. 15A, which is a simplified optical illustration of FIG. 14D. Here it is seen that a generally uninterrupted optical path is defined for light, preferably in the wavelength range of 400-1650 nm, from each electro-optic component 600 through glass substrate 634 and curved portion 636 of mirror assembly 630 into reflective engagement with a curved portion 660 of layer 638 and thence through curved portion 636 and substrate 634 into reflective engagement with layer 642 and thence through multiple reflections through substrate 634 between layer 638 and layer 642, and then through substrate 634 and adhesive 646 to focus at an end 650 of a core 628. In the embodiment of FIG. 15A, the operation of the curved portion of layer 638 is to focus light exiting from electro-optic component 600 onto end 650 of core 628.

Reference is now made to FIG. 15B, which is a simplified optical illustration of FIG. 14D in accordance with a further embodiment of the present invention. In this embodiment, the curvature of the curved portion 660 of layer 638 produces collimation rather than focusing of the light exiting from electro-optic component 600 onto end 650 of core 628.

Reference is now made to FIG. 15C, which is a simplified optical illustration of FIG. 14D in accordance with yet another embodiment of the present invention wherein a grating 662 is added to the curved portion 660 of layer 638. The additional provision of grating 662 causes separation of light impinging thereon according to its wavelength, such that only one component of multispectral light exiting electro-optic component 600 is focused on end 650 of core 628.

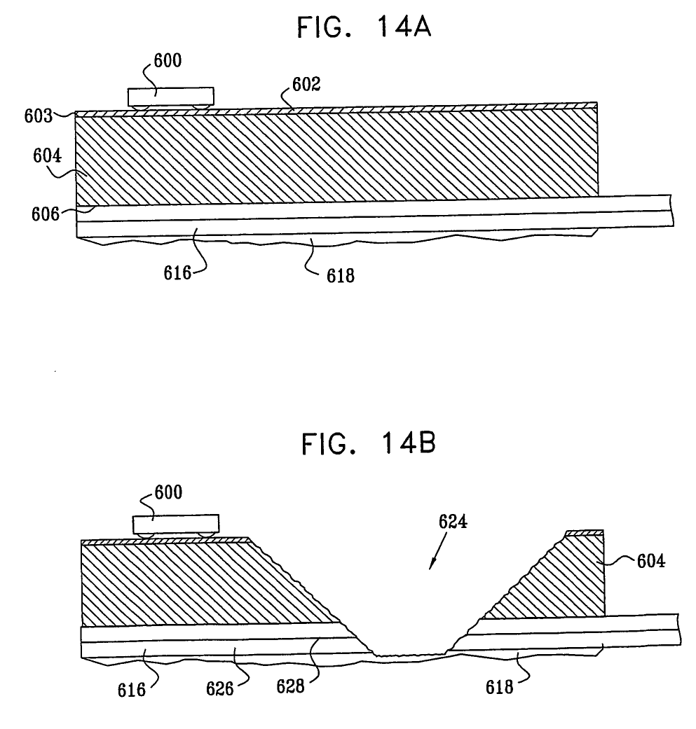

Reference is now made to FIG. 16, which is a simplified sectional illustration of an electro-optic integrated circuit constructed and operative in accordance with still another preferred embodiment of the present invention. The embodiment of FIG. 16 corresponds generally to that described hereinabove with respect to FIG. 14D other than in that a mirror with multiple concave reflective surfaces is provided rather than a mirror with a single such reflective surface. As seen in FIG. 16, it is seen that light from an electro-optic component 720, such as a diode laser, is directed onto a partially flat and partially concave mirror assembly 730, preferably mounted parallel to one of the rough inclined surfaces 732 defined by notch 724. It is appreciated that electro-optic component 720 may be any suitable electro-optic component, such as a laser diode, diode detector, waveguide, array waveguide grating or a semiconductor optical amplifier. Mirror assembly 730 preferably comprises a glass substrate 734 having formed thereon a plurality of curved portions 736 over which are formed a curved metallic layer or a dichroic filter layer 738. Mirror assembly 730 also defines a reflective surface 740, which is disposed on a planar surface 742 generally opposite layer 738.

Preferably, the mirror assembly 730 is securely held in place partially by any suitable adhesive 744, such as epoxy, and partially by an optical adhesive 746, such as OG 146, manufactured by Epoxy Technology, 14 Fortune Drive, Billerica, Mass. 01821, USA, whose refractive index preferably is precisely matched to that of the cores 728 of the optical fibers 716. It is appreciated that optical adhesive 746 may be employed throughout instead of adhesive 744.

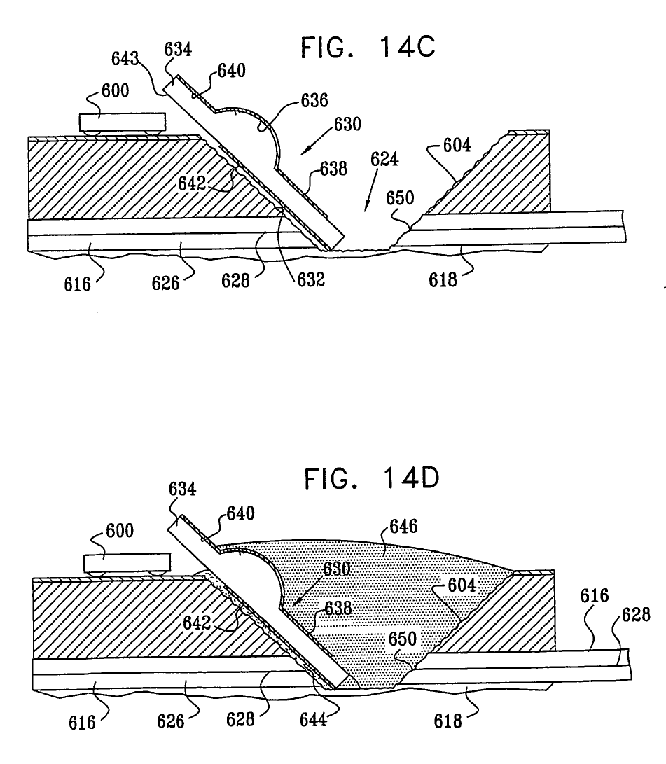

Reference is now made to FIG. 17A, which is an enlarged simplified optical illustration of a portion of FIG. 16. Here it is seen that a generally uninterrupted optical path is defined for light, preferably in the wavelength range of 400-1650 nm, from each electro-optic component 720 through glass substrate 734 of mirror assembly 730 into reflective engagement with a part of layer 738 overlying the flat portion thereof, and thence through substrate 734 to reflective surface 740, where it is reflected back through substrate 734 and a first curved portion 736 into reflective engagement with a part of layer 738 overlying first curved portion 736, and thence through first curved portion 736 and substrate 734 to reflective surface 740, where it is reflected back through substrate 734 and a second curved portion 736 to another part of layer 738 overlying second curved portion 736 and is reflected back through second curved surface 736 and substrate 734 to reflective surface 740 and thence through substrate 734 and adhesive 746 to focus at an end 750 of a core 728. In the embodiment of FIG. 17A, the operation of curved layer 738 overlying first and second curved portions 736 is to focus light exiting from electro-optic component 720 onto end 750 of core 728, with enhanced optical properties.

Reference is now made to FIG. 17B, which is an enlarged simplified optical illustration of a portion of FIG. 16 in accordance with a further embodiment of the present invention. In this embodiment, the curvature of curved layer 738 produces collimation rather than focusing of the light exiting from electro-optic component 720 onto end 750 of core 728.

Reference is now made to FIG. 17C, which is an enlarged simplified optical illustration of a portion of FIG. 16 in accordance with yet another embodiment of the present invention wherein a reflective grating 760 replaces a middle portion of reflective surface 740. The additional provision of grating 760 causes separation of light impinging thereon according to its wavelength, such that only one component of multispectral light exiting electro-optic component 720 is focused on end 750 of core 728.

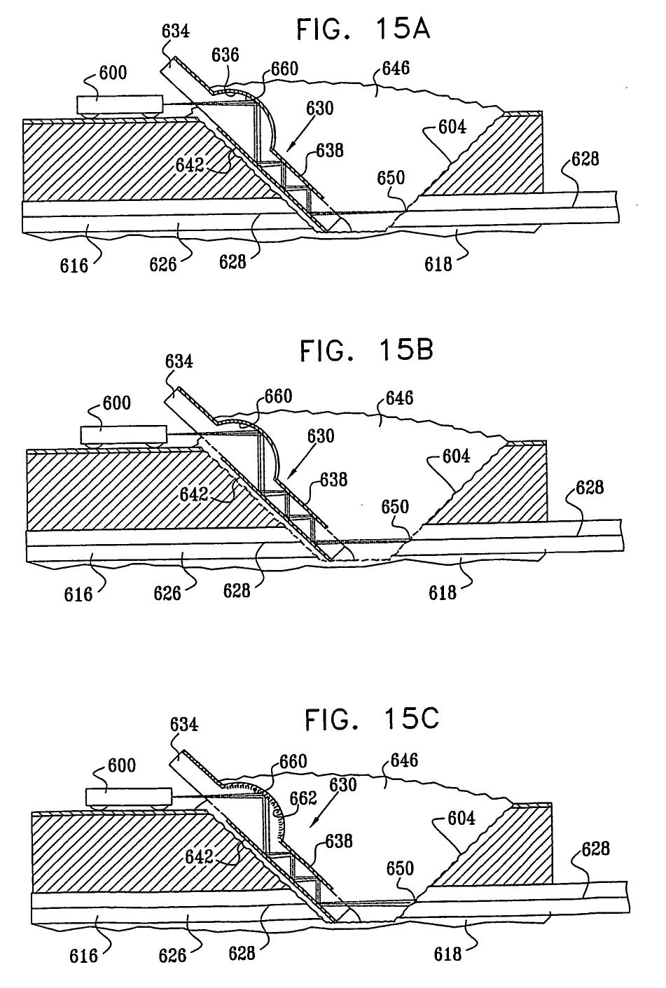

Reference is now made to FIGS. 18A, 18B, 18C and 18D, which are simplified illustrations of a method for fabricating optical elements employed in the embodiments of FIGS. 4A-6C in accordance with one embodiment of the present invention. A glass substrate 800, typically of thickness 200-400 microns, seen in FIG. 18A, has formed thereon an array of microlenses 802, typically formed of photoresist, as seen in FIG. 18B. The microlenses 802 preferably have an index of refraction which is identical or very close to that of substrate 800. This may be achieved by one or more conventional techniques, such as photolithography and thermal reflow, photolithography using of a grey scale mask, and jet printing.

A thin metal layer 804, typically aluminum, is formed over the substrate 800 and microlenses 802 as seen in FIG. 18C, typically by evaporation or sputtering. The substrate 800 and the metal layer 804 formed thereon are then diced by conventional techniques, as shown in FIG. 18D, thereby defining individual optical elements 806, each including a curved portion defined by a microlens 802.

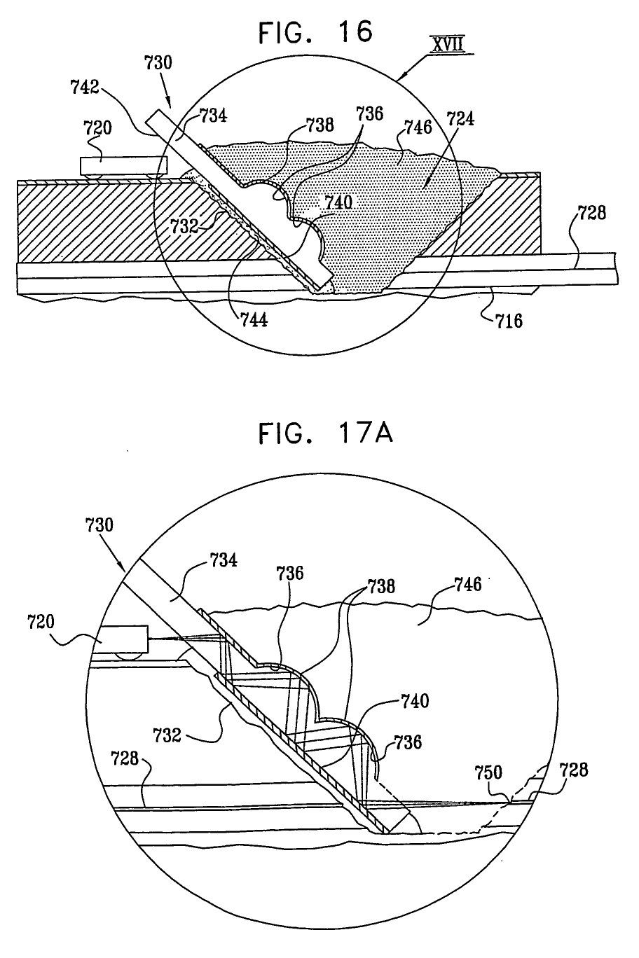

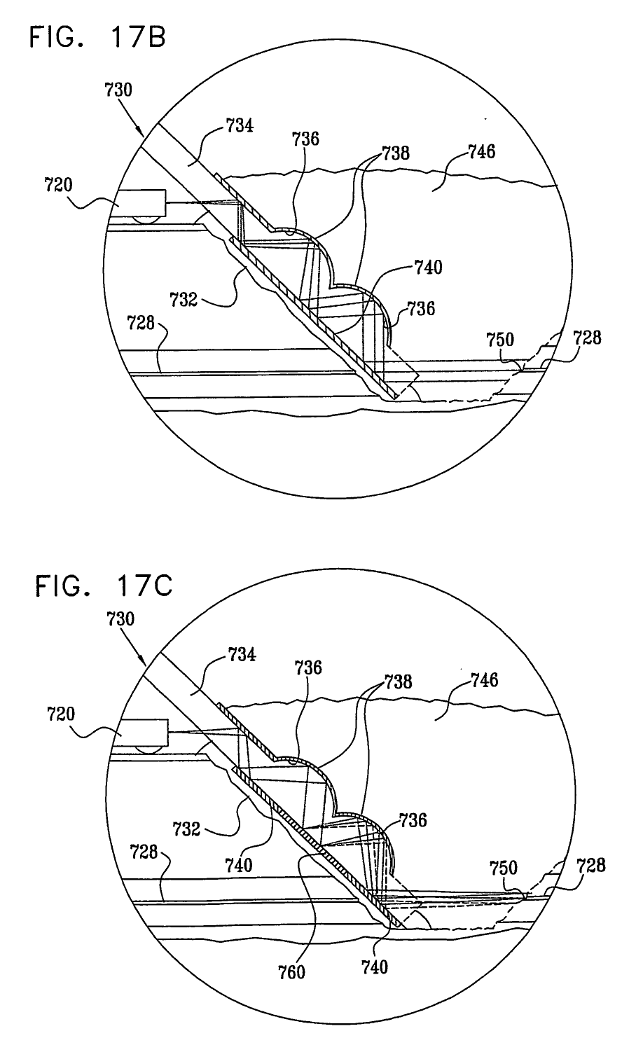

Reference is now made to FIGS. 19A, 19B, 19C, 19D and 19E, which are simplified illustrations of a method for fabricating optical elements employed in the embodiments of FIGS. 1A-6C in accordance with another embodiment of the present invention. A glass substrate 810, typically of thickness 200-400 microns, seen in FIG. 19A, has formed thereon an array of microlenses 812, typically formed of photoresist, as seen in FIG. 19B. The microlenses 812 preferably have an index of refraction which is identical or very close to that of substrate 810. This may be achieved by one or more conventional techniques, such as photolithography and thermal reflow, photolithography using of a grey scale mask, and jet printing.

A thin metal layer 814, typically aluminum, is formed over the substrate 810 and microlenses 812 as seen in FIG. 19C, typically by evaporation or sputtering. The substrate 810 is then notched from underneath by conventional techniques. As seen in FIG. 19D, notches 815 are preferably formed at locations partially underlying microlenses 812.

Following notching, the substrate 810, the microlenses 812 and the metal layer 814 formed thereon are diced by conventional techniques, as shown in FIG. 19E, thereby defining individual optical elements 816, each including a curved portion defined by part of a microlens 812.

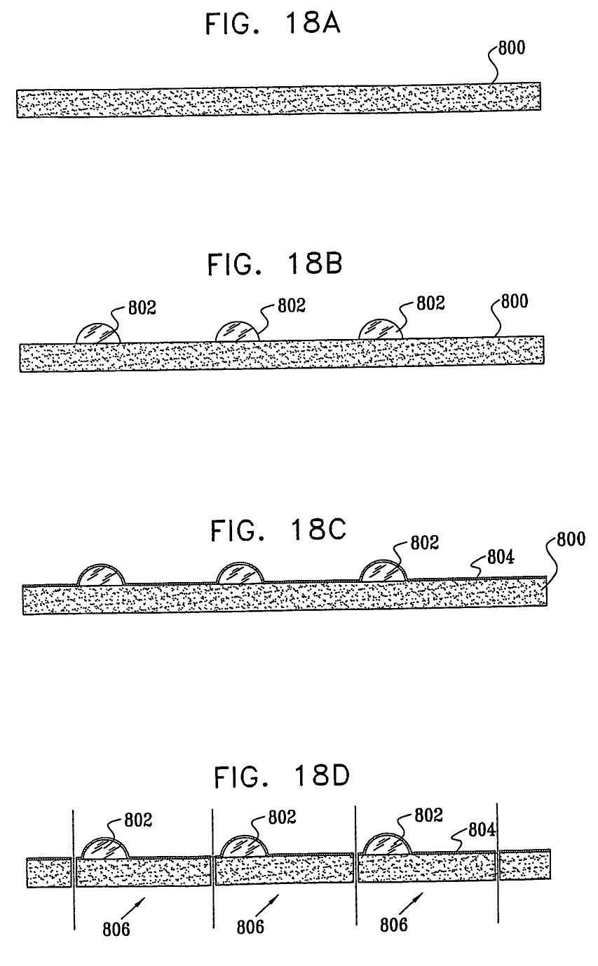

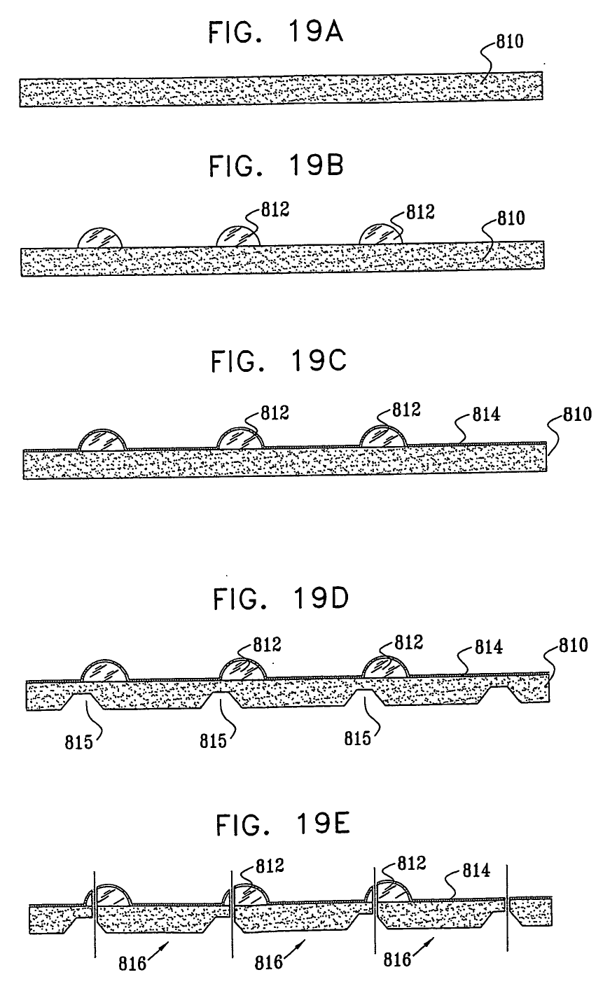

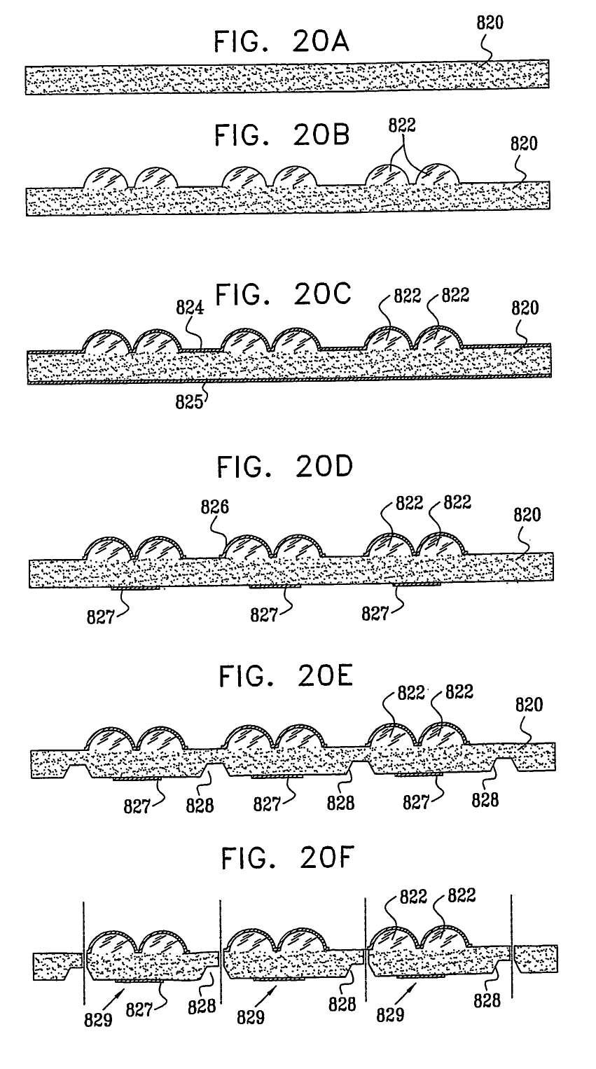

Reference is now made to FIGS. 20A, 20B, 20C, 20D, 20E and 20F, which are simplified illustrations of a method for fabricating optical elements employed in the embodiments of FIGS. 9A-17C in accordance with yet another embodiment of the present invention. A glass substrate 820, typically of thickness 200-400 microns, seen in FIG. 20A, has formed thereon an array of microlenses 822, typically formed of photoresist, as seen in FIG. 20B. The microlenses 822 preferably have an index of refraction which is identical or very close to that of substrate 820. This may be achieved by one or more conventional techniques, such as photolithography and thermal reflow, photolithography using of a grey scale mask, and jet printing.

A thin metal layer 824, typically aluminum, is formed over the substrate 820 and microlenses 822, as seen in FIG. 20C, typically by evaporation or sputtering. An additional metal layer 825, typically aluminum, is similarly formed on an opposite surface of substrate 820. Metal layers 824 and 825 are patterned typically by conventional photolithographic techniques to define respective reflective surfaces 826 and 827 as seen in FIG. 20D.

The substrate 820 is notched from underneath by conventional techniques. As seen in FIG. 20E, notches 828 need not be at locations partially underlying microlenses 822. Following notching, the substrate 820 is diced by conventional techniques, as shown in FIG. 20F, at locations intersecting inclined walls of the notches 828, thereby defining individual optical elements 829, each including a curved reflective portion defined by a pair of microlenses 822 as well as a flat reflective surface 829.

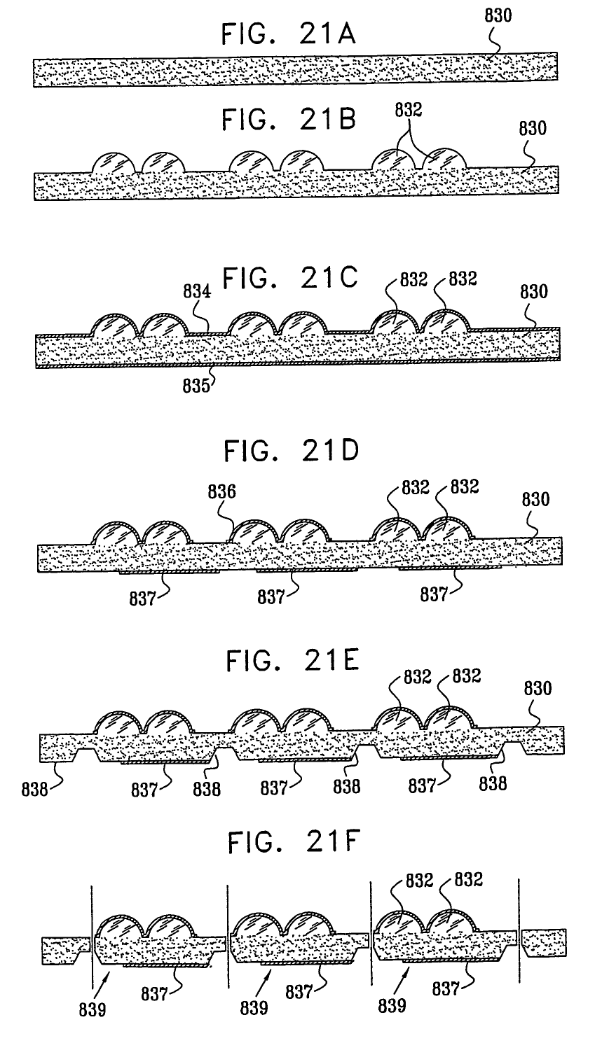

Reference is now made to FIGS. 21A, 21B, 21C, 21D, 21E and 21F which are simplified illustrations of a method for fabricating optical elements employed in the embodiments of FIGS. 1A-17C in accordance with still another embodiment of the present invention. A glass substrate 830, typically of thickness 200-400 microns, seen in FIG. 21A, has formed thereon an array of pairs of microlenses 832, typically formed of photoresist, as seen in FIG. 21B. The microlenses 832 preferably have an index of refraction which is identical or very close to that of substrate 830. This may be achieved by one or more conventional techniques, such as photolithography and thermal reflow, photolithography using of a grey scale mask, and jet printing.

A thin metal layer 834, typically aluminum, is formed over the substrate 830 and pairs of microlenses 832, as seen in FIG. 21C, typically by evaporation or sputtering. An additional metal layer 835, typically aluminum, is similarly formed on an opposite surface of substrate 830. Metal layers 834 and 835 are patterned, typically by conventional photolithographic techniques, to define respective reflective surfaces 836 and 837 as seen in FIG. 21D.

The substrate 830 is notched from underneath by conventional techniques, defining notches 838, as seen in FIG. 21E. Following notching, the substrate 830 is diced by conventional techniques, as shown in FIG. 21F, thereby defining individual optical elements 839, each including a curved reflective portion defined by a pair of microlenses 823 as well as a flat reflective surface 837.

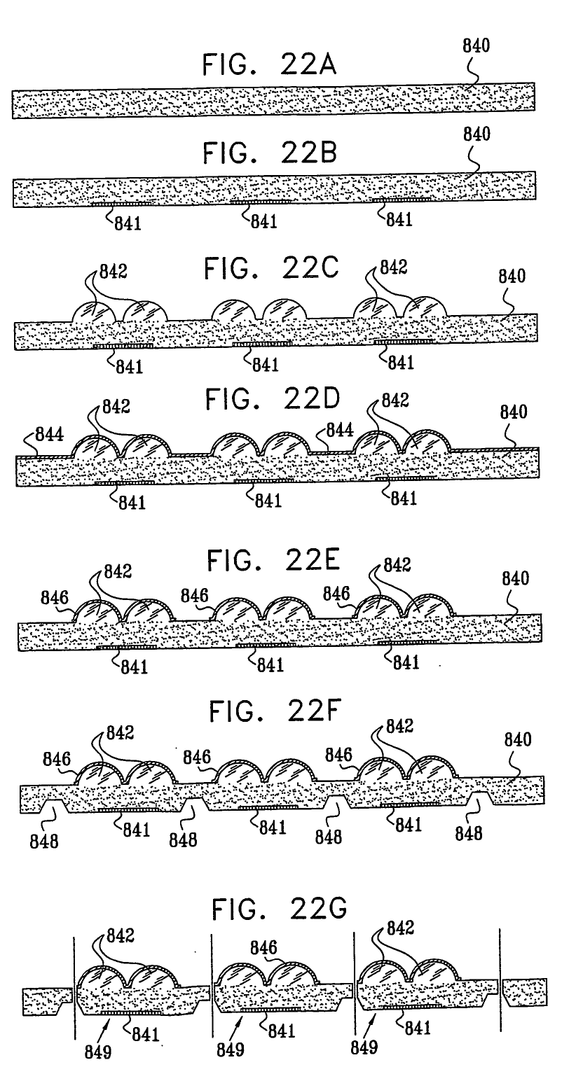

Reference is now made to FIGS. 22A, 22B, 22C, 22D, 22E, 22F and 22G, which are simplified illustrations of a method for fabricating optical elements employed in the embodiments of FIGS. 1A-8C in accordance with a further embodiment of the present invention. A glass substrate 840, typically of thickness 200-400 microns, seen in FIG. 22A, has formed in an underside surface thereof an array of reflective diffraction gratings 841, as seen in FIG. 22B, typically by etching. Alternatively, the gratings 841 may be formed on the surface of the substrate 840, typically by lithography or transfer. An array of pairs of microlenses 842, typically formed of photoresist, is formed on an opposite surface of substrate 840, as seen in FIG. 22C. The microlenses 842 preferably have an index of refraction which is identical or very close to that of substrate 840. This may be achieved by one or more conventional techniques, such as photolithography and thermal reflow, photolithography using of a grey scale mask, and jet printing.

A thin metal layer 844, typically aluminum, is formed over the substrate 840 and pairs of microlenses 842 as seen in FIG. 22D, typically by evaporation or sputtering. Metal layer 844 is preferably patterned, typically by conventional photolithographic techniques, to define a reflective surface 846, as seen in FIG. 22E.

The substrate 840 is notched from underneath by conventional techniques, defining notches 848, as seen in FIG. 22F. Following notching, the substrate 840 is diced by conventional techniques, as shown in FIG. 22G, at locations intersecting inclined walls of the notches 848, thereby defining individual optical elements 849, each including a curved reflective portion defined by a pair of microlenses 842 as well as a flat reflective grating 841.

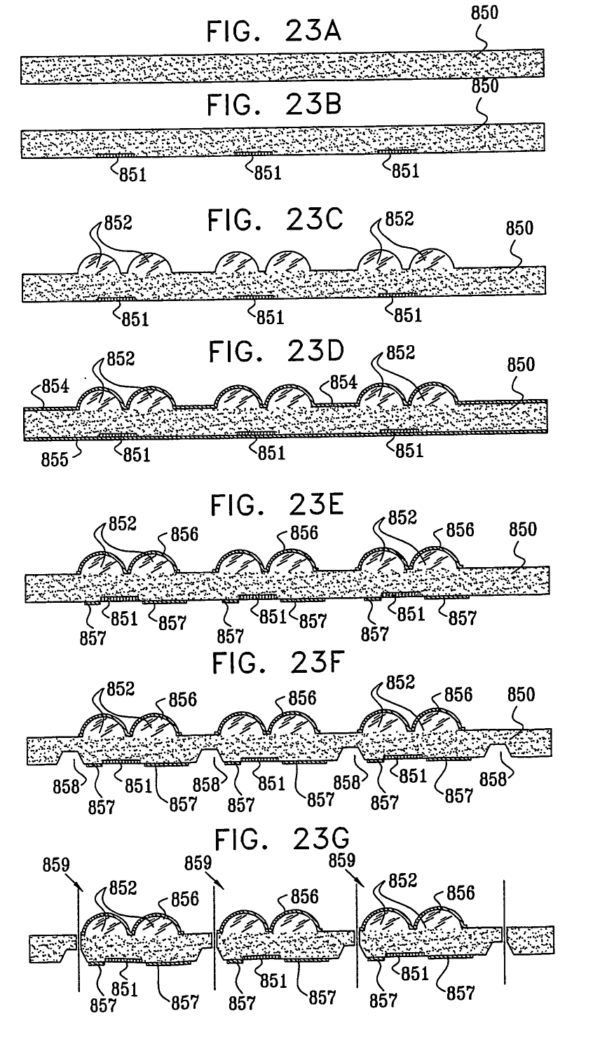

Reference is now made to FIGS. 23A, 23B, 23C, 23D, 23E, 23F and 23G, which are simplified illustrations of a method for fabricating optical elements employed in the embodiments of FIGS. 9A-17C in accordance with yet a further embodiment of the present invention. A glass substrate 850, typically of thickness 200-400 microns, seen in FIG. 23A, has formed in an underside surface thereof an array of reflective diffraction gratings 851, as seen in FIG. 23B, typically by etching. Alternatively, the gratings 851 may be formed on the surface of the substrate 850, typically by lithography or transfer. An array of pairs of microlenses 852, typically formed of photoresist, is formed on an opposite surface of substrate 850, as seen in FIG. 23C. The microlenses 852 preferably have an index of refraction which is identical or very close to that of substrate 850. This may be achieved by one or more conventional techniques, such as photolithography and thermal reflow, photolithography using of a grey scale mask, and jet printing.

A thin metal layer 854, typically aluminum, is formed over the substrate 850 and pairs of microlenses 852 as seen in FIG. 23D, typically by evaporation or sputtering. An additional metal layer 855 is similarly formed on an opposite surface of the substrate 850. Metal layers 854 and 855 are preferably patterned, typically by conventional photolithographic techniques, to define respective reflective surfaces 856 and 857, as seen in FIG. 23E.

The substrate 850 is notched from underneath by conventional techniques, defining notches 858, as seen in FIG. 23F. Following notching, the substrate 850 is diced by conventional techniques, as shown in FIG. 23G, at locations intersecting inclined walls of the notches 858, thereby defining individual optical elements 859, each including a curved reflective portion defined by a pair of microlenses 852 as well as a flat reflective grating 851 and flat reflective surfaces 857.

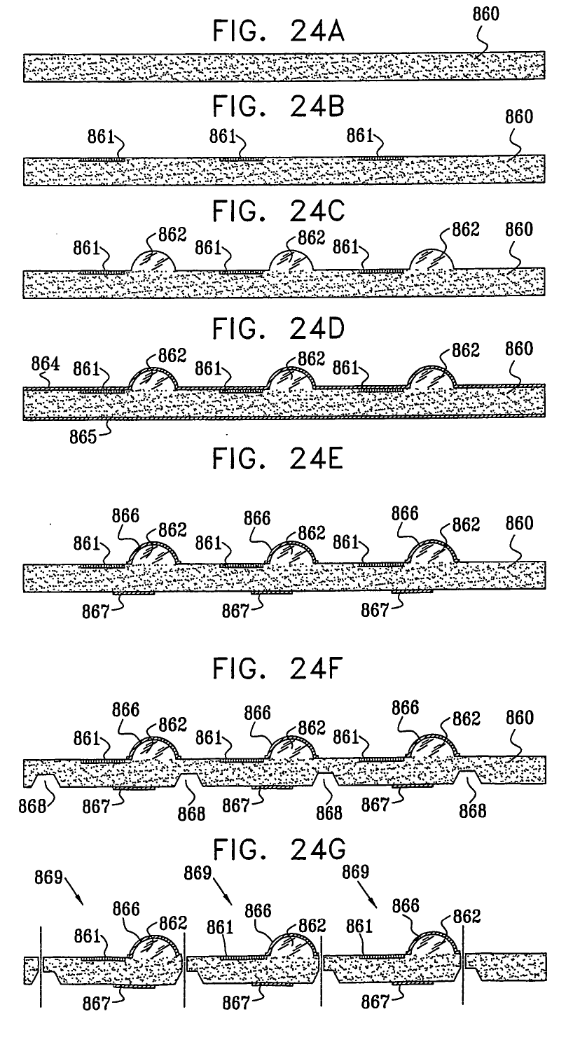

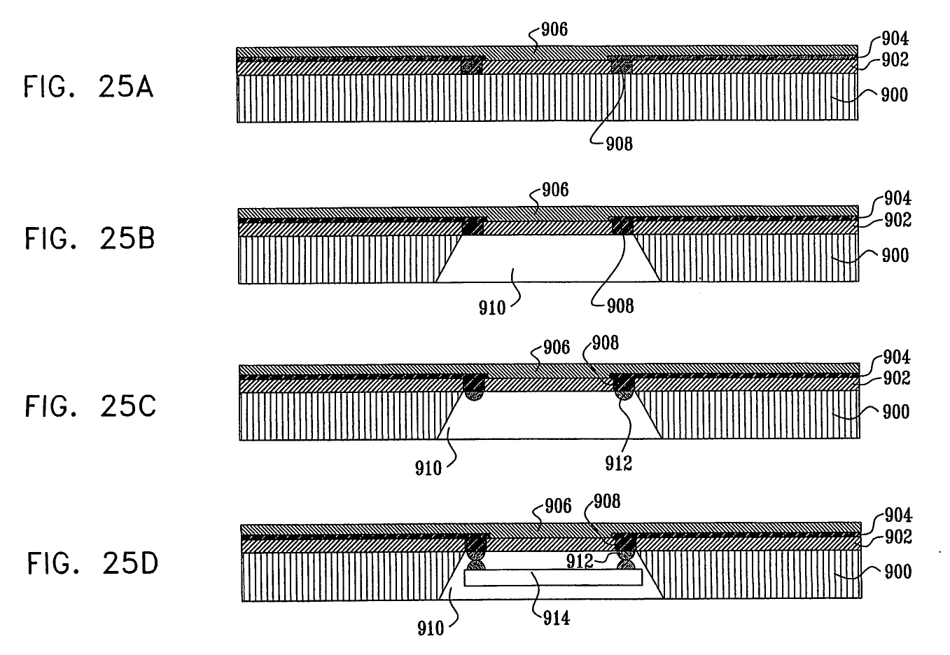

Reference is now made to FIGS. 24A, 24B, 24C, 24D, 24E, 24F and 24G, which are simplified illustrations of a method for fabricating optical elements employed in the embodiments of FIGS. 1A-17C in accordance with a still further embodiment of the present invention. A glass substrate 860, typically of thickness 200-400 microns, seen in FIG. 24A, has formed therein an array of reflective diffraction gratings 861, as seen in FIG. 24B, typically by etching. Alternatively, the gratings 861 may be formed on the surface of the substrate 860, typically by lithography or transfer. An array of microlenses 862, typically formed of photoresist, is formed on the same surface of substrate 860, as seen in FIG. 24C. The microlenses 862 preferably have an index of refraction which is identical or very close to that of substrate 860. This may be achieved by one or more conventional techniques, such as photolithography and thermal reflow, photolithography using of a grey scale mask, and jet printing.

A thin metal layer 864, typically aluminum, is formed over the substrate 860 and microlenses 862 as seen in FIG. 24D, typically by evaporation or sputtering. An additional metal layer 865 is similarly formed on an opposite surface of the substrate 860. Metal layers 864 and 865 are preferably patterned, typically by conventional photolithographic techniques, to define respective reflective surfaces 866 and 867, as seen in FIG. 24E.

The substrate 860 is notched from underneath by conventional techniques, defining notches 868, as seen in FIG. 24F. Following notching, the substrate 860 is diced by conventional techniques, as shown in FIG. 24G, at locations intersecting inclined walls of the notches 868, thereby defining individual optical elements 869, each including a curved reflective surface 866 defined by a microlens 862 as well as a flat reflective grating 861 and a flat reflective surface 867.

Reference is now made to FIGS. 25A, 25B, 25C and 25D, which are simplified illustrations of multiple stages in the production of a multi-chip module in accordance with a preferred embodiment of the present invention. As seen in FIG. 25A, a substrate 900, typically formed of silicon and having a thickness of 300-800 microns, has formed thereon at least one dielectric passivation layer 902, at least one metal layer 904 and at least one overlying dielectric layer 906. The dielectric layers are preferably transparent to light preferably in both the visible and the infrared bands. Vias 908, connected to at least one metal layer 904, extend through layer 902 to the substrate 900.

As seen in FIG. 25B, an array of openings 910 is formed by removing portions of substrate 900 at a location underlying vias 908. Preferably, the entire thickness of the substrate 900 is removed. The removal of substrate 900 may be achieved by using conventional etching techniques and, preferably, provides a volume of dimensions of at least 600 microns in width.

As seen in FIG. 25C, metallic bumps 912, preferably solder bumps, are preferably formed onto the thus exposed surfaces of vias 908. As seen in FIG. 25D, integrated circuit chips 914 are preferably located in openings 910 and operatively engaged with vias 908 by being soldered to bumps 912, thus creating a multi-chip module, wherein integrated circuit chips 914 reside within the substrate of the module.

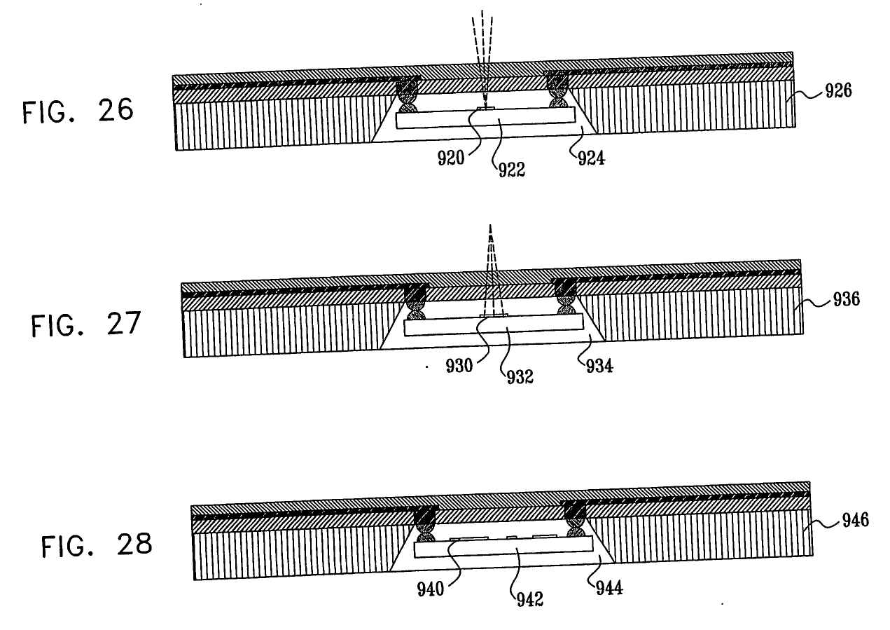

Reference is now made FIG. 26, which is a simplified illustration of a multi-chip module of the type referenced in FIGS. 25A-25D, including a laser light source 920 formed on an integrated circuit chip 922, located in an opening 924 formed in a module substrate 926.

Reference is now made to FIG. 27, which is a simplified illustration of a multi-chip module of the type referenced in FIGS. 25A-25D, including an optical detector 930 formed on an integrated circuit chip 932, located in an opening 934 formed in a module substrate 936.

Reference is now made to FIG. 28, which is a simplified illustration of a multi-chip module of the type referenced in FIGS. 25A-25D, including an electrical element 940 formed on an integrated circuit chip 942 located in an opening 944 formed in a module substrate 946.

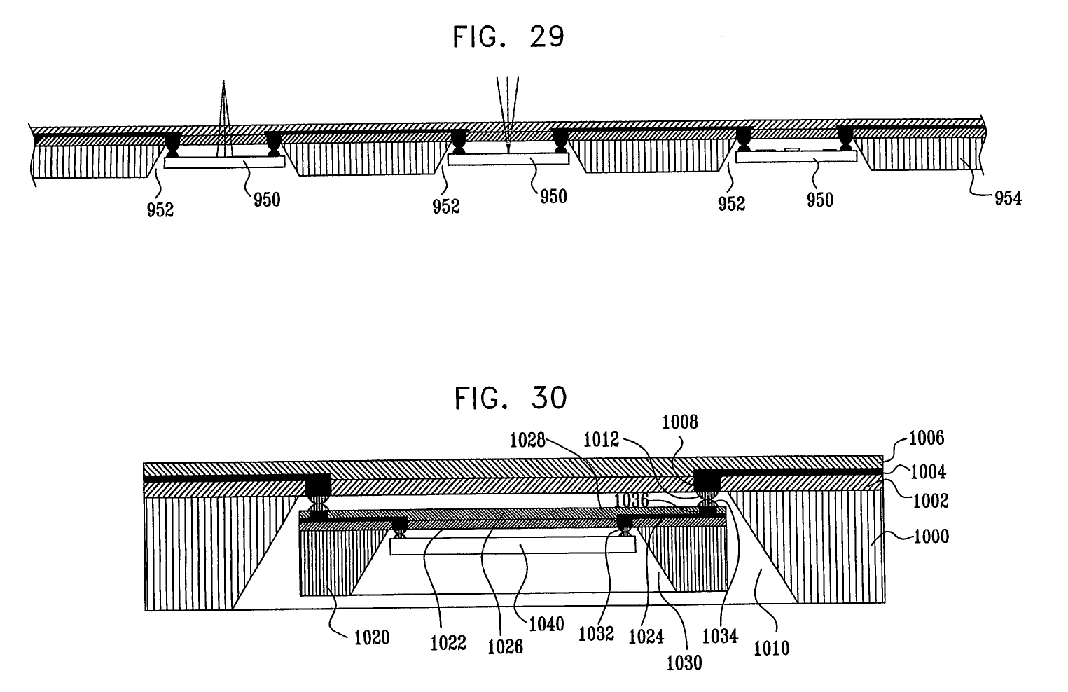

Reference is now made to FIG. 29, which is a simplified illustration of a multi-chip module of the type referenced in FIGS. 25A-25D, including multiple elements 950 located in multiple recesses 952 formed within a substrate 954. These elements may by any suitable electrical or electro-optic element.

Reference is now made to FIG. 30, which is a simplified illustration of a multi-chip module of the type referenced in FIGS. 25A-25D, including multiple stacked elements located in recesses formed within substrates. As seen in FIG. 30, a substrate 1000, typically formed of silicon and having a thickness of 500-1000 microns, has formed thereon at least one dielectric passivation layer 1002, at least one metal layer 1004 and at least one overlying dielectric layer 1006. The dielectric layers are preferably transparent to light preferably in both the visible and the infrared bands. Vias 1008, connected to at least one metal layer 1004 extend through layer 1002 to the substrate 1000. At least one opening 1010 is formed by removing a portion of substrate 1000 at a location underlying vias 1008. Preferably, the entire thickness of substrate 1000 is removed. The removal of substrate 1000 may be achieved by using conventional etching techniques and provides a volume of dimensions of at least 1000 microns in width. Metallic bumps 1012, preferably solder bumps, are preferably formed onto the thus exposed surfaces of vias 1008.

Disposed within opening 1010 is a substrate 1020, typically formed of silicon and having a thickness of 300-800 microns, having formed thereon at least one dielectric passivation layer 1022, at least one metal layer 1024 and at least one overlying dielectric layer 1026. The dielectric layers are preferably transparent to light preferably in both the visible and the infrared bands. Vias 1028, connected to at least one metal layer 1024, extend through layer 1022 to the substrate 1020. At least one opening 1030 is formed by removing portions of substrate 1020 at a location underlying vias 1028. Preferably, the entire thickness of substrate 1020 is removed. The removal of substrate 1020 may be achieved by using conventional etching techniques and provides a volume of dimensions of at least 600 microns in width. Metallic bumps 1032, preferably solder bumps, are preferably formed onto the thus exposed surfaces of vias 1028. Additional metallic bumps 1034, preferably solder bumps, are preferably formed onto ends of vias 1036 which are preferably connected to at least one metal layer 1024, which need not necessarily be connected to bumps 1032. Bumps 1012 and 1034 are preferably soldered together to mount substrate 1020 within substrate 1000.

An integrated circuit chip 1040 is preferably located in opening 1030 and operatively engaged with vias 1028 by being soldered to bumps 1032, thus creating a multi-chip module, wherein at least one integrated circuit chip 1040 resides within substrate 1020, which in turn resides within substrate 1000.

It is appreciated that any suitable number of substrates, such as substrates 1000 and 1020, may be nested within each other, as shown in FIG. 30, and that each such substrate may have multiple openings formed therein.

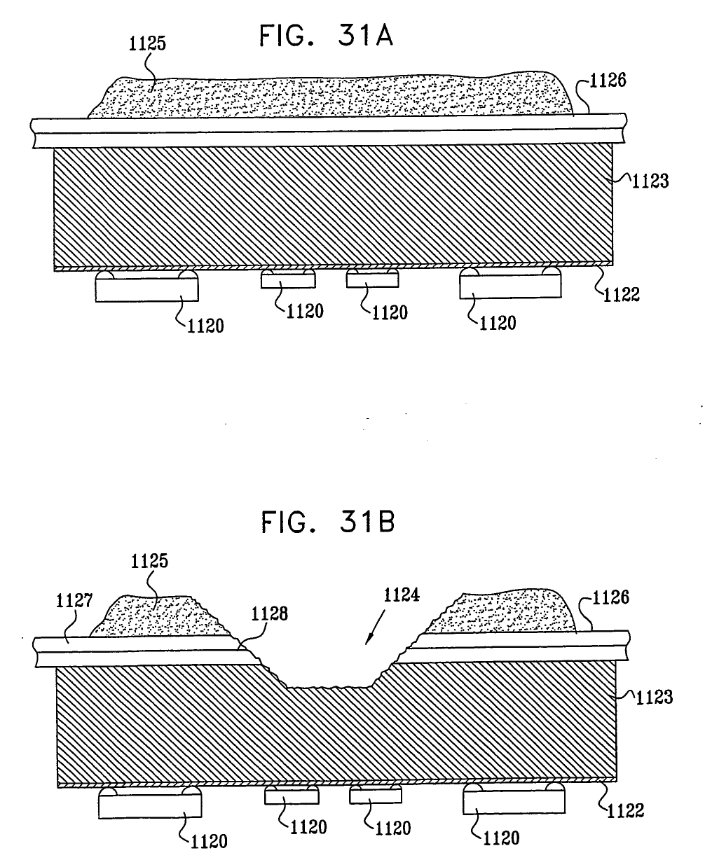

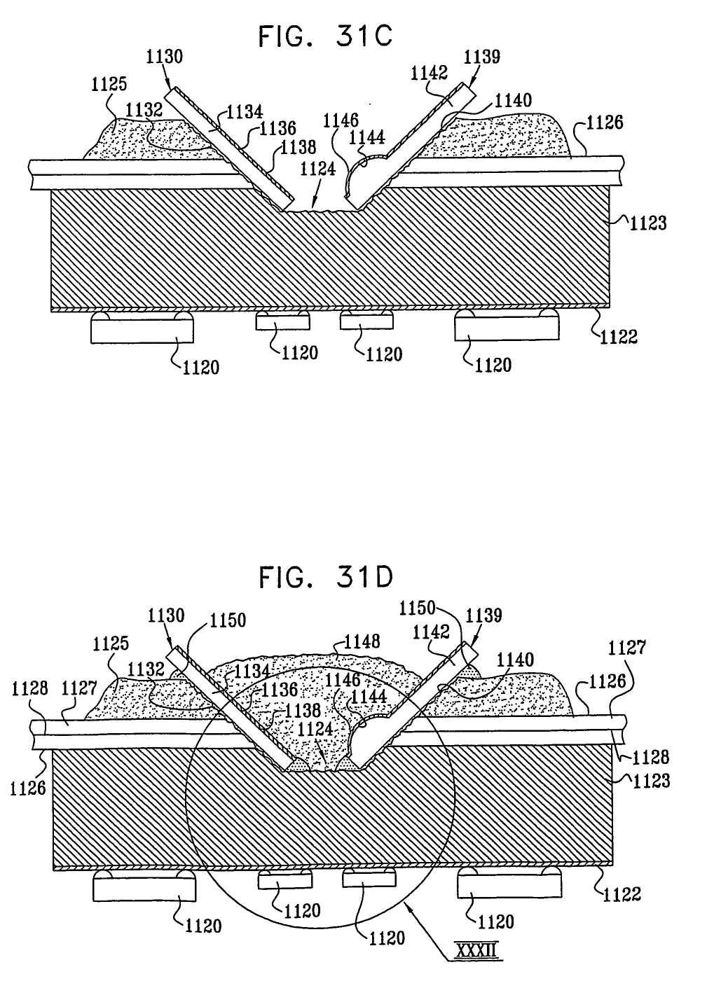

Reference is now made to FIGS. 31A, 31B, 31C and 31D, which are simplified sectional illustrations of stages in the production of an electro-optic integrated assembly in accordance with a preferred embodiment of the present invention. In the embodiment of FIG. 31A, similarly to FIG. 2A described hereinabove, electro-optic components 1120, such as diode lasers, are mounted onto an electrical circuit (not shown), included within a planarized layer 1122 formed onto a substrate 1123. It is appreciated that electro-optic components 1120 may be any suitable electro-optic component, such as a laser diode, diode detector, waveguide, array waveguide grating or a semiconductor optical amplifier.

As shown in FIG. 31B, a transverse notch 1124 is preferably formed, at least partially overlapping the locations of the electro-optic components 1120 and extending through an adhesive 1125 and partially through each of a plurality of optical fibers 1126. Specifically, in this embodiment, the notch 1124 extends entirely through the cladding 1127 of each fiber 1126 and entirely through the core 1128 of each fiber. It is appreciated that the surfaces defined by the notch 1124 are relatively rough, as shown.

Turning now to FIG. 31C, it is seen that a mirror 1130, typically of the type illustrated in FIGS. 2C and 3, is preferably mounted parallel to one of the rough inclined surfaces 1132 defined by notch 1124. Mirror 1130 preferably comprises a glass substrate 1134 having formed on a surface 1136 thereof, a metallic layer or a dichroic filter layer 1138. A partially flat and partially concave mirror 1139, typically similar to the type illustrated in FIGS. 5C and 6A, is preferably mounted parallel to an opposite one of the rough inclined surfaces, here designated 1140. Mirror 1139 preferably comprises a glass substrate 1142 having formed thereon a curved portion 1144 over which is formed a curved metallic layer or a dichroic filter layer 1146.

As seen in FIG. 31D, the mirrors 1130 and 1139 are securely held in place by any suitable adhesive 1148, such as epoxy, and partially by an optical adhesive 1150, such as OG 146, manufactured by Epoxy Technology, 14 Fortune Drive, Billerica, Mass. 01821, USA, whose refractive index preferably is precisely matched to that of the cores 1128 of the optical fibers 1126. The adhesive 1150 preferably fills the interstices between the roughened surfaces 1132 and 1140 defined by notch 1124 and respective mirrors 1130 and 1139. It is appreciated that optical adhesive 1150 may be employed throughout instead of adhesive 1148. It is noted that the index of refraction of adhesive 1150 is close to but not identical to that of substrates 1123, 1134 and 1142.

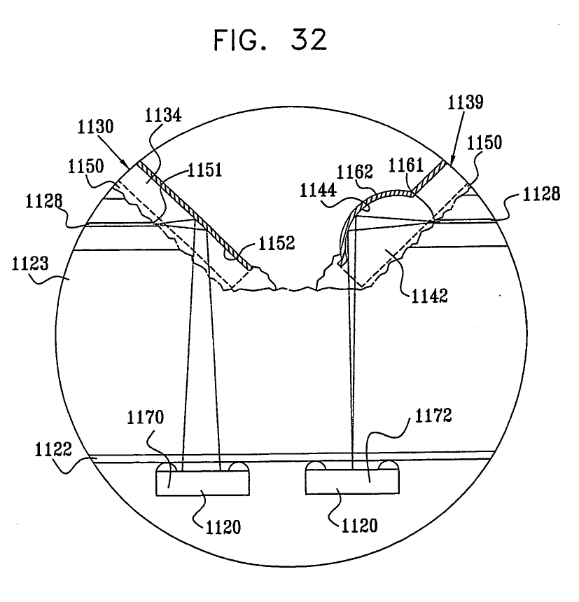

Reference is now made to FIG. 32, which is an enlarged simplified optical illustration of a portion of FIG. 31D. Here it is seen that a generally uninterrupted optical path is defined for light, preferably in the wavelength range of 600-1650 nm, from an end 1151 of a core 1128, through adhesive 1150 and glass substrate 1134 to a reflective surface 1152 of mirror 1130 and thence through glass substrate 1134, adhesive 1150, substrate 1123 and layer 1122, which are substantially transparent to this light. Similarly, a generally uninterrupted optical path is defined for light, preferably in the wavelength range of 600-1650 nm, from an end 1161 of core 1128, through adhesive 1150, glass substrate 1142 and curved portion 1144 to a reflective surface 1162 of mirror 1139 and thence through curved portion 1144, glass substrate 1142, adhesive 1150, substrate 1123 and layer 1122, which are substantially transparent to this light.

It is noted that mirror 1130 typically reflects light onto an electro-optic component 1120, here designated 1170, without focusing or collimating the light, while mirror 1139 focuses light reflected thereby onto another electro-optic component 1120, here designated 1172. It is appreciated that any suitable combination of mirrors having any suitable optical properties, such as collimating and focusing, may alternatively be employed.

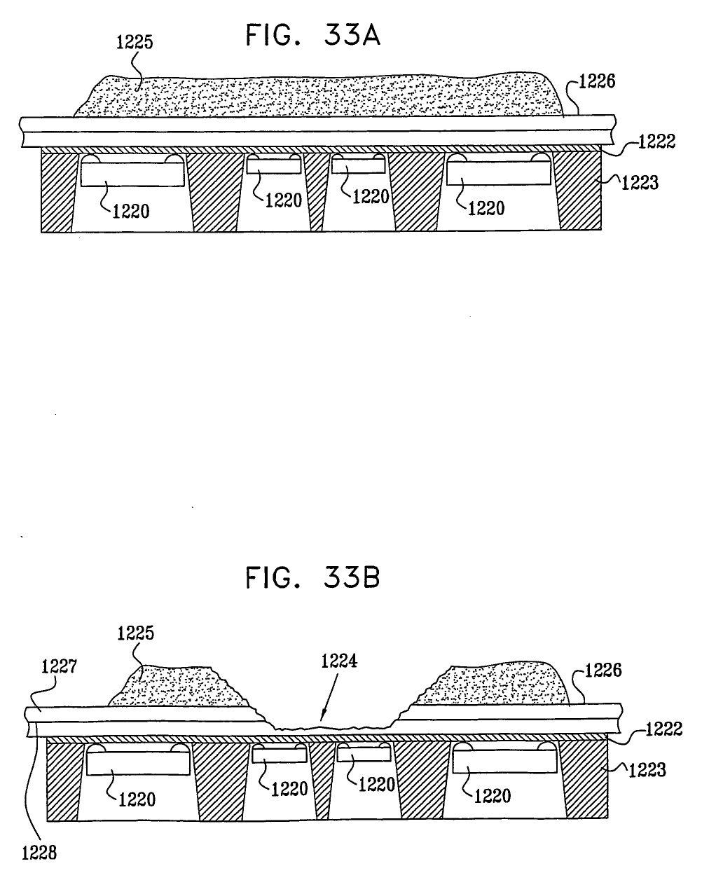

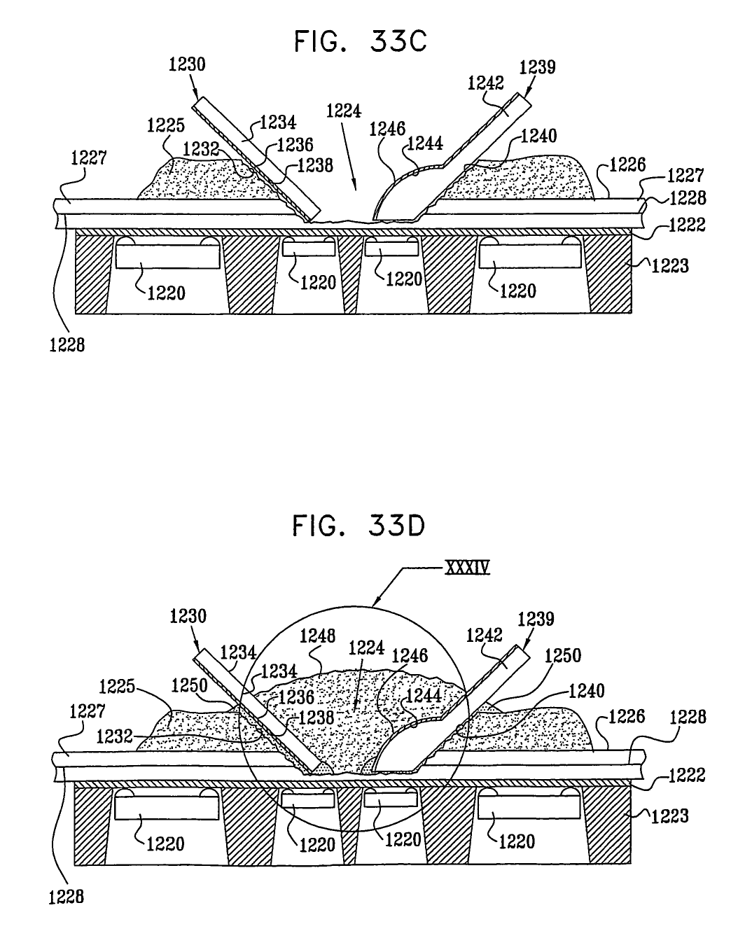

Reference is now made to FIGS. 33A, 33B, 33C and 33D, which are simplified sectional illustrations of stages in the production of an electro-optic integrated assembly in accordance with another preferred embodiment of the present invention. In the embodiment of FIG. 33A, similarly to FIG. 31A described hereinabove, electro-optic components 1220, such as diode lasers, are mounted onto an electrical circuit (not shown), included within a planarized layer 1222 formed onto a substrate 1223. It is appreciated that electro-optic components 1220 may be any suitable electro-optic component, such as a laser diode, diode detector, waveguide, array waveguide grating or a semiconductor optical amplifier. In contrast to the embodiment of FIG. 31A, here the electro-optic components 1220 are located in openings or recesses formed within the substrate 1223, similarly to the structure shown in FIG. 29.

As shown in FIG. 33B, a transverse notch 1224 is preferably formed, at least partially overlapping the locations of at least one of the electro-optic components 1220 and extending through an adhesive 1225 and partially through each of a plurality of optical fibers 1226. Specifically, in this embodiment, the notch 1224 extends through part of the cladding 1227 of each fiber 1226 and entirely through the core 1228 of each fiber. It is appreciated that the surfaces defined by the notch 1224 are relatively rough, as shown.

Turning now to FIG. 33C, it is seen that a mirror 1230, typically, similar to the type illustrated in FIGS. 2C and 3, is preferably mounted parallel to one of the rough inclined surfaces, here designated 1232, defined by notch 1224. Mirror 1230 preferably comprises a glass substrate 1234 having formed on a surface 1236 thereof, a metallic layer or a dichroic filter layer 1238. A partially flat and partially concave mirror 1239, typically similar to the type illustrated in FIGS. 5C and 6A, is preferably mounted parallel to an opposite one of the rough inclined surfaces, here designated 1240. Mirror 1239 preferably comprises a glass substrate 1242 having formed thereon a curved portion 1244 over which is formed a curved metallic layer or a dichroic filter layer 1246.

As seen in FIG. 33D, the mirrors 1230 and 1239 are securely held in place partially by any suitable adhesive 1248, such as epoxy, and partially by an optical adhesive 1250, such as OG 146, manufactured by Epoxy Technology, 14 Fortune Drive, Billerica, Mass. 01821, USA, whose refractive index preferably is precisely matched to that of the cores 1228 of the optical fibers 1226. The adhesive 1250 preferably fills the interstices between the roughened surfaces 1232 and 1240 defined by notch 1224 and respective mirrors 1230 and 1239. It is appreciated that optical adhesive 1250 may be employed throughout instead of adhesive 1248. It is noted that the index of refraction of adhesive 1250 is close to but not identical to that of cladding 1227, substrate 1242 and curved portion 1244.

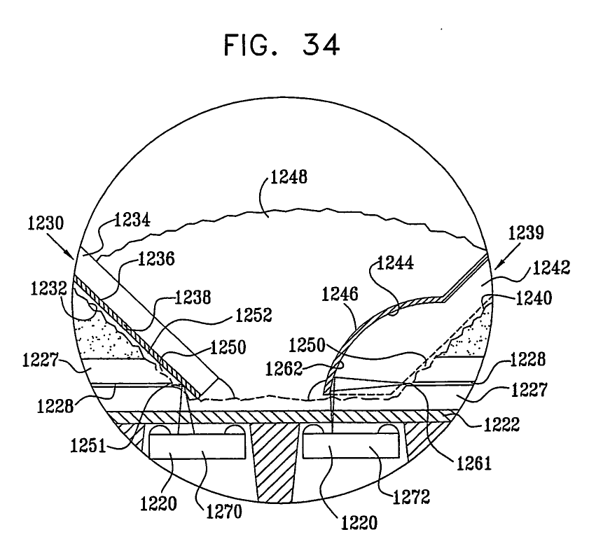

Reference is now made to FIG. 34, which is an enlarged simplified optical illustration of a portion of FIG. 33D. Here it is seen that a generally uninterrupted optical path is defined for light, preferably in the wavelength range of 600-1650 nm, from an end 1251 of a core 1228, through adhesive 1250 to a reflective surface 1252 of mirror 1230 and thence through adhesive 1250 and cladding 1227, and then through layer 1222, which is substantially transparent to this light. Similarly, a generally uninterrupted optical path is defined for light, preferably in the wavelength range of 600-1650 nm, from an end 1261 of core 1228, through adhesive 1250, substrate 1242 and curved portion 1244, to a reflective surface 1262 of mirror 1239 and thence through curved portion 1244, adhesive 1250 and cladding 1227, and then through layer 1222, which is substantially transparent to this light.

It is noted that mirror 1230 typically reflects light onto an electro-optic component 1220, here designated 1270, without focusing or collimating the light, while mirror 1239 focuses light reflected thereby onto another electro-optic component 1220, here designated 1272. It is appreciated that any suitable combination of mirrors having any suitable optical properties, such as collimating and focusing, may alternatively be employed.

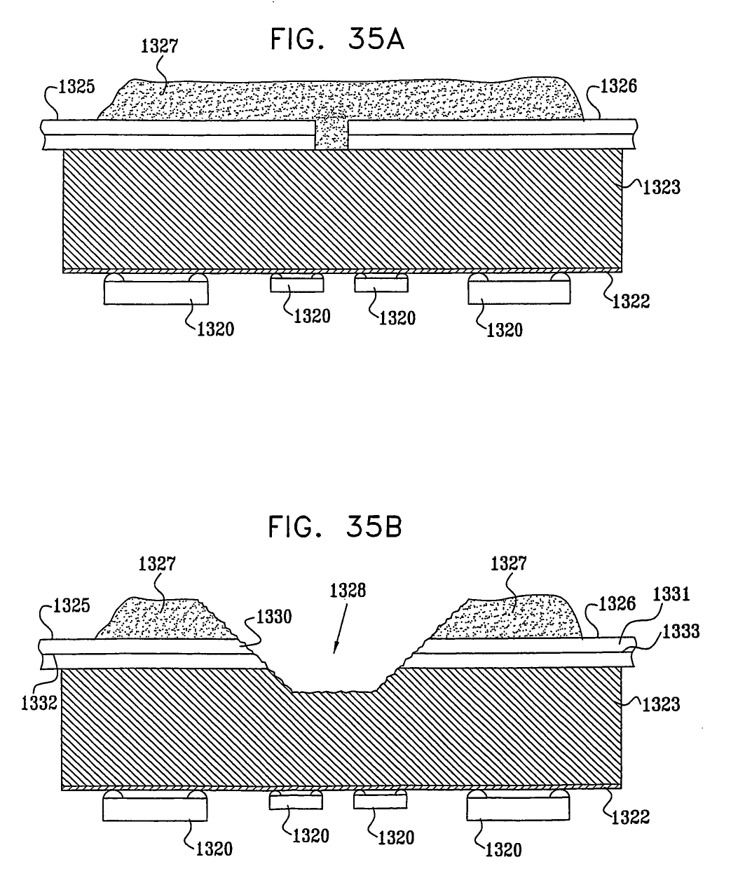

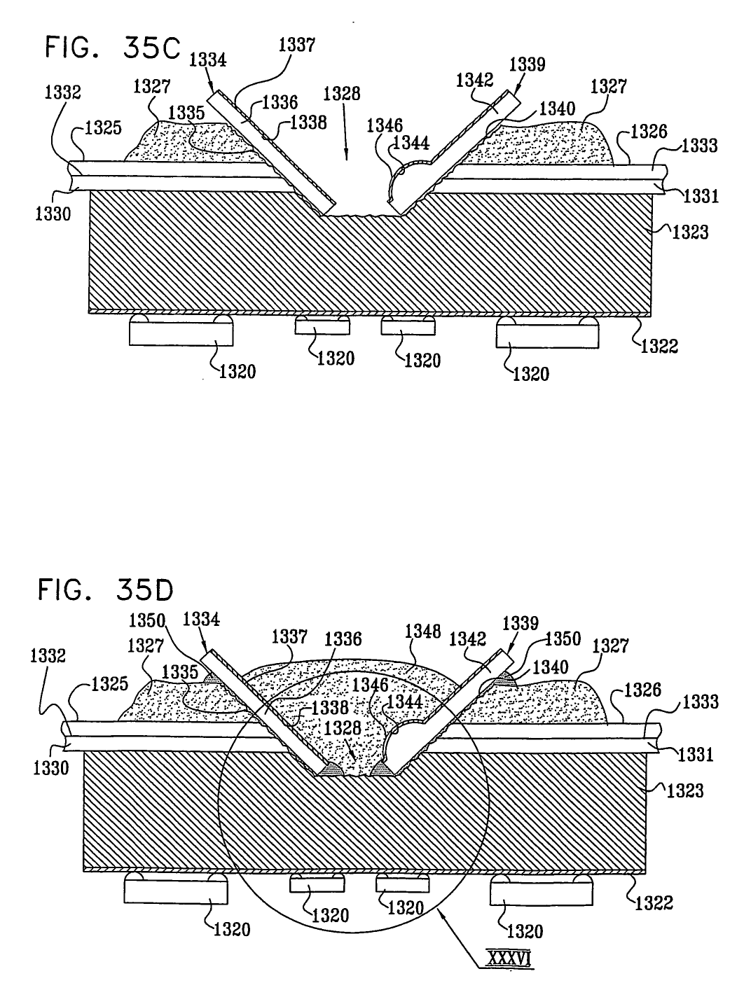

Reference is now made to FIGS. 35A, 35B, 35C and 35D, which are simplified sectional illustrations of stages in the production of an electro-optic integrated assembly in accordance with a preferred embodiment of the present invention. In the embodiment of FIG. 35A, similarly to FIG. 31A described hereinabove, electro-optic components 1320, such as diode lasers, are mounted onto an electrical circuit (not shown), included within a planarized layer 1322 formed onto a substrate 1323. It is appreciated that electro-optic components 1320 may be any suitable electro-optic component, such as a laser diode, diode detector, waveguide, array waveguide grating or a semiconductor optical amplifier. As distinct from the embodiment of FIGS. 31A-32, here at least first and second separate fibers 1325 and 1326 are fixed to substrate 1323, preferably by an adhesive 1327. The fibers 1325 and 1326 may be identical, similar or different, and need not be arranged in a mutually aligned spatial relationship.

As shown in FIG. 35B, a transverse notch 1328 is preferably formed, at least partially overlapping the locations of the electro-optic components 1320 and extending through adhesive 1327 and partially through at least each of optical fibers 1325 and 1326. Specifically, in this embodiment, the notch 1328 extends entirely through of the cladding 1330 and 1331 and entirely through the cores 1332 and 1333 of fibers 1325 and 1326 respectively. It is appreciated that the surfaces defined by the notch 1328 are relatively rough, as shown.

Turning now to FIG. 35C, it is seen that a mirror 1334, typically of the type illustrated in FIGS. 2C and 3, is preferably mounted parallel to one of the rough inclined surfaces 1335 defined by notch 1328. Mirror 1334 preferably comprises a glass substrate 1336 having formed on a surface 1337 thereof, a metallic layer or a dichroic filter layer 1338. A partially flat and partially concave mirror 1339, typically similar to the type illustrated in FIGS. 5C and 6A, is preferably mounted parallel to an opposite one of the rough inclined surfaces, here designated 1340. Mirror 1339 preferably comprises a glass substrate 1342 having formed thereon a curved portion 1344 over which is formed a curved metallic layer or a dichroic filter layer 1346.

As seen in FIG. 35D, the mirrors 1334 and 1339 are securely held in place partially by any suitable adhesive 1348, such as epoxy, and partially by optical adhesive 1350, such as OG 146, manufactured by Epoxy Technology, 14 Fortune Drive, Billerica, Mass. 01821, USA, whose refractive indices preferably are precisely matched to those of the cores 1332 and 1333 of the optical fibers 1325 and 1326 respectively. The adhesive 1350 preferably fills the interstices between the roughened surfaces 1335 and 1340 defined by notch 1328 and respective mirrors 1334 and 1339. It is appreciated that optical adhesive 1350 may also be employed instead of adhesive 1348. It is noted that the index of refraction of adhesive 1350 is close to but not identical to that of substrates 1323, 1336 and 1342.

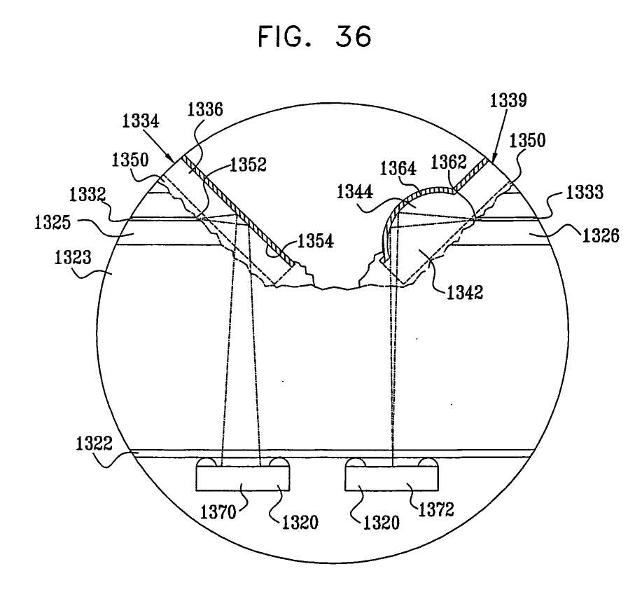

Reference is now made to FIG. 36, which is an enlarged simplified optical illustration of a portion of FIG. 35D. Here it is seen that a generally uninterrupted optical path is defined for light, preferably in the wavelength range of 600-1650 nm, from an end 1352 of a core 1332 of a fiber 1325, through adhesive 1350 and substrate 1336 to a reflective surface 1354 of mirror 1334 and thence through substrate 1336, adhesive 1350, substrate 1323 and layer 1322, which are substantially transparent to this light. Similarly, a generally uninterrupted optical path is defined for light, preferably in the wavelength range of 600-1650 nm, from an end 1362 of core 1333 of fiber 1326, through adhesive 1350, substrate 1342 and curved portion 1344 to a reflective surface 1364 of mirror 1339 and thence through curved portion 1344, substrate 1342, adhesive 1350, substrate 1323 and layer 1322, which are substantially transparent to this light.

It is noted that mirror 1334 typically reflects light onto an electro-optic component 1320, here designated 1370, without focusing or collimating the light, while mirror 1339 focuses light reflected thereby onto another electro-optic component 1320, here designated 1372. It is appreciated that any suitable combination of mirrors having any suitable optical properties, such as collimating and focusing, may alternatively be employed.

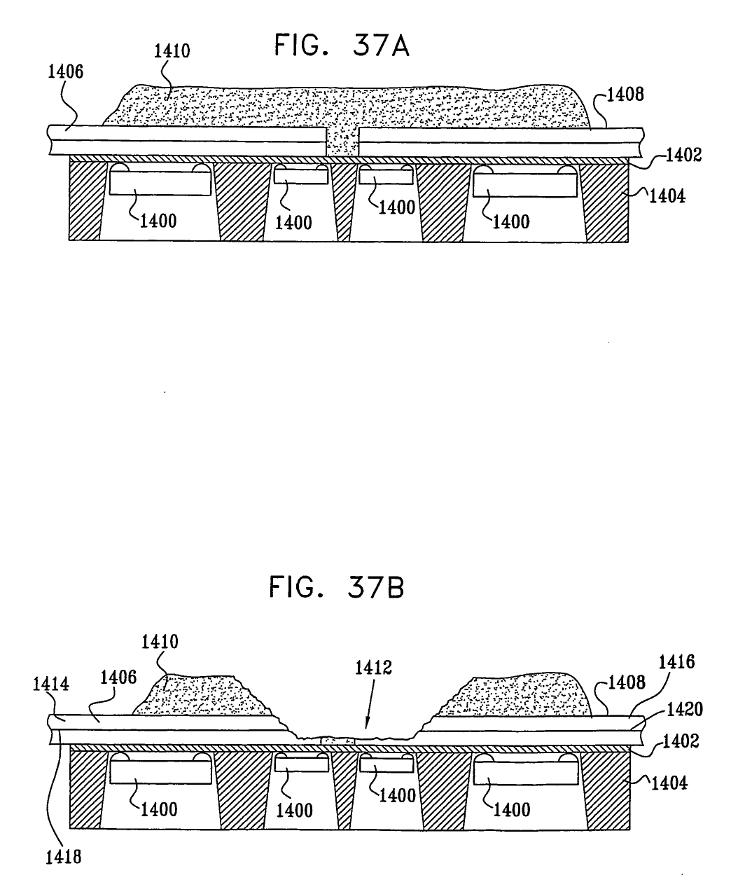

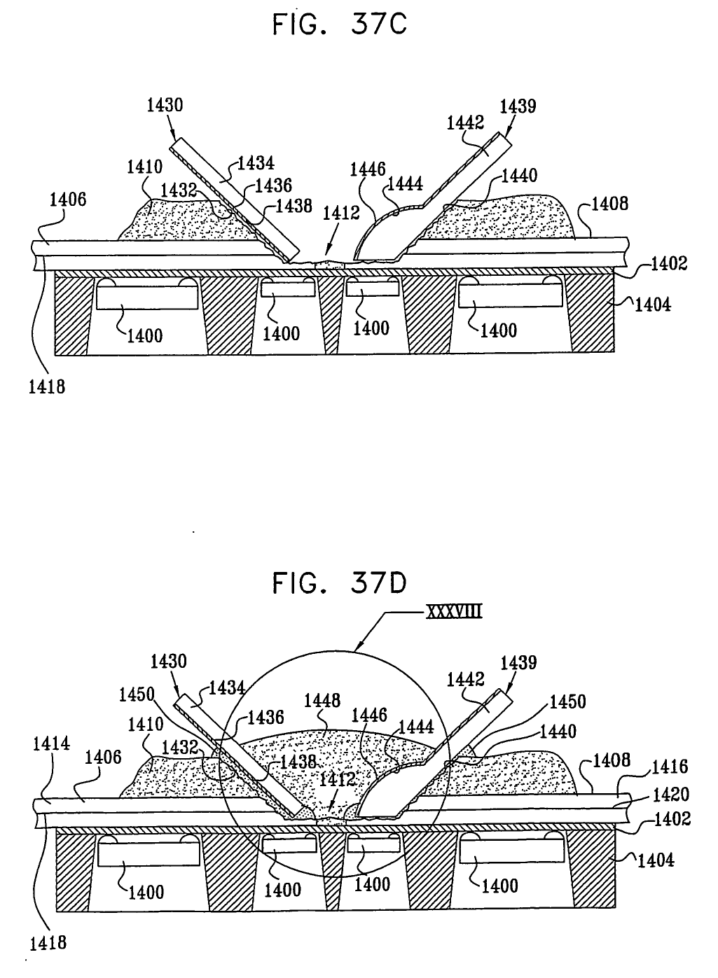

Reference is now made to FIGS. 37A, 37B, 37C and 37D, which are simplified sectional illustrations of stages in the production of an electro-optic integrated assembly in accordance with another preferred embodiment of the present invention. The embodiment of FIGS. 37A-37D is similar to the embodiments of FIGS. 33A-33D and 35A-35D, described hereinabove. As shown in FIG. 37A, electro-optic components 1400, such as diode lasers, are mounted onto an electrical circuit (not shown), included within a planarized layer 1402 formed onto a substrate 1404. It is appreciated that electro-optic components 1400 may be any suitable electro-optic component, such as a laser diode, diode detector, waveguide, array waveguide grating and a semiconductor optical amplifier. In contrast to the embodiment of FIG. 35A, here the electro-optic components 1400 are located in openings or recesses formed within the substrate 1404, similarly to the structure shown in FIG. 33A. As distinct from the embodiment of FIG. 33A, here at least first and second separate fibers 1406 and 1408 are fixed to substrate 1404, preferably by an adhesive 1410, similarly to the structure shown in FIG. 35A. The fibers 1406 and 1408 may be identical, similar or different and need not be arranged in a mutually aligned spatial relationship.

As shown in FIG. 37B, a transverse notch 1412 is preferably formed, at least partially overlapping the locations of at least one of the electro-optic components 1400 and extending through an adhesive 1410 and partially through each of a plurality of optical fibers 1406 and 1408. Specifically, in this embodiment, the notch 1412 extends through part of the claddings 1414 and 1416 and entirely through the cores 1418 and 1420 of fibers 1406 and 1408, respectively. It is appreciated that the surfaces defined by the notch 1412 are relatively rough, as shown.

Turning now to FIG. 37C, it is seen that a mirror 1430, typically, similar to the type illustrated in FIGS. 2C and 3, is preferably mounted parallel to one of the rough inclined surfaces, here designated 1432, defined by notch 1412. Mirror 1430 preferably comprises a glass substrate 1434 having formed on a surface 1436 thereof, a metallic layer or a dichroic filter layer 1438. A partially flat and partially concave mirror 1439, typically similar to the type illustrated in FIGS. 5C and 6A, is preferably mounted parallel to an opposite one of the rough inclined surfaces, here designated 1440. Mirror 1439 preferably comprises a glass substrate 1442 having formed thereon a curved portion 1444 over which is formed a curved metallic layer or a dichroic filter layer 1446.

As seen in FIG. 37D, the mirrors 1430 and 1439 are securely held in place partially by any suitable adhesive 1448, such as epoxy, and partially by an optical adhesive 1450, such as OG 146, manufactured by Epoxy Technology, 14 Fortune Drive, Billerica, Mass. 01821, USA, whose refractive index preferably is precisely matched to that of the cores 1418 and 1420 of the optical fibers 1406 and 1408, respectively. The adhesive 1450 preferably fills the interstices between the roughened surfaces 1432 and 1440 defined by notch 1412 and respective mirrors 1430 and 1439. It is appreciated that optical adhesive 1450 may be employed throughout instead of adhesive 1448. It is noted that the index of refraction of adhesive 1450 is close to but not identical to that of the curved portion 1444, substrate 1442 and claddings 1414 and 1416 of the optical fibers 1406 and 1408, respectively.

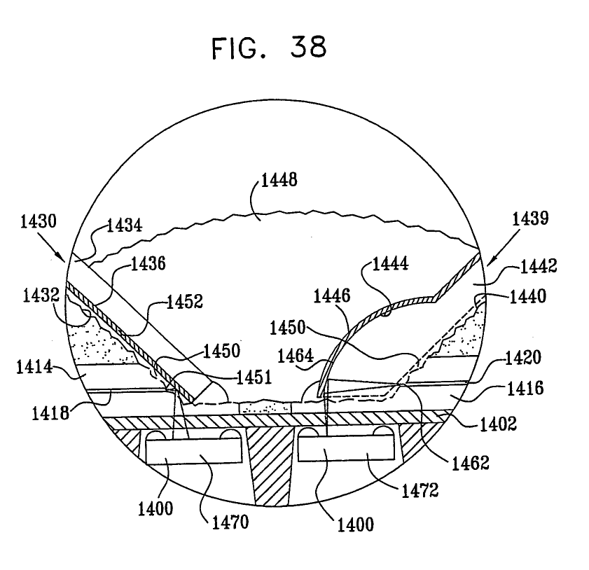

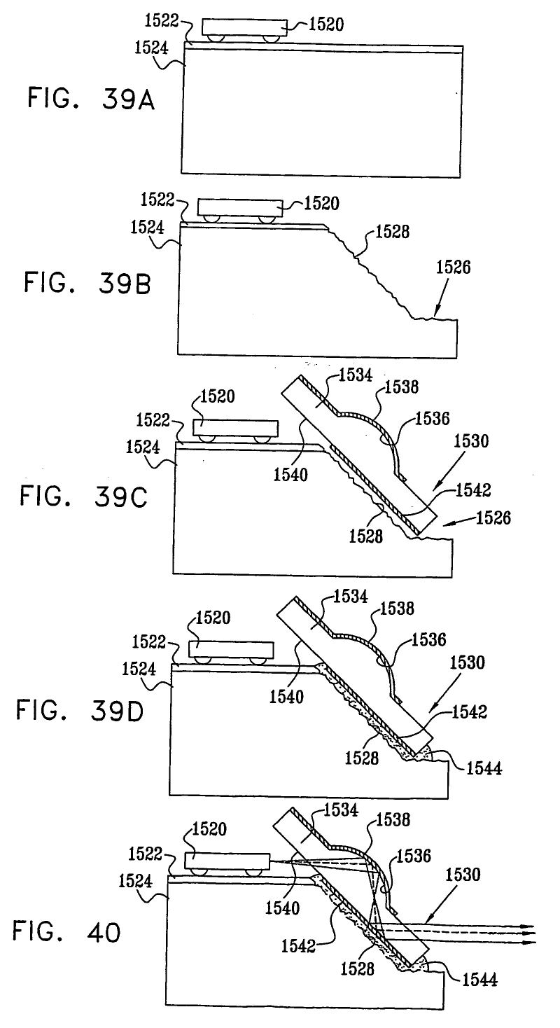

Reference is now made to FIG. 38, which is an enlarged simplified optical illustration of a portion of FIG. 37D. Here it is seen that a generally uninterrupted optical path is defined for light, preferably in the wavelength range of 600-1650 mm, from an end 1451 of a core 1418, through adhesive 1450 to a reflective surface 1452 of mirror 1430 and thence through adhesive 1450 and cladding 1414, through layer 1402, which is substantially transparent to this light. Similarly, a generally uninterrupted optical path is defined for light, preferably in the wavelength range of 600-1650 nm, from an end 1462 of core 1420, through adhesive 1450, substrate 1442 and curved portion 1444 to a reflective surface 1464 of mirror 1439 and thence through curved portion 1444, adhesive 1450 and cladding 1416, through layer 1402, which is substantially transparent to this light.

It is noted that mirror 1430 typically reflects light onto an electro-optic component 1400, here designated 1470, without focusing or collimating the light, while mirror 1439 focuses light reflected thereby onto another electro-optic component 1400, here designated 1472. It is appreciated that any suitable combination of mirrors having any suitable optical properties, such as collimating and focusing, may alternatively be employed.

Reference is now made to FIGS. 39A, 39B, 39C, and 39D, which are simplified sectional illustrations of stages in the production of an electro-optic integrated circuit in accordance with another preferred embodiment of the present invention. As seen in FIG. 39A, electro-optic components 1520, such as a diode laser, are each mounted onto an electrical circuit (not shown), included within a planarized layer 1522 formed onto substrate 1524. It is appreciated that electro-optic components 1520 may be any suitable electro-optic component, such as a laser diode, diode detector, waveguide, array waveguide grating or a semiconductor optical amplifier.

As shown in FIG. 39B, a transverse cut 1526 is preferably formed to extend partially through the substrate 1524. It is appreciated that a surface 1528 defined by the cut 1526 is relatively rough, as shown.

Turning now to FIG. 39C, it is seen that a partially flat and partially concave mirror assembly 1530 is preferably mounted parallel to the rough inclined surface 1528 defined by the cut 1526. Mirror assembly 1530 preferably comprises a glass substrate 1534 having formed thereon a curved portion 1536 over which is formed a curved metallic layer or a dichroic filter layer 1538. Mirror assembly 1530 also defines a flat surface 1540, having formed thereon a metallic layer or a dichroic filter layer 1542 partially underlying the curved portion 1536. As seen in FIG. 39D, preferably, the mirror assembly 1530 is securely held in place by any suitable adhesive 1544, such as epoxy.

Reference is now made to FIG. 40, which is a simplified optical illustration corresponding to FIG. 39D. Here it is seen that a generally uninterrupted optical path is defined for light, preferably in the wavelength range of 400-165 nm, from each electro-optic component 1520 through glass substrate 1534 and curved portion 1536 of mirror assembly 1530 into reflective engagement with layer 1538 and thence through curved portion 1536 and substrate 1534 to layer 1542 and reflected from layer 1542 through substrate 1534 as a parallel beam.

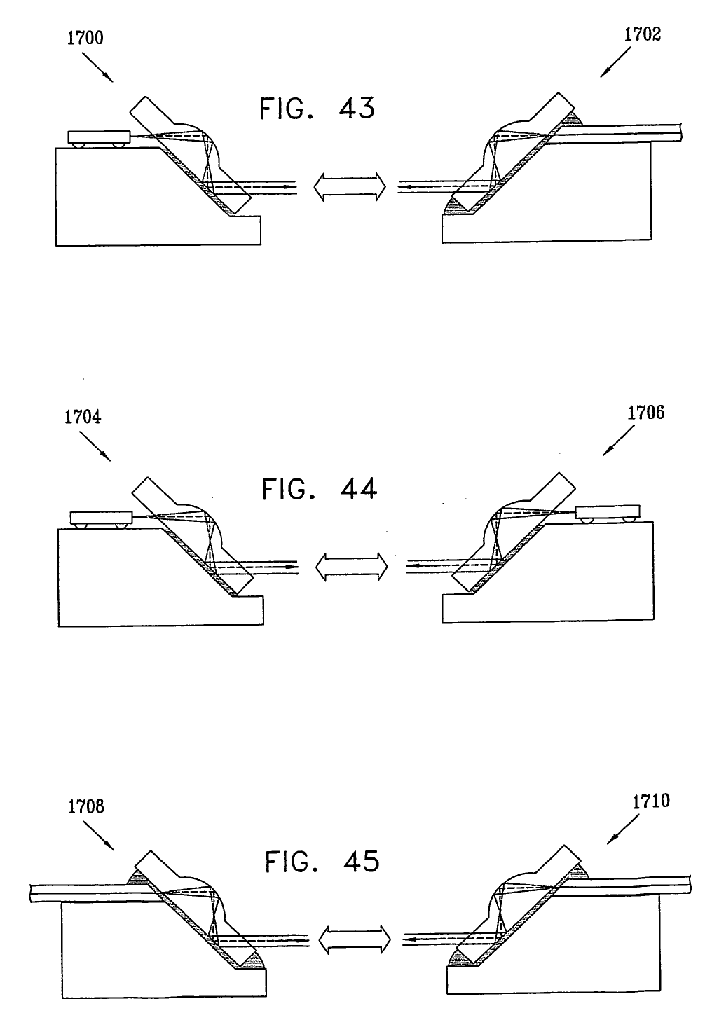

It is appreciated that the electro-optic integrated circuit described in reference to FIGS. 39A-40 may be configured to operate as either a light transmitter or a light receiver, as described hereinbelow with reference to FIGS. 43-45.

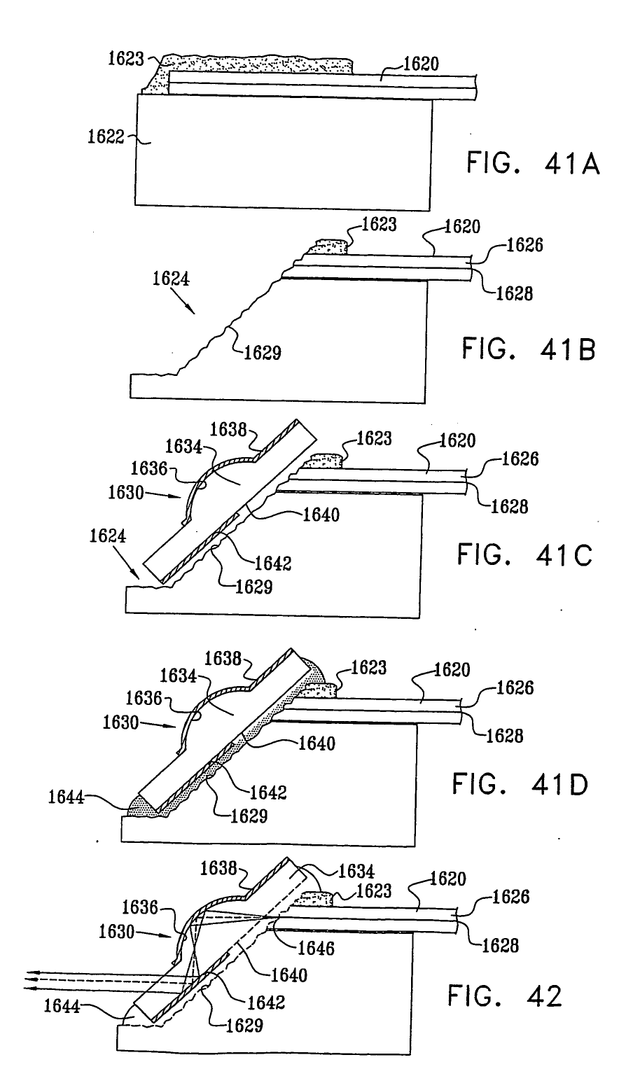

Reference is now made to FIGS. 41A, 41B, 41C, and 41D, which are simplified sectional illustrations of stages in the production of an electro-optic integrated circuit in accordance with another preferred embodiment of the present invention. As seen in FIG. 41A, an optical fiber 1620 is mounted onto a substrate 1622, preferably by means of adhesive 1623. As shown in FIG. 41B, a transverse cut 1624 is preferably formed to extend through the adhesive 1623, the optical fiber 1620 and the substrate 1622. Specifically, in this embodiment, the cut 1624 extends through the cladding 1626 of fiber 1620 and entirely through the core 1628 of the fiber. It is appreciated that a surface 1629 defined by the cut 1624 is relatively rough, as shown.

Turning now to FIG. 41C, it is seen that a partially flat and partially concave mirror assembly 1630 is preferably mounted parallel to the rough inclined surface 1629 defined by the cut 1624. Mirror assembly 1630 preferably comprises a glass substrate 1634 having formed thereon a curved portion 1636 over which is formed a curved metallic layer or a dichroic filter layer 1638. Mirror assembly 1630 also defines a flat surface 1640 having formed thereon a metallic layer or a dichroic filter layer 1642, partially underlying the curved portion 1636. As seen in FIG. 41D, preferably, the mirror assembly 1630 is securely held in place by an optical adhesive 1644, such as OG 146, manufactured by Epoxy Technology, 14 Fortune Drive, Billerica, Mass. 01821, USA, whose refractive index preferably is precisely matched to that of the cores 1628 of the optical fibers 1620.

Reference is now made to FIG. 42, which is a simplified optical illustration corresponding to FIG. 41D. Here it is seen that a generally uninterrupted optical path is defined for light, preferably in the wavelength range of 400-1650 nm, from an end 1646 of core 1628 of fiber 1620 through adhesive 1644 and substrate 1634 and curved portion 1636 of mirror assembly 1630 into reflective engagement with layer 1638 and thence through curved portion 1636 and substrate 1634 to layer 1642 and reflected from layer 1642 through substrate 1634 as a parallel beam.

It is appreciated that the electro-optic integrated circuit described in reference to FIGS. 41A-42 may be configured to operate as either a light transmitter or a light receiver, as described hereinbelow with reference to FIGS. 43-45.

Reference is now made to FIG. 43, which illustrates optical coupling through free space between the electro-optic integrated circuit of FIG. 40, here designated by reference numeral 1700 and the electro-optic integrated circuit of FIG. 42, here designated by reference numeral 1702. It is appreciated that either of electro-optic integrated circuits 1700 and 1702 may transmit light to the other, which receives the light, along a parallel beam.

Reference is now made to FIG. 44, which illustrates optical coupling through free space between an electro-optic integrated circuit of FIG. 40, here designated by reference numeral 1704 and another electro-optic integrated circuit of FIG. 40, here designated by reference numeral 1706. It is appreciated that either of electro-optic integrated circuits 1704 and 1706 may transmit light to the other, which receives the light, along a parallel beam.

Reference is now made to FIG. 45, which illustrates optical coupling through free space between an electro-optic integrated circuit of FIG. 42, here designated by reference numeral 1708 and another electro-optic integrated circuit of FIG. 42, here designated by reference numeral 1710. It is appreciated that either of electro-optic integrated circuits 1708 and 1710 may transmit light to the other, which receives the light, along a parallel beam.

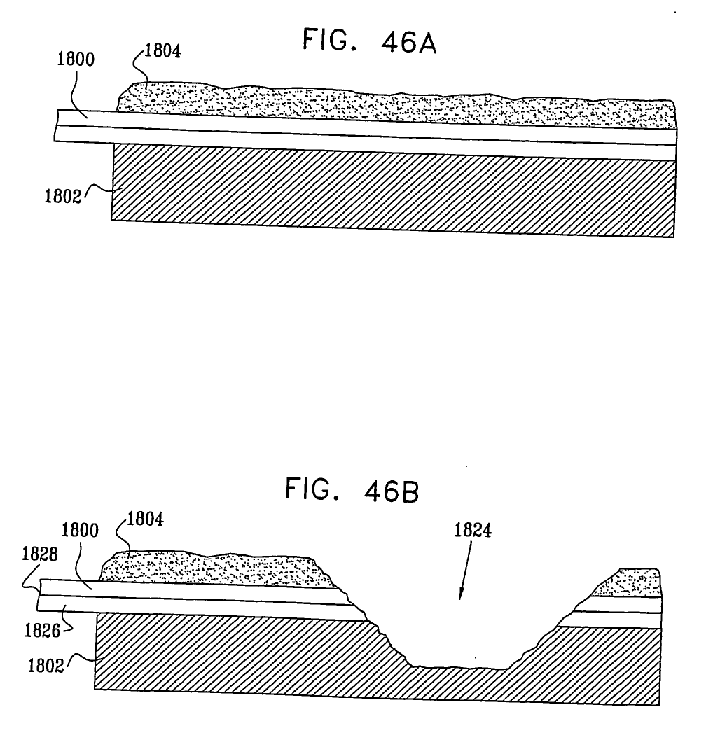

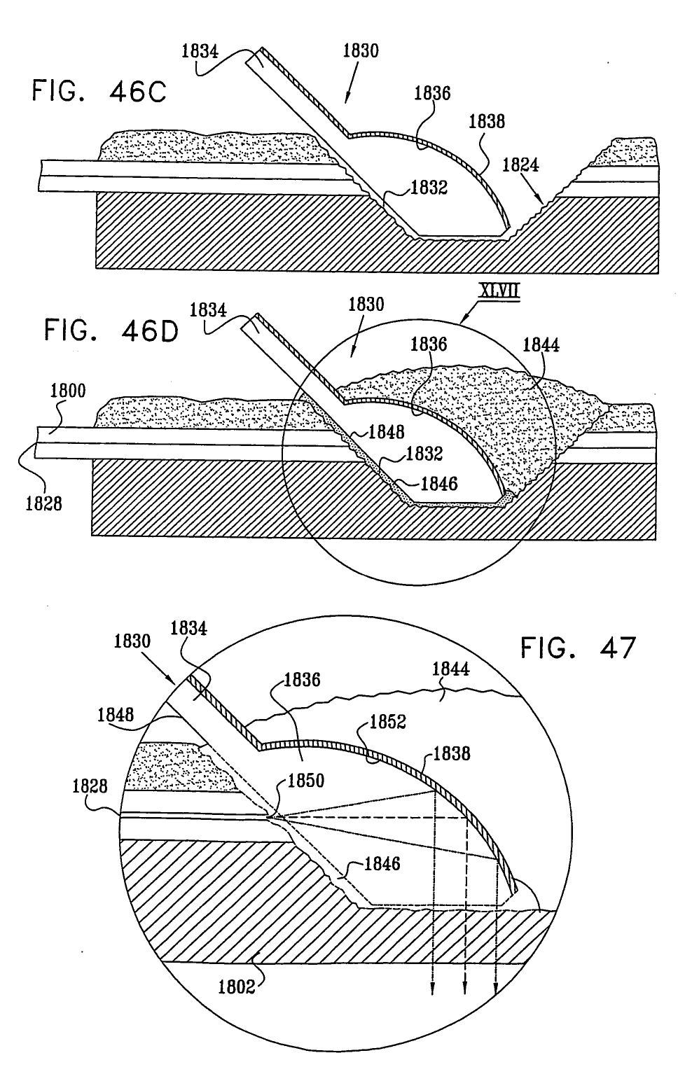

Reference is now made to FIGS. 46A, 46B, 46C, and 46D, which are simplified sectional illustrations of stages in the production of an electro-optic integrated circuit in accordance with another preferred embodiment of the present invention. As seen in FIG. 46A, an optical fiber 1800 is fixed in place on substrate 1802 by means of a suitable adhesive 1804, preferably epoxy. As shown in FIG. 46B, a transverse notch 1824 is preferably formed, extending through the adhesive 1804 entirely through the optical fiber 1800 and partially into substrate 1802. Specifically, in this embodiment, the notch 1824 extends through all of cladding 1826 of the fiber 1800 and entirely through the core 1828 of the fiber. It is appreciated that the surfaces defined by the notch 1824 are relatively rough, as shown.

Turning now to FIG. 46C, it is seen that a partially flat and partially concave mirror 1830 is preferably mounted parallel to one of the rough inclined surfaces 1832 defined by notch 1824. Mirror 1830 preferably comprises a glass substrate 1834 having formed thereon a curved portion 1836 over which is formed a curved metallic layer or a dichroic filter layer 1838. As seen in FIG. 46D, preferably, the mirror 1830 is securely held in place partially by any suitable adhesive 1844, such as epoxy, and partially by an optical adhesive 1846, such as OG 146, manufactured by Epoxy Technology, 14 Fortune Drive, Billerica, Mass. 01821, USA, whose refractive index preferably is precisely matched to that of the cores 1828 of the optical fibers 1800. It is appreciated that optical adhesive 1846 may be employed throughout instead of adhesive 1844. The optical adhesive 1846 preferably fills the interstices between the roughened surface 1832 defined by notch 1824 and a surface 1848 of mirror 1830.

Reference is now made to FIG. 47, which is an enlarged simplified optical illustration of a portion of FIG. 46D. Here it is seen that a generally uninterrupted optical path is defined for light, preferably in the wavelength range of 400-1650 nm, from an end 1850 of a core 1828, through adhesive 1846, substrate 1834 and curved portion 1836, to a reflective surface 1852 of layer 1838 and thence through curved portion 1836, adhesive 1846 and substrate 1802, which are substantially transparent to this light. It is noted that the index of refraction of adhesive 1846 is close to but not identical to that of curved portion 1836 and substrates 1802 and 1834. As seen in FIG. 47, the operation of curved layer 1838 is to collimate light exiting from end 1850 of core 1828 through substrate 1802 as a parallel beam.

Reference is now made to FIG. 48, which illustrates optical coupling through free space between an electro-optic integrated circuit of FIG. 46D, here designated by reference numeral 1900, and another electro-optic integrated circuit of FIG. 46D, here designated by reference numeral 1902. It is appreciated that either of electro-optic integrated circuits 1900 and 1902 may transmit light to the other, which receives the light, along a parallel beam.

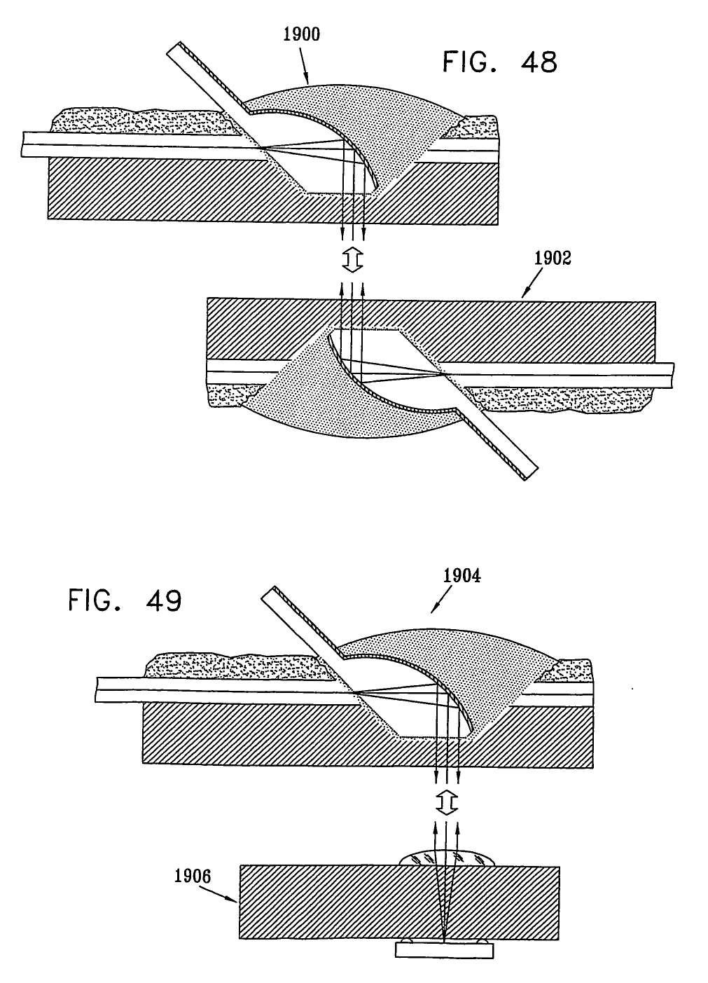

Reference is now made to FIG. 49, which illustrates optical coupling through free space between an electro-optic integrated circuit of FIG. 46D, here designated by reference numeral 1904, and an optical device 1906. Optical device 1906 may be any optical device that receives or transmits light along a parallel beam. It is appreciated that either of electro-optic integrated circuit 1904 and optical device 1906 may transmit light to the other, which receives the light, along a parallel beam.

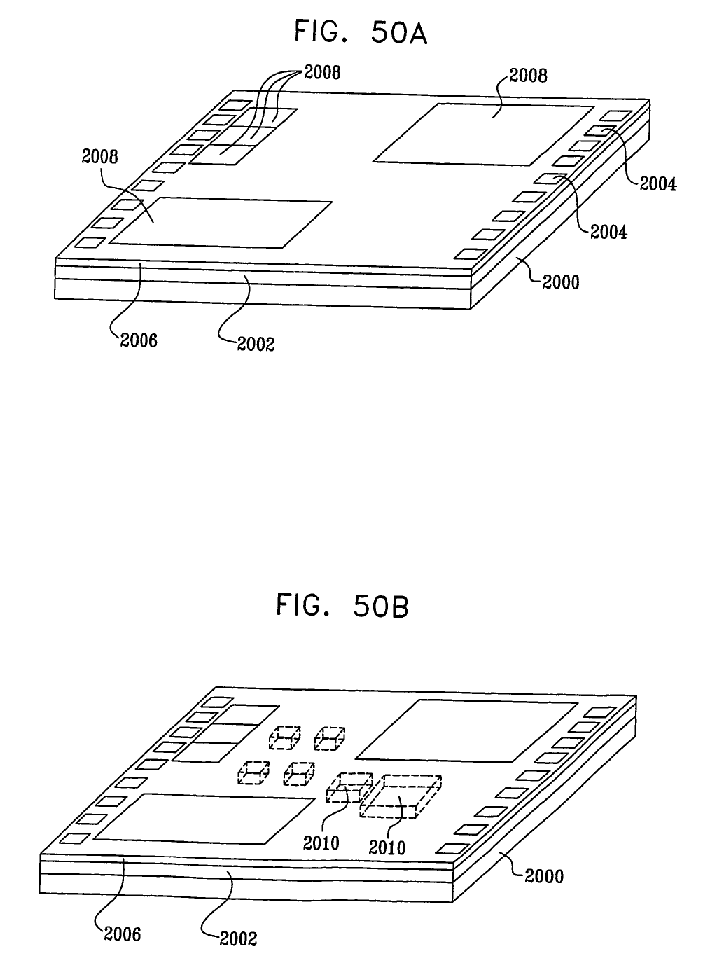

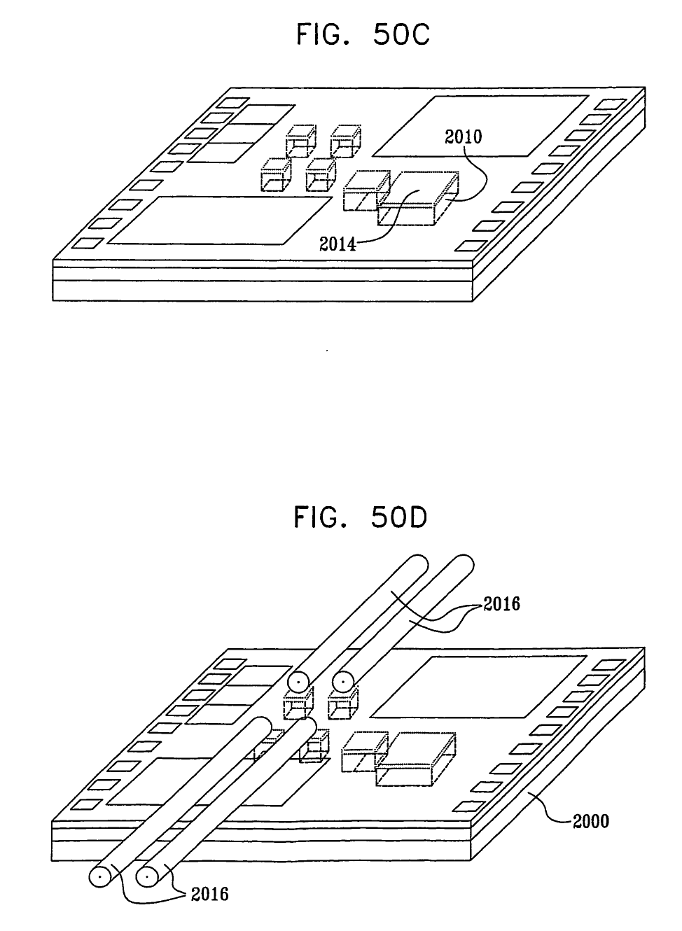

Reference is now made to FIGS. 50A, 50B, 50C, 50D and 50E, which are simplified pictorial illustrations of stages in the production of an electro-optic integrated circuit constructed and operative in accordance with still another preferred embodiment of the present invention. As seen in FIG. 50A, a substrate 2000, typically formed of silicon and having a thickness of 300-800 microns, has formed thereon at least one dielectric passivation layer 2002, at least one metal layer 2004 and at least one overlying dielectric layer 2006. The dielectric layers are preferably transparent to light preferably in both the visible and the infrared bands. Vias, (not shown) connected to at least one metal layer 2004, extend through layer 2002 to the substrate 2000. One or more semiconductor functional blocks 2008 are preferably formed on substrate 2000.

As seen in FIG. 50B, one or more openings 2010 are formed by removing portions of the substrate 2000 from the underside thereof, as shown for example in FIG. 25B. The removal of portions of substrate 2000 may be achieved by using conventional etching techniques and, preferably, provides a volume of dimensions of at least 600 microns in width.

As seen in FIG. 50C, integrated circuit chips 2014 are preferably located in openings 2010. These chips may be operatively engaged with vias (not shown) by being soldered to bumps (not shown) as illustrated for example in FIG. 25D, thus creating an optoelectronic integrated circuit, wherein integrated circuit chips 2014 reside within the substrate of the integrated circuit.

As seen in FIG. 50D, one or more fibers 2016 are fixed to substrate 2000, preferably by an adhesive (not shown), similarly to that shown in FIG. 37A. Multiple fibers 2016 may be identical, similar or different and need not be arranged in a mutually aligned spatial relationship.

As shown in FIG. 50E, it is seen that a mirror 2030, typically of the type illustrated in any of FIGS. 18A-24G, is preferably mounted in operative engagement with each fiber 2016.

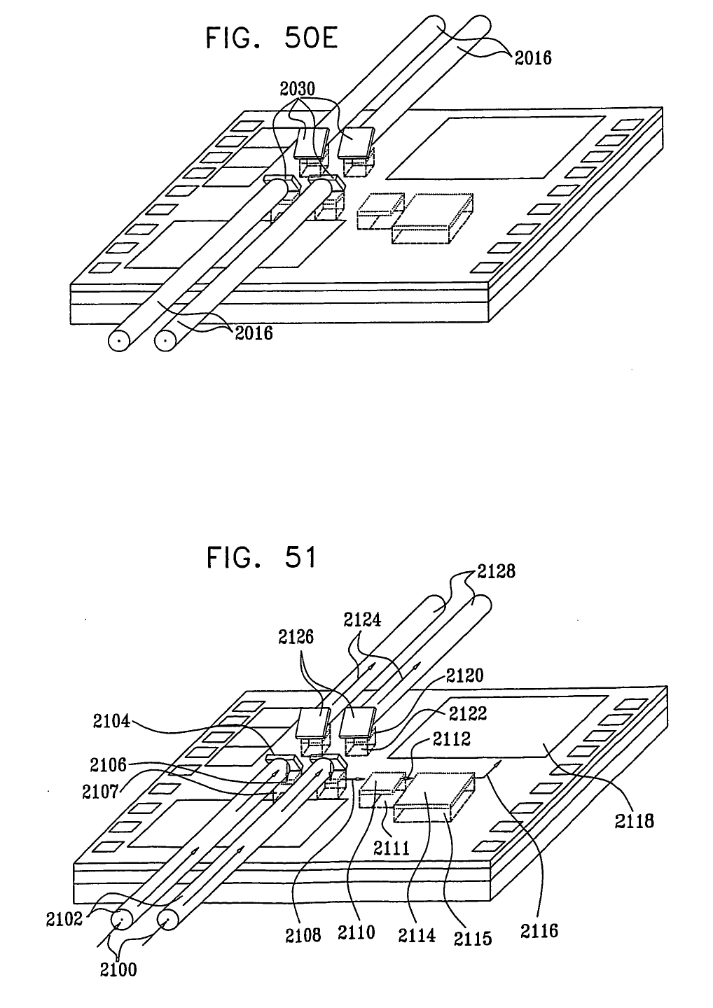

Reference is now made to FIG. 51, which is a simplified functional illustration of a preferred embodiment of the structure of FIG. 50E. As seen in FIG. 51, a high frequency optical signal 2100, typically of frequency 10 GHz, passes through a fiber 2102 and is reflected by a mirror 2104 onto a diode 2106, which may be located in a recess 2107. An output electrical signal 2108 from diode 2106 is supplied to an amplifier 2110, which may be located in a recess 2111 and need not be formed of silicon, but could be formed, for example, of gallium arsenide or indium phosphide. The amplified output 2112 of amplifier 2110 may be provided to a serializer/deserializer 2114, which may be located in a recess 2115 and need not be formed of silicon, but could be formed, for example, of gallium arsenide or indium phosphide.

An output signal 2116 from serializer/deserializer 2114 is preferably fed to one or more semiconductor functional blocks 2118 for further processing. A laser 2120, which may be located in a recess 2122, may employ an electrical output from a functional block 2118 to produce a modulated light beam 2124, which is reflected by a mirror 2126 so as to pass through a fiber 2128. It is appreciated that electro-optic integrated circuit devices 2106 and 2120 may be configured to operate as either a light transmitter or a light receiver or both.

It is appreciated that in addition to the substrate materials described hereinabove the substrates may comprise glass, silicon, sapphire, alumina, aluminum nitride, boron nitride or any other suitable material.

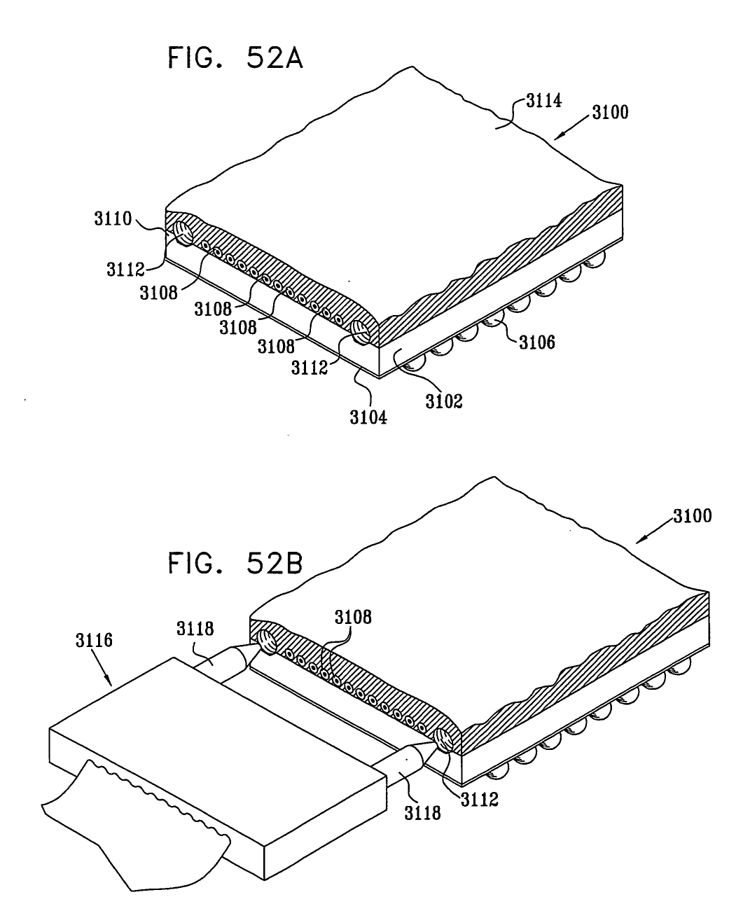

Reference is now made to FIGS. 52A and 52B, which are simplified pictorial illustrations of a packaged electro-optic circuit 3100, having integrally formed therein an optical connector and electrical connections, alone and in conjunction with a conventional optical connector.

As seen in FIGS. 52A and 52B, a packaged electro-optic circuit 3100 is provided in accordance with a preferred embodiment of the present invention and includes an at least partially transparent substrate 3102, typically glass. Electrical circuitry (not shown) is formed, as by conventional photolithographic techniques, over one surface of substrate 3102 and is encapsulated by a layer 3104 of a protective material such as BCB, commercially available from Dow Corning of the U.S.A. An array 3106 of electrical connections, preferably in the form of conventional solder bumps, communicates with the electrical circuitry via conductive pathways (not shown) extending through the protective material of layer 3104.

Formed on a surface of substrate 3102 opposite to that adjacent layer 3104 there are defined optical pathways (not shown) which communicate with an array of optical fibers 3108, whose ends are aligned along an edge 3110 of the substrate 3102. Preferably, physical alignment bores 3112 are aligned with the array of optical fibers 3108. The bores 3112 are preferably defined by cylindrical elements, which, together with the optical fibers 3108 and the optical pathways, are encapsulated by a layer 3114 of protective material, preferably epoxy.

FIG. 52B shows a conventional MPO type optical connector 3116, such as an MPO connector manufactured by SENKO Advanced Components, Inc. of Marlborough, Mass., USA., arranged for mating contact with the packaged electro-optic circuit 3100, wherein alignment pins 3118 of connector 3116 are arranged to seat in alignment bores 3112 of the electro-optic circuit 3100 and optical fiber ends (not shown) of connector 3116 are arranged in butting aligned relationship with the ends of the array 3108 of optical fibers in packaged electro-optic circuit 3100.

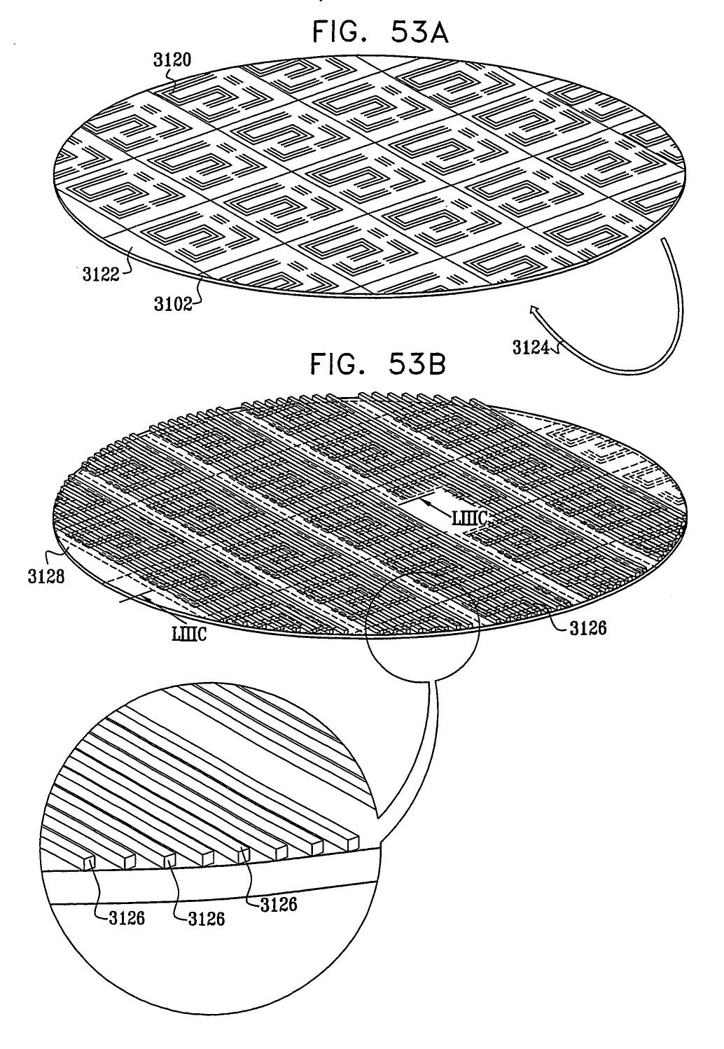

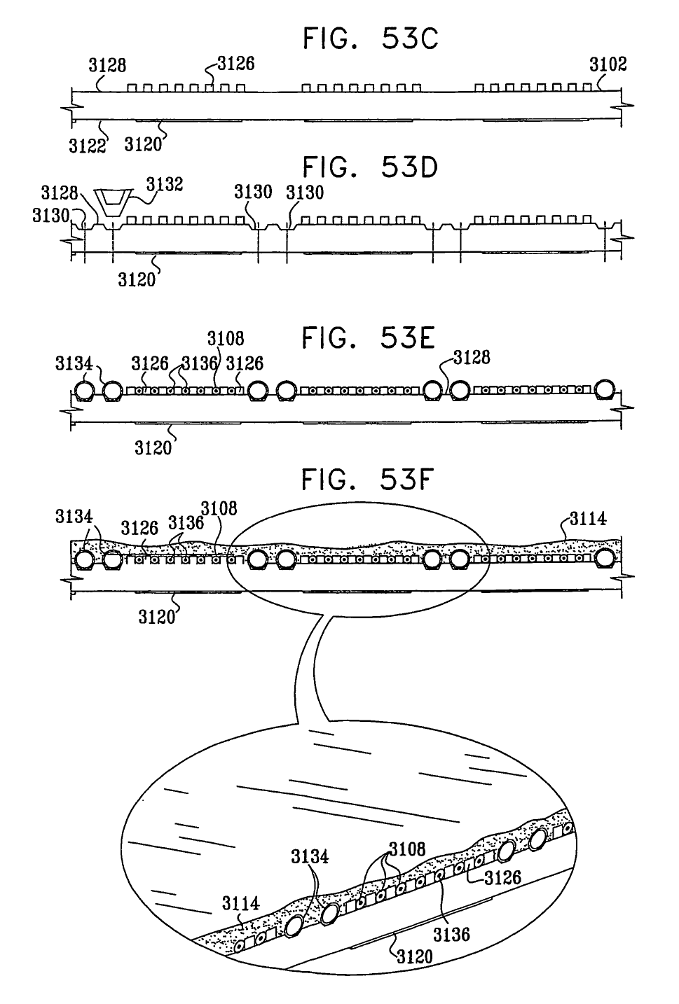

Reference is now made to FIGS. 53A, 53B, 53C, 53D, 53E and 53F, which are simplified pictorial and sectional illustrations of a first plurality of stages in the manufacture of the packaged electro-optic circuit of FIGS. 52A and 52B. Turning to FIG. 53A, it is seen that electrical circuits 3120 are preferably formed onto a first surface 3122 of substrate 3102, at least part of which is transparent to light within at least part of the wavelength range of 600-1650 nm. Substrate 3102 is preferably of thickness between 200-800 microns. The electrical circuits 3120 are preferably formed by conventional photolithographic techniques employed in the production of integrated circuits.

The substrate shown in FIG. 53A is turned over, as indicated by an arrow 3124 and, as seen in FIG. 53B, an array of parallel, spaced, elongate optical fiber positioning elements 3126 is preferably formed, such as by conventional photolithographic techniques, over an opposite surface 3128 of substrate 3102. It is appreciated that the positions of the array of elements 3126 on surface 3128 are preferably precisely coordinated with the positions of the electrical circuits 3120 on first surface 3122 of the substrate 3102, as shown in FIG. 53C.

Turning to FIG. 53D, it is seen that notches 3130 are preferably formed on surface 3128, as by means of a dicing blade 3132, to precisely position and accommodate alignment bore defining cylinders 3134, as shown in FIG. 53E. FIG. 53E illustrates that the centers of alignment bore defining cylinders 3134 preferably lie in the same plane as the centers 3136 of optical fibers 3108 which are precisely positioned between elements 3126 on surface 3128. FIG. 53F illustrates encapsulation of the fibers 3108, the cylinders 3134 and the positioning elements 3126 by layer 3114 of protective material, preferably epoxy.

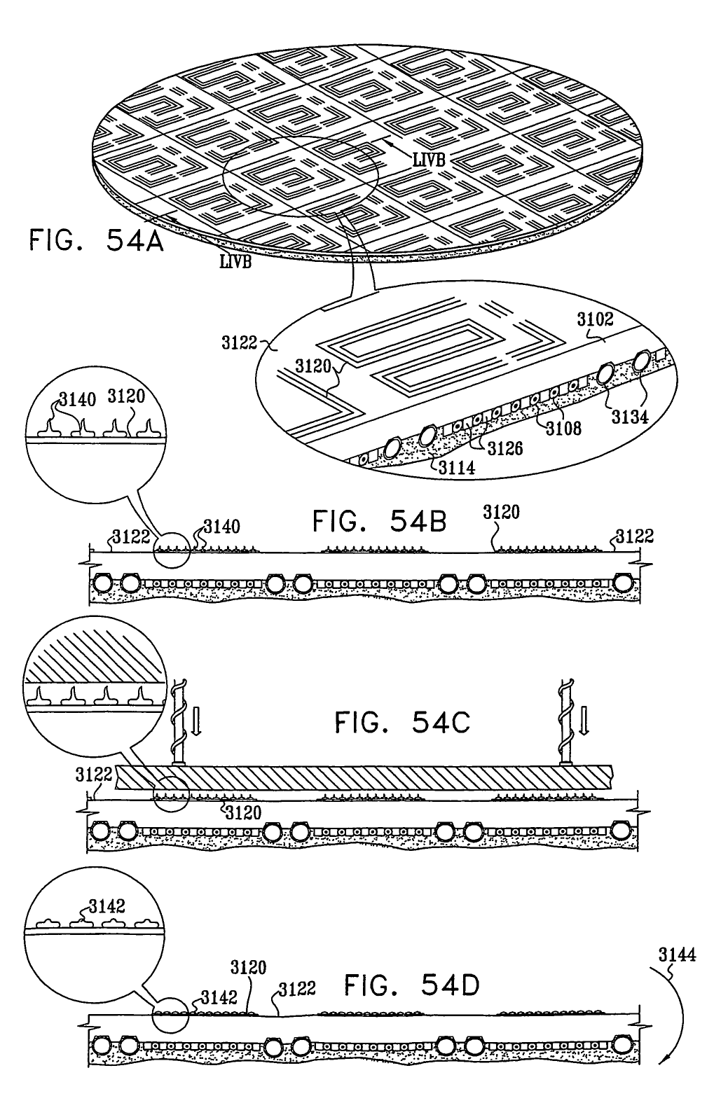

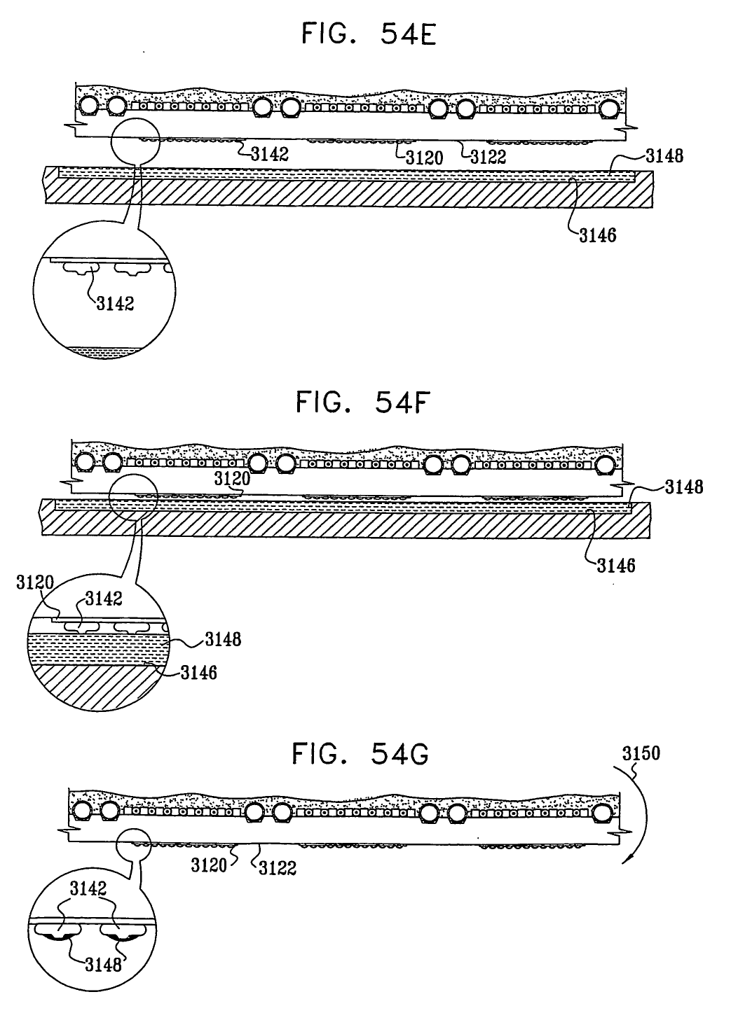

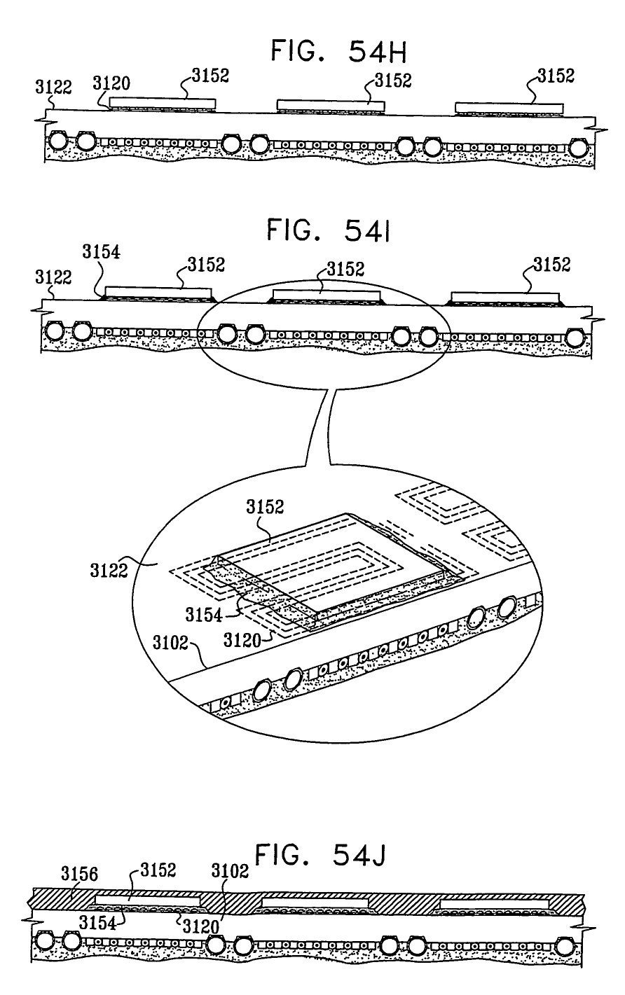

Reference is now made to Figs. FIGS. 54A, 54B, 54C, 54D, 54E, 54F, 54G, 54H, 541 and 54J, which are simplified pictorial and sectional illustrations of a second plurality of stages in the manufacture of the packaged electro-optic circuit of FIGS. 52A and 52B. FIG. 54A shows the wafer of FIG. 53F turned over.

As shown in FIG. 54B, a multiplicity of studs 3140, preferably gold studs, are formed onto electrical circuits 3120 lying on surface 3122. The studs 3140 are preferably flattened or “coined”, as shown schematically in FIG. 54C, to yield a multiplicity of flattened electrical contacts 3142, as shown in FIG. 54D.

As shown in FIGS. 54E, 54F and 54G, the wafer of FIG. 54D is turned over, as indicated by an arrow 3144, and the electrical contacts 3142 are dipped into a shallow bath 3146 of a conductive adhesive 3148, such as H20E silver filled epoxy, manufactured by Epoxy Technology, 14 Fortune Drive, Billerica, Mass. 01821, USA, so as to coat the tip of each contact 3142 with adhesive 3148, as shown. The wafer of FIG. 54G is then turned over, as indicated by an arrow 3150, and a plurality of integrated circuits 3152 is mounted onto the multiplicity of contacts 3142, as seen in FIG. 54H. Integrated circuits 3152 may be electrical or electro-optic integrated circuits as appropriate.

FIG. 54I illustrates the application of underfill material 3154, such as OG 146, manufactured by Epoxy Technology, 14 Fortune Drive, Billerica, Mass. 01821, USA, at the gap between integrated circuits 3152 and electrical circuits 3120 as well as substrate 3102. If integrated circuits 3152 include electro-optic devices, the underfill material 3154 should be transparent as appropriate.

As shown in FIG. 54J, an encapsulation layer 3156, such as a layer of solder mask, is preferably formed over integrated circuits 3152, electrical circuits 3120, substrate 3102 and underfill material 3154.

For the purposes of the discussion which follows, it is assumed that at least some, if not all, of the integrated circuits 3152 are electro-optic devices. It is appreciated that additional integrated circuits (not shown) which are not electro-optic devices, may be electrically connected to the electrical circuits 3120 on substrate 3102 by other techniques, such as wire bonding.

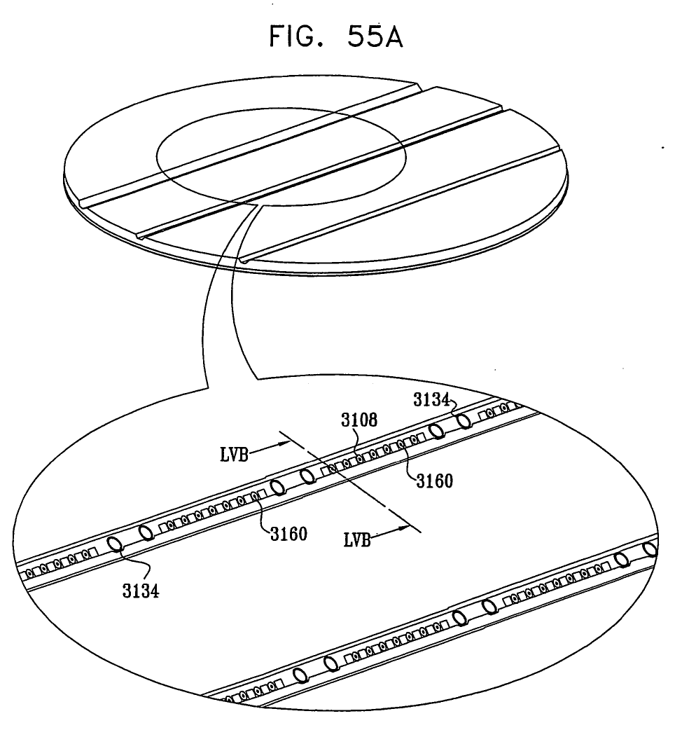

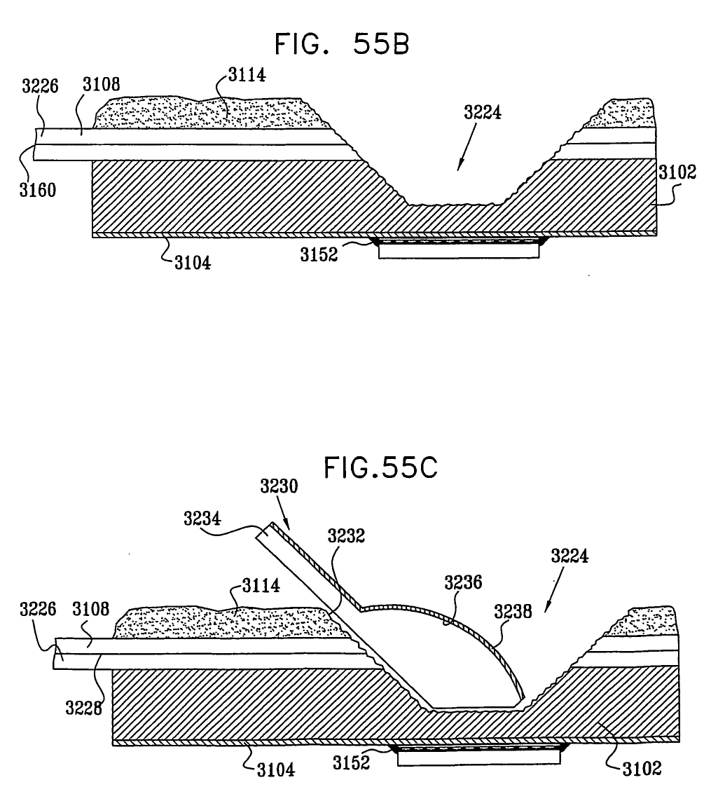

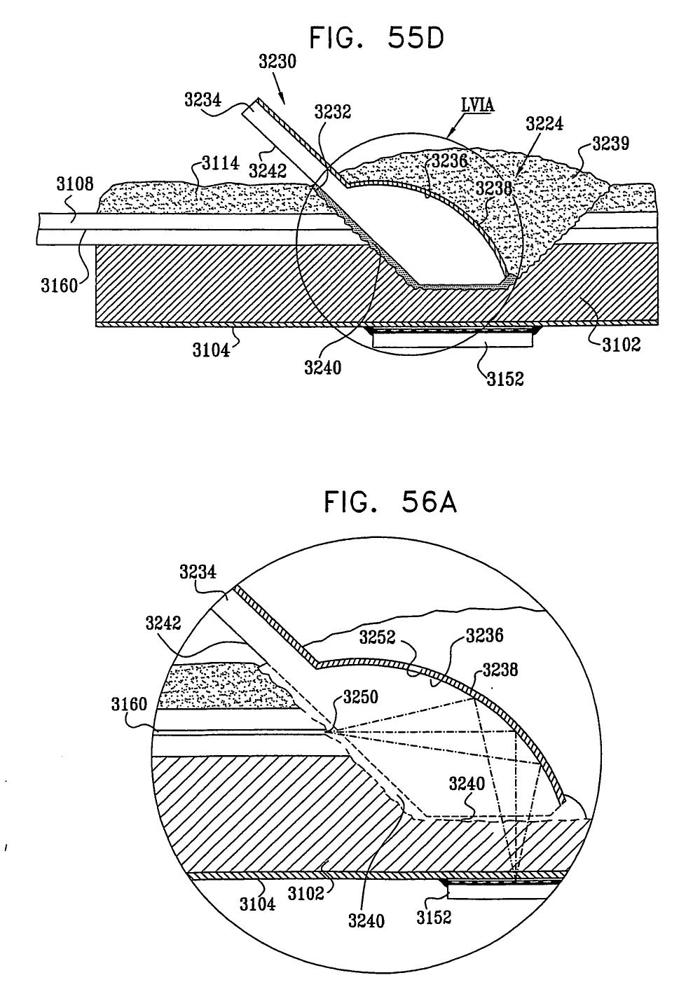

Reference is now made to Figs. FIGS. 55A, 55B, 55C and 55D, which are simplified pictorial and sectional illustrations of a third plurality of stages in the manufacture of the packaged electro-optic circuit of FIGS. 52A and 52B.

FIG. 55A illustrates the wafer of FIG. 54J, turned over and notched along lines extending perpendicularly to the array of optical fibers 3108, producing an inclined cut extending entirely through at least the core 3160 of each fiber 3108 and extending at least partially through cylindrical elements 3134.

FIG. 55B is a simplified sectional illustrations, taken along the lines LVB -LVB in FIG. 55A, of a further stage in the production of the electro-optic integrated circuit.

As shown in FIG. 55B, the notching preferably forms a notch 3224, at least partially overlapping the locations of the integrated circuits 3152, at least some, if not all, of which are electro-optic devices, and extending through the layer 3114 of protective material, entirely through each optical fiber 3108 and partially into substrate 3102. Specifically, in this embodiment, the notch 3224 extends through all of cladding 3226 of each fiber 3108 and entirely through the core 3160 of each fiber. It is appreciated that the surfaces defined by the notch 3224 are relatively rough, as shown.

Turning now to FIG. 55C, it is seen that a partially flat and partially concave mirror assembly 3230 is preferably mounted parallel to one of the rough inclined surfaces 3232 defined by notch 3224. Mirror assembly 3230 preferably comprises a glass substrate 3234 having formed thereon a curved portion 3236 over which is formed a curved metallic layer or a dichroic filter layer 3238. A preferred method of fabrication of mirror assembly 3230 is described hereinabove with reference to FIGS. 19A-19E. As seen in FIG. 55D, preferably, the mirror assembly 3230 is securely held in place partially by any suitable adhesive 3239, such as epoxy, and partially by an optical adhesive 3240, such as OG 146, manufactured by Epoxy Technology, 14 Fortune Drive, Billerica, Mass. 01821, USA, whose refractive index preferably is precisely matched to that of the cores 3160 of the optical fibers 3108. It is appreciated that optical adhesive 3240 may be employed throughout instead of adhesive 3239. Optical adhesive 3240 preferably fills the interstices between the roughened surface 3232 defined by notch 3224 and a surface 3242 of mirror assembly 3230.

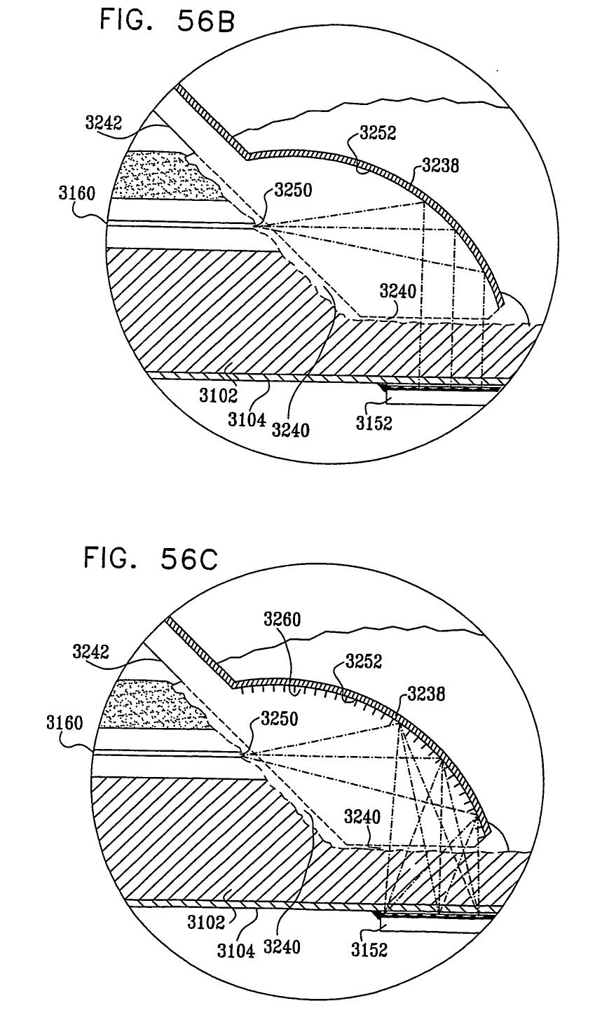

Reference is now made to FIGS. 56A, 56B and 56C, which are enlarged simplified optical illustrations of a portion of FIG. 55D in accordance with preferred embodiments of the present invention. FIG. 56A is an enlarged simplified optical illustration of a portion of FIG. 55D. Here it is seen that a generally uninterrupted optical path is defined for light, preferably in the wavelength range of 400-1650 nm, from an end 3250 of a core 3160, through adhesive 3240, substrate 3234 and curved portion 3236 to a reflective surface 3252 of layer 3238 and thence through curved portion 3236, adhesive 3240 and substrate 3102 and layer 3104 which are substantially transparent to this light. It is noted that the index of refraction of adhesive 3240 is close to but not identical to that of curved portion 3236 and substrates 3102 and 3234. In the embodiment of FIG. 56A, the operation of curved layer 3238 is to focus light exiting from end 3250 of core 3160 onto the electro-optic component 3152.

FIG. 56B is an enlarged simplified optical illustration of a portion of FIG. 55D in accordance with a further embodiment of the present invention. In this embodiment, the curvature of curved layer 3238 produces collimation rather than focusing of the light exiting from end 3250 of core 3160 onto the electro-optic component 3152.

FIG. 56C is an enlarged simplified optical illustration of a portion of FIG. 55D in accordance with yet another embodiment of the present invention wherein a grating 3260 is added to curved layer 3238. The additional provision of grating 3260 causes separation of light impinging thereon according to its wavelength, such that multispectral light exiting from end 3250 of core 3160 is focused at multiple locations on electro-optic component 3152 in accordance with the wavelengths of components thereof.

Reference is now made to FIG. 57, which is a simplified sectional illustration of an electro-optic integrated circuit constructed and operative in accordance with yet another preferred embodiment of the present invention. The embodiment of FIG. 57 corresponds generally to that described hereinabove with respect to FIG. 55D other than in that a mirror with multiple concave reflective surfaces is provided rather than a mirror with a single such reflective surface. As seen in FIG. 57, it is seen that light from an optical fiber 3316 is directed onto an electro-optic component 3320 by a partially flat and partially concave mirror assembly 3330, preferably mounted parallel to one of the rough inclined surfaces 3332 defined by notch 3324. Mirror assembly 3330 preferably comprises a glass substrate 3334 having formed thereon a plurality of curved portions 3336 over which are formed a curved metallic layer or a dichroic filter layer 3338. Mirror assembly 3330 also defines a reflective surface 3340, which is disposed on a planar surface 3342 generally opposite layer 3338. A preferred method of fabrication of mirror assembly 3330 is described hereinabove with reference to FIGS. 20A-20F. Preferably, the mirror assembly 3330 is securely held in place partially by any suitable adhesive 3343, such as epoxy, and partially by an optical adhesive 3344, such as OG 146, manufactured by Epoxy Technology, 14 Fortune Drive, Billerica, Mass. 01821, USA, whose refractive index preferably is precisely matched to that of the cores 3328 of the optical fibers 3316. It is appreciated that optical adhesive 3344 may be employed throughout instead of adhesive 3343. The optical adhesive 3344 preferably fills the interstices between the roughened surface 3332 defined by notch 3324 and surface 3342 of mirror assembly 3330.

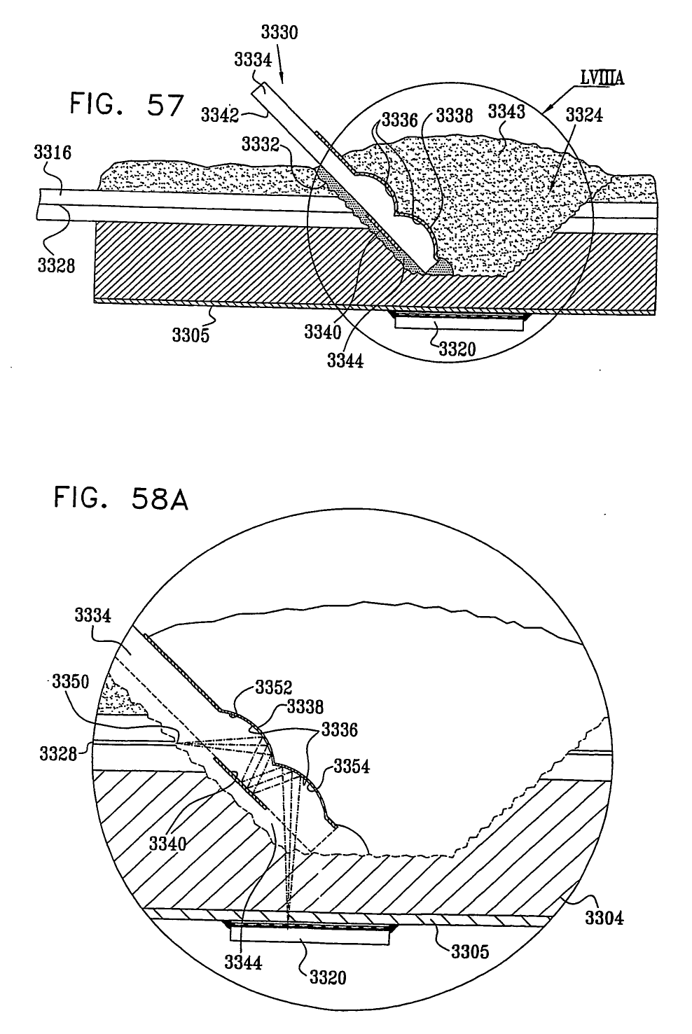

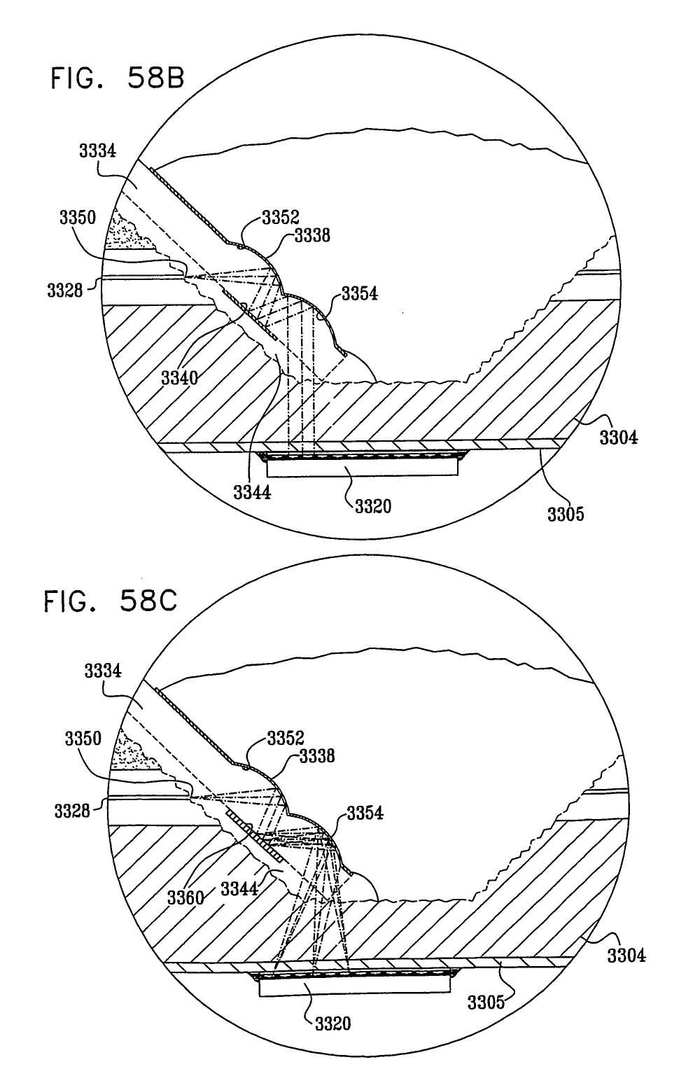

Reference is now made to FIG. 58A, which is an enlarged simplified optical illustration of a portion of FIG. 57. Here it is seen that a generally uninterrupted optical path is defined for light, preferably in the wavelength range of 400-1650 nm, from an end 3350 of a core 3328, through adhesive 3344, substrate 3334 and first curved portion 3336, to a curved reflective surface 3352 of layer 3338 and thence through first curved portion 3336 and substrate 3334 to reflective surface 3340, from reflective surface 3340 through substrate 3334 and second curved portion 3336 to another curved reflective surface 3354 of layer 3338 and thence through second curved portion 3336, substrate 3334, adhesive 3344 and substrate 3304 and layer 3305, which are substantially transparent to this light. It is noted that the index of refraction of adhesive 3344 is close to but not identical to that of substrates 3304 and 3334. In the embodiment of FIG. 58A, the operation of curved layer 3338 and reflective surface 3340 is to focus light exiting from end 3350 of core 3328 onto the electro-optic component 3320.

Reference is now made to FIG. 58B, which is an enlarged simplified optical illustration of a portion of FIG. 57 in accordance with a further embodiment of the present invention. In this embodiment, the curvature of curved layer 3338 produces collimation rather than focusing of the light exiting from end 3350 of core 3328 onto the electro-optic component 3320.

Reference is now made to FIG. 58C, which is an enlarged simplified optical illustration of a portion of FIG. 57 in accordance with yet another embodiment of the present invention wherein a reflective grating 3360 replaces reflective surface 3340. A preferred method of fabrication of mirror assembly 3330 with grating 3360 is described hereinbelow with reference to FIGS. 22A-22F. The additional provision of grating 3360 causes separation of light impinging thereon according to its wavelength, such that multispectral light existing from end 3350 of core 3328 is focused at multiple locations on electro-optic component 3320 in accordance with the wavelengths of components thereof.

It is appreciated that, even though the illustrated embodiments of FIGS. 55C-58C utilize the mirror assemblies whose fabrications are described hereinabove with reference to FIGS. 19A-20F and 22A-22G, any of the mirror assemblies whose fabrications are described hereinabove with reference to FIGS. 18A-24G may alternatively be utilized.

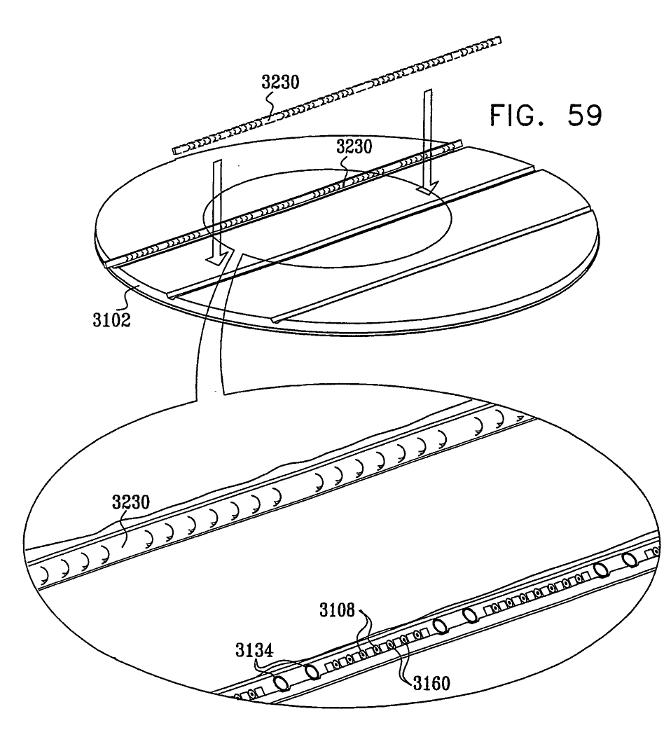

Reference is now made to FIG. 59, which is a simplified pictorial illustration corresponding to sectional illustration 55D. FIG. 59 illustrates the wafer of FIG. 55A, with partially flat and partially concave mirror assembly 3230 mounted thereon, parallel to one of the rough inclined surfaces 3232 defined by notch 3224, as described hereinabove with reference to FIG. 55D. It is appreciated that mirror assembly 3230 extends along the entire length of substrate 3102.

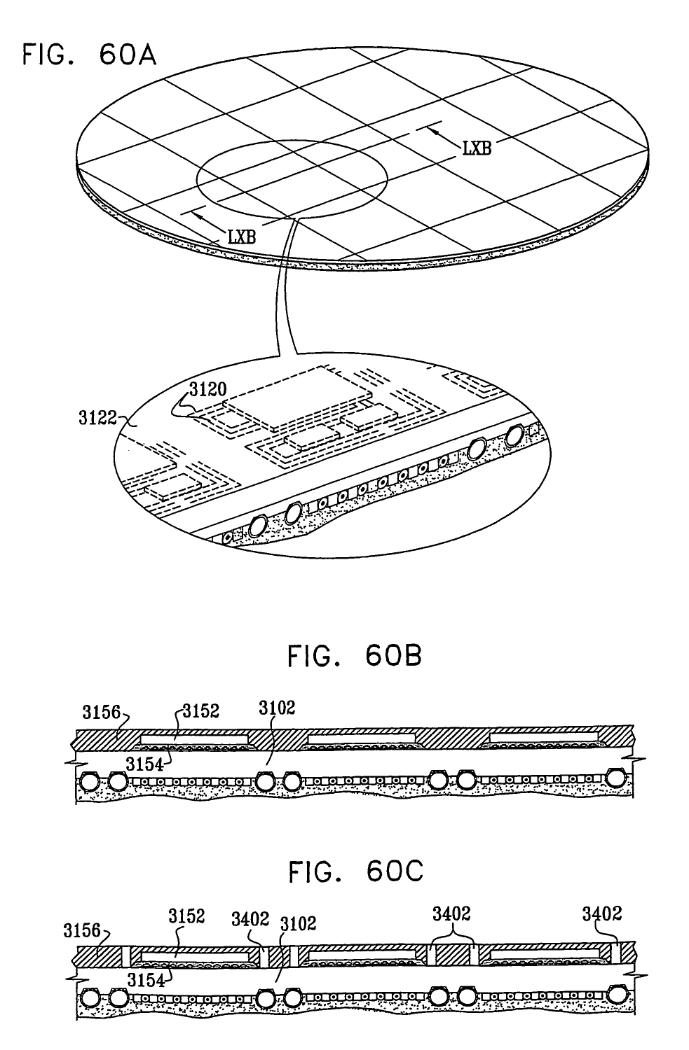

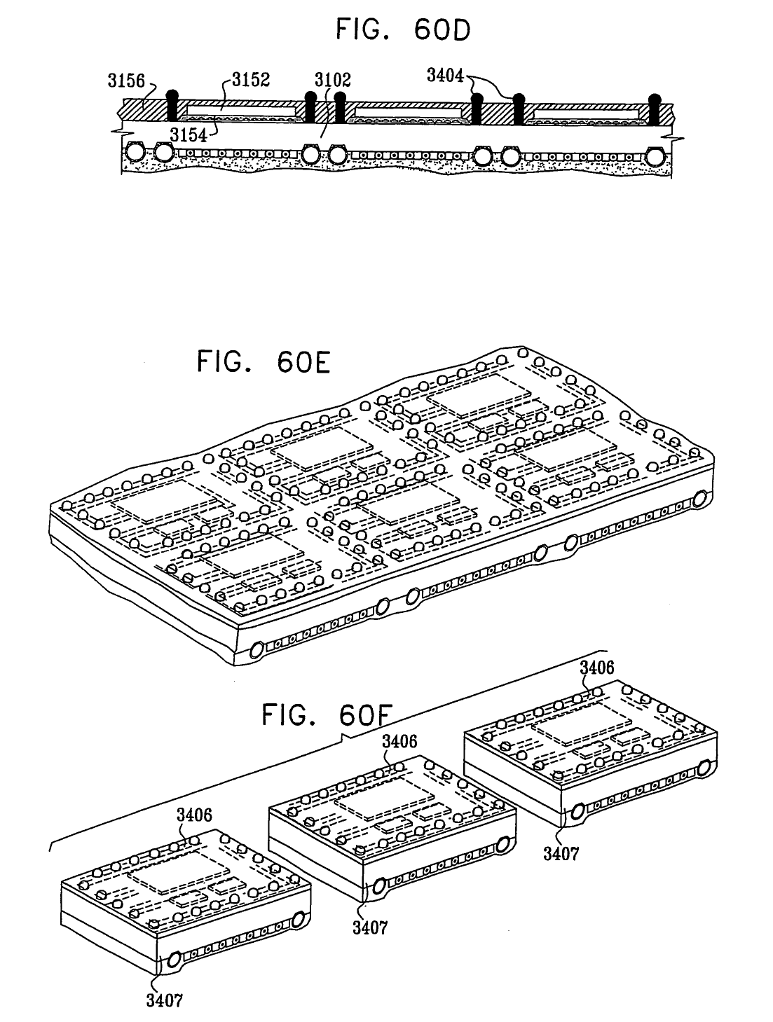

Reference is now made to FIGS. 60A, 60B, 60C, 60D, 60E and 60F, which are simplified pictorial and sectional illustrations of a fourth plurality of stages in the manufacture of the packaged electro-optic circuit of FIGS. 52A and 52B. FIG. 60A shows the wafer of FIG. 59 turned over. FIG. 60B is a sectional illustration of the wafer of FIG. 60A along lines LXB-LXB. FIG. 60C illustrates the formation of holes 3402 by conventional techniques, such as the use of lasers or photolithography, which communicate with electrical circuits 3120 (FIG. 53A) on substrate 3102. FIG. 60D shows the formation of solder bumps 3404 in holes 3402.

Following the formation of solder bumps 3404 in holes 3402, the wafer, as shown in FIG. 60E, is preferably diced, providing a plurality of packaged electro-optic circuit chips 3406, as illustrated in FIG. 60F. Following dicing of substrate 3102 into a plurality of packaged electro-optic circuit chips 3406, an optical edge surface 3407 of each of the plurality of packaged electro-optic circuit chips 3406 is polished to provide an optical quality planar surface. It is appreciated that the planar surface defined by the polishing may be either parallel, or at any suitable angle, to the plane defined by the dicing.

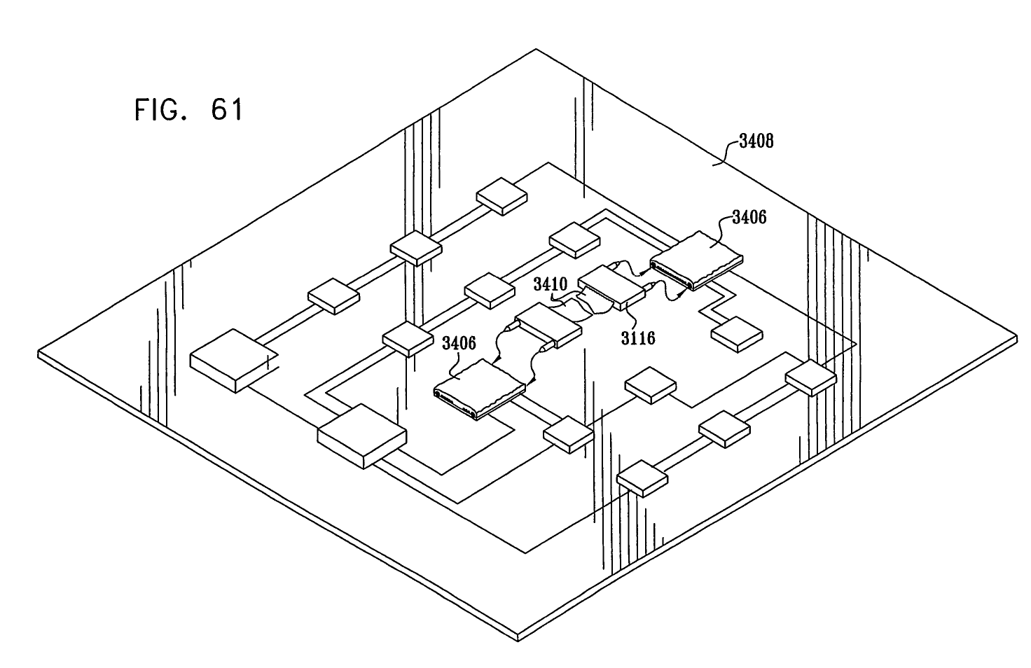

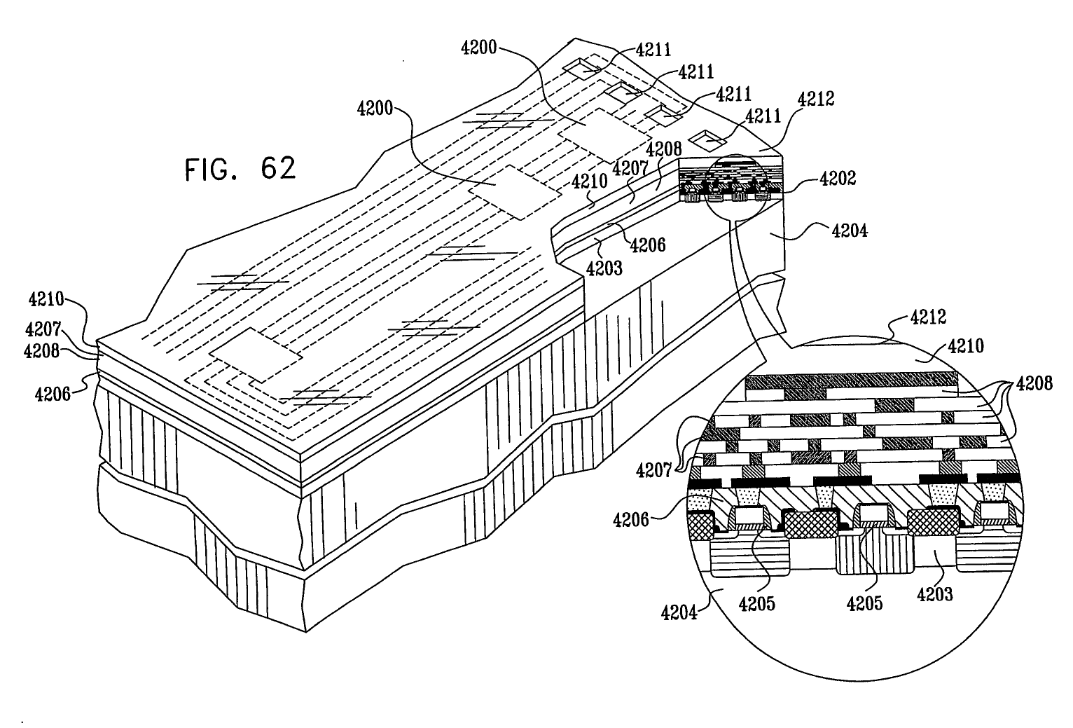

Reference is now made to FIG. 61, which shows packaged electro-optic circuit chips 3406 mounted on a conventional electrical circuit board 3408 and being interconnected by a conventional optical fiber ribbon 3410 and associated conventional optical fiber connectors 3116 (FIG. 52B).

Reference is now made to FIG. 62, which is a simplified pictorial illustration of an initial stage in the production of an electro-optic integrated circuit, constructed and operative in accordance with a preferred embodiment of the present invention. As seen in FIG. 62, one or more electrical circuits 4200 are preferably formed onto a first surface 4202 of an optional epitaxial layer 4203 of a substrate 4204. The epitaxial layer 4203 is typically formed of silicon and has a thickness of between 2-10 microns, while the substrate 4204 is typically formed of silicon and has a thickness of 200-1000 microns. Electrical circuits 4200 are preferably formed onto substrate 4204 by conventional photolithographic and thin film processing techniques employed in the production of integrated circuits. Circuits 4200 preferably include transistors 4205 formed in layer 4203, covered by a dielectric layer 4206, over which is typically formed a plurality of metal conductive layers 4207 interspersed with dielectric layers 4208, covered by a top passivation layer 4210. The dielectric layers are preferably transparent to light preferably in both the visible and the infrared bands within at least part of the wavelength range of 400-1650 nm. Vias 4211, connected to at least one conductive layer 4207, extend through layer 4210 to the top surface 4212.

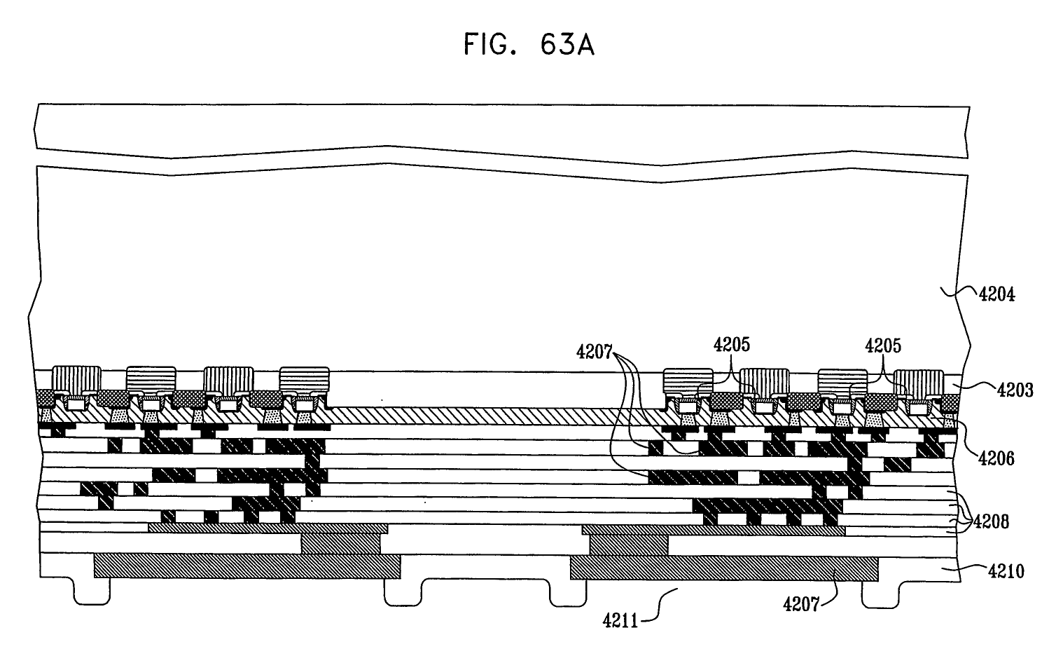

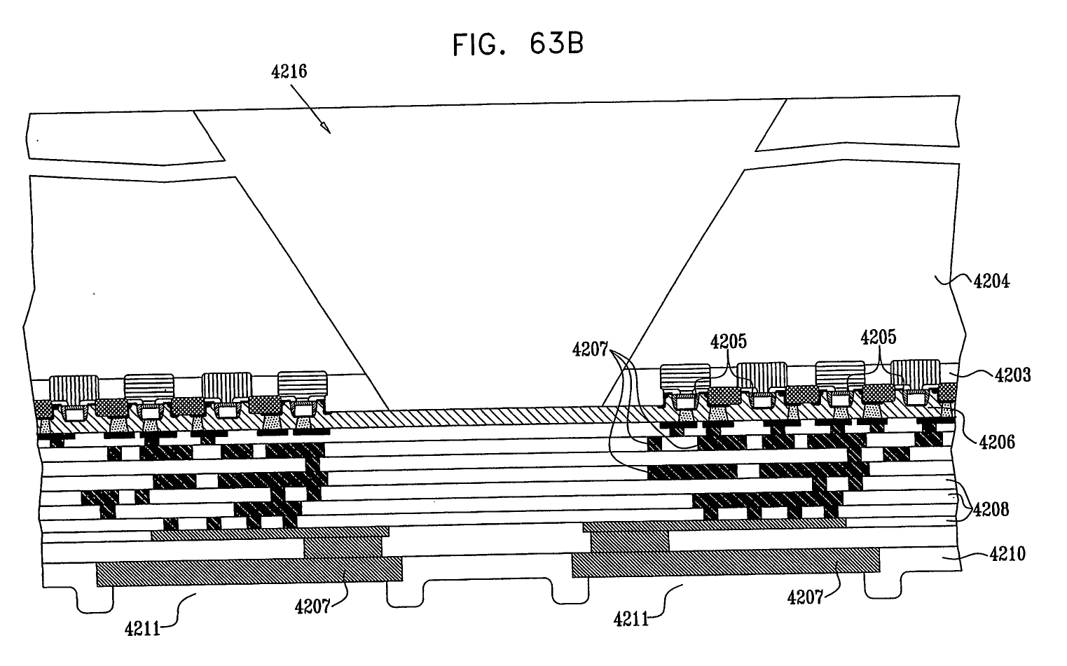

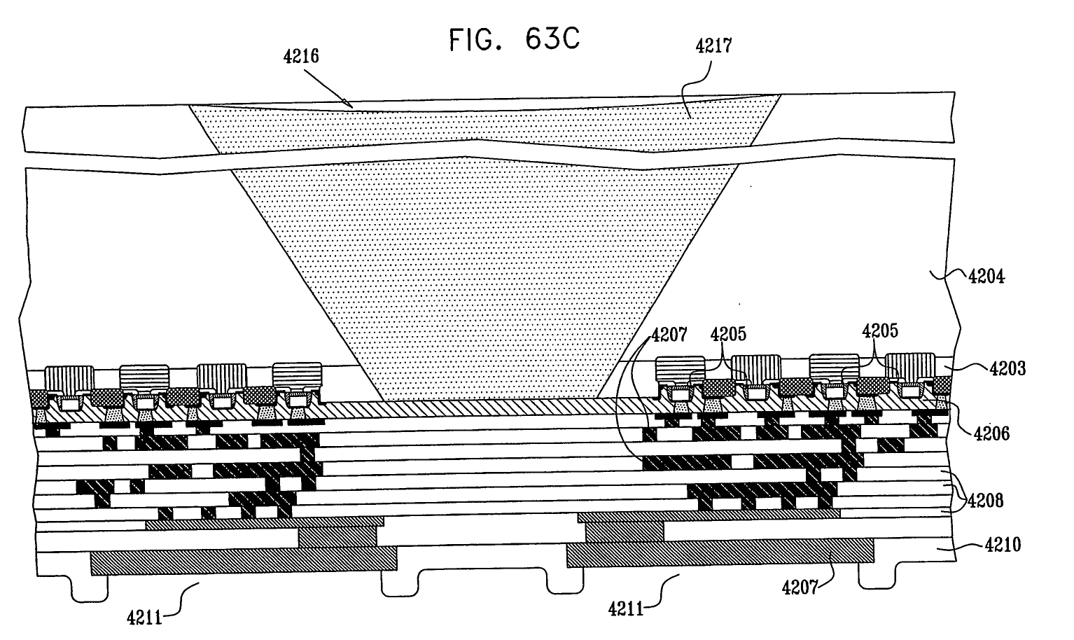

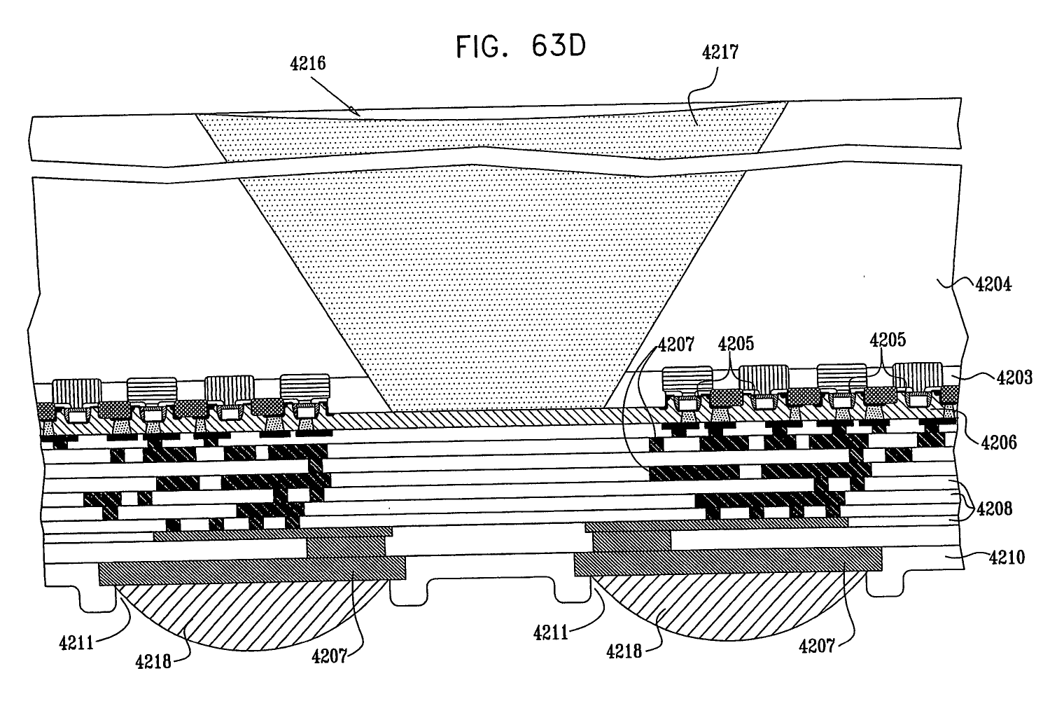

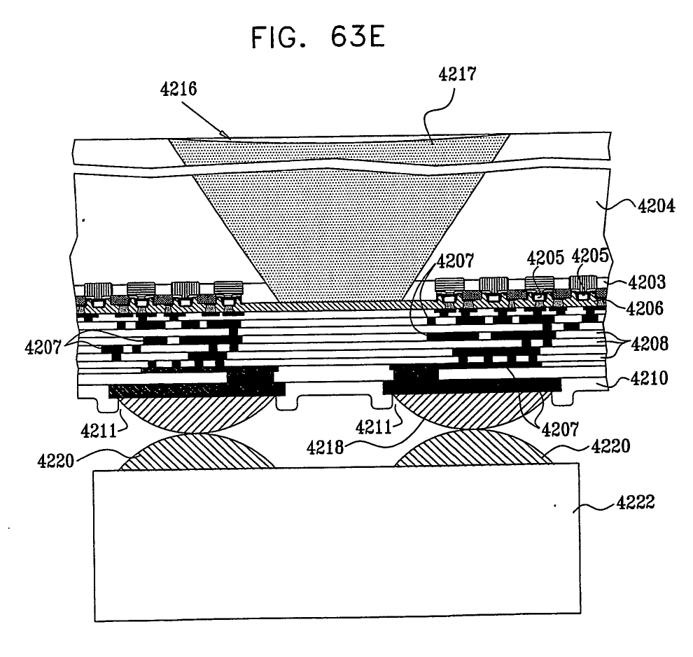

Reference is now made to FIGS. 63A, 63B, 63C, 63D and 63E, which are simplified illustrations of the initial stages in the production of an electro optical integrated circuit in accordance with the embodiment of FIG. 62. FIG. 63A shows the substrate of FIG. 62 after it has been turned over.

As seen in FIG. 63B, an opening 4216 is formed by removing portions of substrate 4204 at locations not underlying vias 4211. Preferably, the entire thickness of the substrate 4204 is removed, leaving dielectric layers 4206, 4208, conductive layers 4207 and top passivation layer 4210 intact. Alternatively, dielectric layer 4206 may also be removed, leaving some or all of dielectric layers 4208 and top passivation layer 4210 intact. The removal of substrate 4204 may be achieved by using conventional etching techniques and, preferably, provides a volume of dimensions of around 100 to 200 microns in width and 1000 to 3000 microns in length.

As seen in FIG. 63C, the openings 4216 are filled by a suitable transparent optical adhesive 4217, such as OG 146, manufactured by Epoxy Technology, 14 Fortune Drive, Billerica, Mass. 01821, USA, whose refractive index preferably is precisely matched to that of cores of conventionally manufactured optical fibers, commercially available from manufacturers, such as Dow Corning of the U.S.A.

As seen in FIG. 63D, conductive bumps 4218, preferably metal bumps, such as solder bumps, are preferably formed onto the exposed surfaces of vias 4211. As seen in FIG. 63E, conductive bumps 4220, preferably metal bumps, such as solder bumps, are preferably formed onto the surfaces of integrated circuit chips 4222, which are preferably located below openings 4216. Integrated circuit chips 4222 are in conductive engagement with vias 4211 by the soldering of bumps 4218 to bumps 4220.

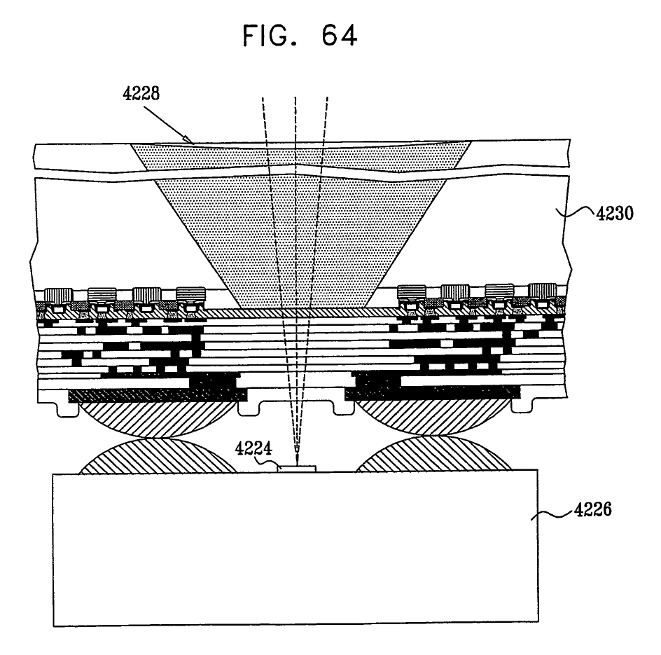

Reference is now made to FIG. 64, which is a simplified illustration of an integrated circuit of the type referenced in FIGS. 63A-63E, including a laser light source 4224 formed on an integrated circuit chip 4226, located below an opening 4228 formed in an integrated circuit substrate 4230.

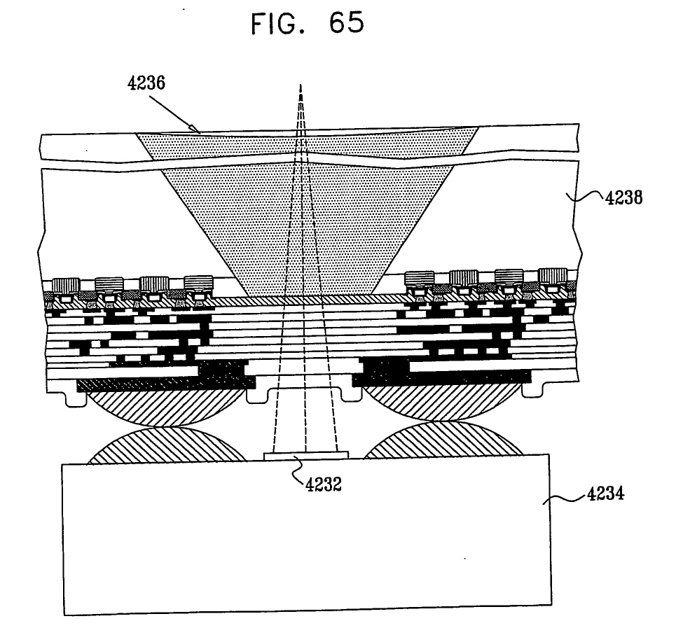

Reference is now made to FIG. 65, which is a simplified illustration of an integrated circuit of the type referenced in FIGS. 63A-63E, including an optical detector 4232 formed on an integrated circuit chip 4234, located below an opening 4236 formed in an integrated circuit substrate 4238.

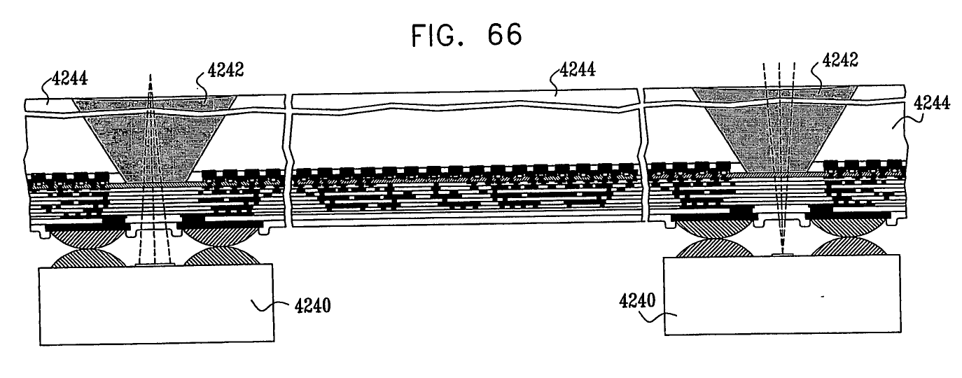

Reference is now made to FIG. 66, which is a simplified illustration of an integrated circuit of the type referenced in FIGS. 63A-63E, including multiple elements 4240 located below multiple openings 4242 formed within a substrate 4244. These elements may by any suitable electrical or electro-optic element.

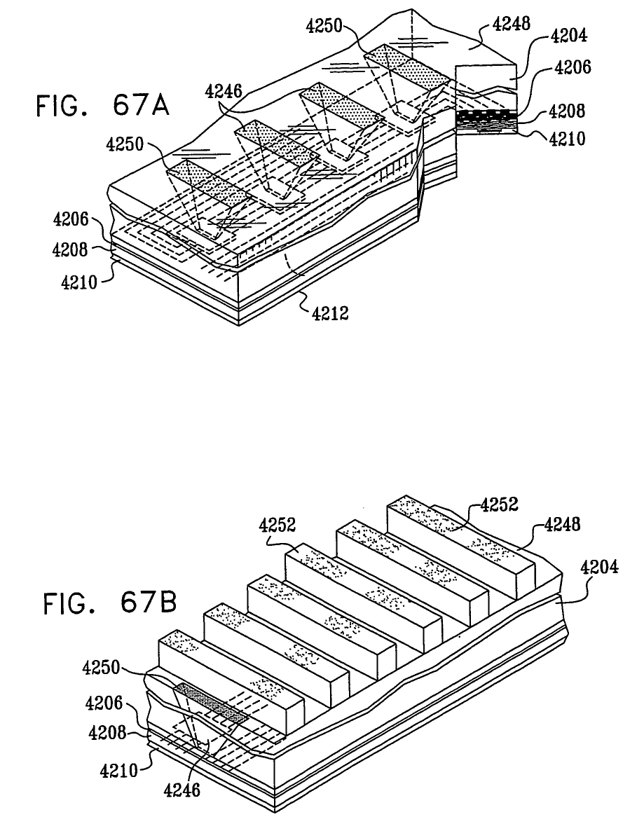

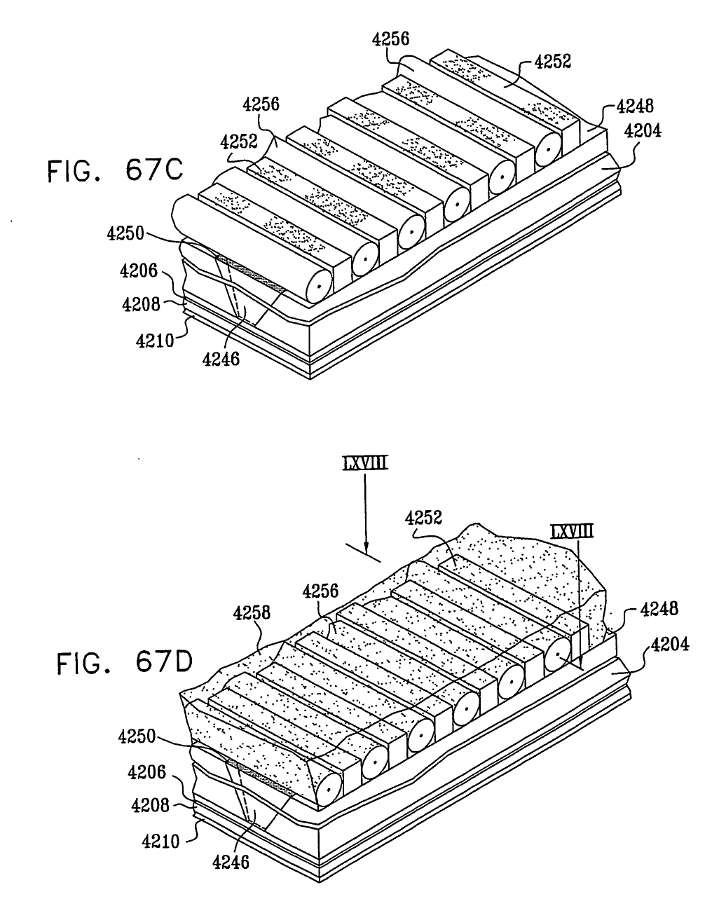

Reference is now made to FIGS. 67A, 67B, 67C and 67D, which are simplified pictorial illustrations of further stages in the production of an electro-optic integrated circuit. FIG. 67A shows the substrate of FIG. 62 after it has been turned over. Openings 4246 are formed on portions of substrate 4204 and filled by a transparent optical adhesive 4250, such as OG 146, manufactured by Epoxy Technology, 14 Fortune Drive, Billerica, Mass. 01821, USA, whose refractive index preferably is precisely matched to that of cores of optical fibers, commercially available from manufacturers such as Dow Corning of the U.S.A. Openings 4246 preferably extend from a second surface 4248 of substrate 4204, which is opposite first surface 4212, to dielectric layer 4206. Alternatively, openings 4246 extend through dielectric layer 4206 and partially or fully through dielectric layers 4208 to passivation layer 4210. After openings 4246 are filled with optical adhesive 4250, multiple electro-optical elements are assembled onto integrated circuit substrate 4204, as described hereinabove with reference to FIGS. 63E-66.

FIG. 67B shows an array of parallel, spaced, elongate optical fiber positioning elements 4252 that is preferably formed, such as by conventional photolithographic and etching techniques, over second surface 4248 of substrate 4204. Preferably, positioning elements 4252 are disposed intermediate openings 4246 filled with optical adhesive 4250.

As seen in FIG. 67C, an array of optical fibers 4256 is disposed over surface 4248 of substrate 4204, each fiber being positioned between adjacent positioning elements 4252. The fibers 4256 are fixed in place, relative to positioning elements 4252 and to surface 4248 of substrate 4204, by means of a suitable adhesive 4258, preferably epoxy, as seen in FIG. 67D, and preferably overlie openings 4246 filled with optical adhesive 4250.

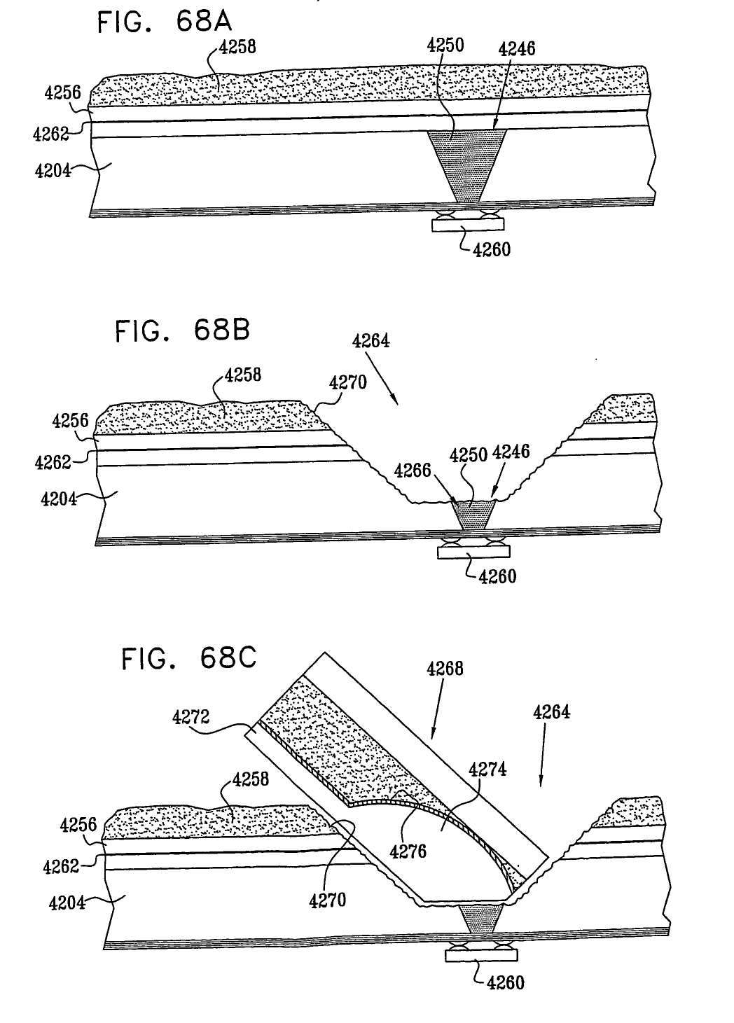

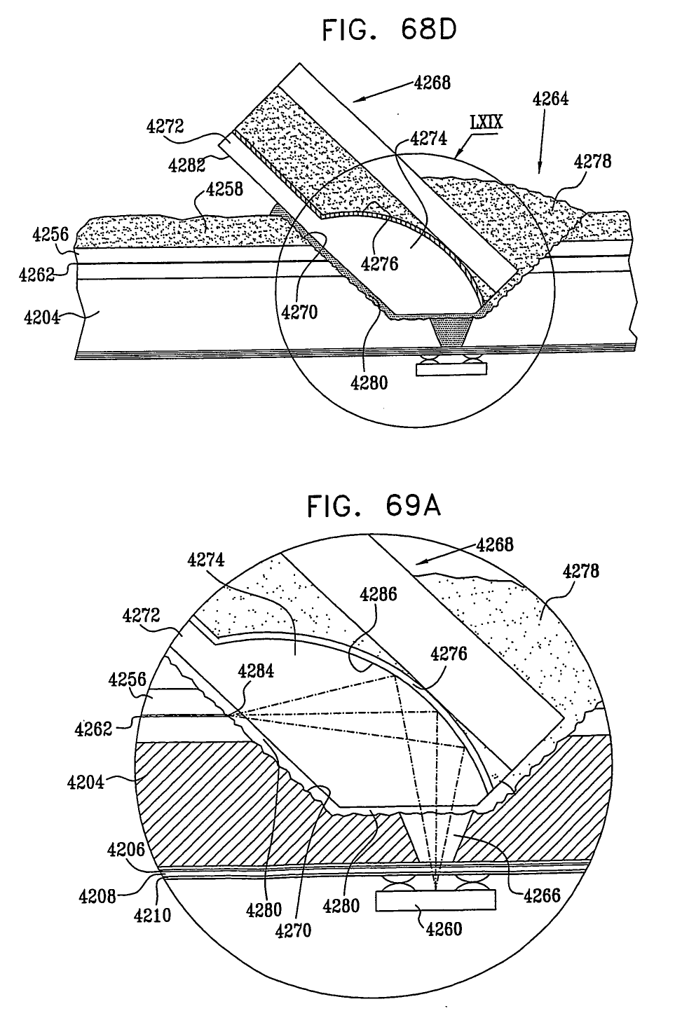

Reference is now made to FIGS. 68A, 68B, 68C, and 68D, which are simplified sectional illustrations, taken along the lines LXVIII-LXVIII in FIG. 67D, of additional stages in the production of an electro-optic integrated circuit. As seen in FIG. 68A, electro-optic components 4260, such as diode lasers, are mounted onto electrical circuits 4200 (FIG. 62). It is appreciated that electro-optic components 4260 may include any suitable electro-optic components, such as laser diodes, diode detectors, waveguides, array waveguide gratings or semiconductor optical amplifiers. As described hereinabove with reference to FIG. 67A, optical opening 4246 is formed by removing portions of substrate 4204 across the entire thickness of the substrate 4204, and filling the opening 4246 with transparent optical adhesive 4250, such as OG 146, manufactured by Epoxy Technology, 14 Fortune Drive, Billerica, Mass. 01821, USA, whose refractive index preferably is precisely matched to that of cores 4262 of the optical fibers 4256.

As shown in FIG. 68B, a transverse notch 4264 is preferably formed, at least partially overlapping the locations of the electro-optic components 4260 and extending through the adhesive 4258, entirely through each optical fiber 4256 and partially into both substrate 4204 and the optical adhesive 4250 in opening 4246. Specifically, the notch 4264 extends partly through openings 4246, defining an optical via 4266 filled with optically clear epoxy at the bottom of the notch 4264. It is appreciated that the surfaces 4270 defined by the notch 4264 are relatively rough, as shown.

Turning now to FIG. 68C, it is seen that a partially flat and partially concave mirror 4268 is preferably mounted parallel to one of the rough inclined surfaces 4270 defined by notch 4264. Mirror 4268 preferably comprises a glass substrate 4272 having formed thereon a curved portion 4274 over which is formed a curved metallic layer or a dichroic filter layer 4276. As seen in FIG. 68D, preferably, the mirror 4268 is securely held in place partially by any suitable adhesive 4278, such as epoxy, and partially by an optical adhesive 4280, such as OG 146, manufactured by Epoxy Technology, 14 Fortune Drive, Billerica, Mass. 01821, USA, whose refractive index preferably is precisely matched to that of the cores 4262 of the optical fibers 4256. It is appreciated that optical adhesive 4280 may be employed throughout instead of adhesive 4278. Optical adhesive 4280 preferably fills the interstices between the roughened surface 4270 defined by notch 4264 and a surface 4282 of mirror 4268.

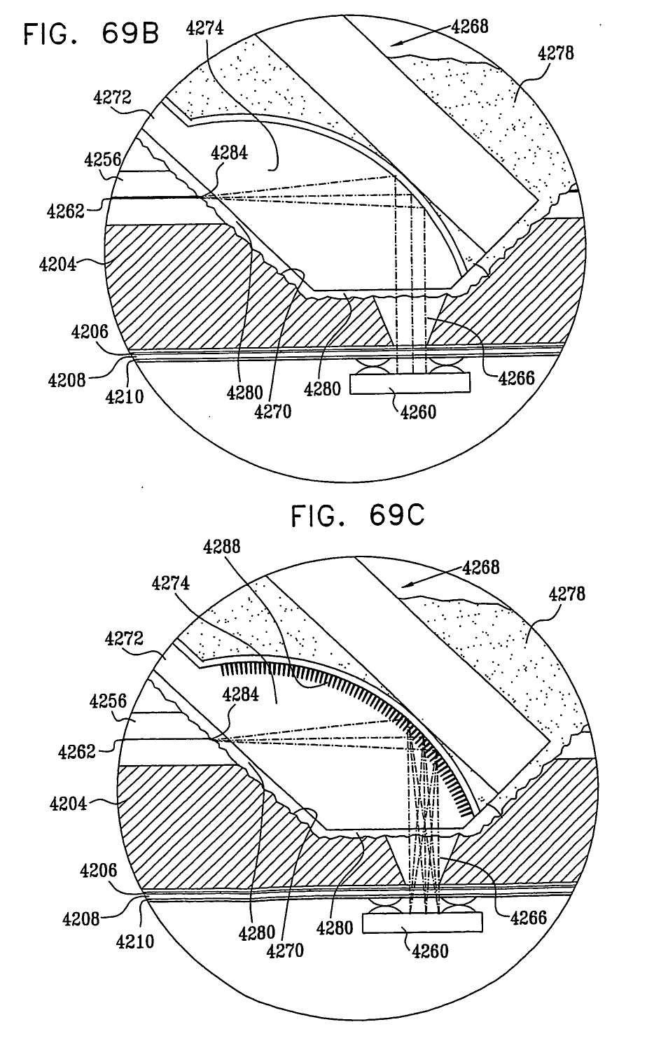

Reference is now made to FIG. 69A, which is an enlarged simplified optical illustration of a portion of FIG. 68D. Here it is seen that a generally uninterrupted optical path is defined for light, preferably in the wavelength range of 400-1650 nm, from an end 4284 of core 4262 of fiber 4256, through adhesive 4280, substrate 4272 and curved portion 4274 to a reflective surface 4286 of layer 4276 and thence through curved portion 4274, adhesive 4280, optical via 4266, layers 4206, 4208 and 4210 which are substantially transparent to this light. It is noted that the index of refraction of adhesive 4280 is identical to that of optical via 4266 and precisely matched to the index of refraction of the core 4262. In the embodiment of FIG. 69A, the operation of the curved reflective surface 4286 is to focus light exiting from end 4284 of core 4262 onto the electro-optic component 4260 or similarly to focus light exiting from the electro-optic component 4260 onto the end 4284 of core 4262.

Reference is now made to FIG. 69B, which is an enlarged simplified optical illustration of a portion of FIG. 68D, in accordance with a further embodiment of the present invention. In this embodiment, the curvature of curved layer 4274 produces collimation rather than focusing of the light exiting from end 4284 of core 4262 onto the electro-optic component 4260.

Reference is now made to FIG. 69C, which is an enlarged simplified optical illustration of a portion of FIG. 68D, in accordance with yet another embodiment of the present invention, wherein a grating 4288 is added to curved portion 4274. The additional provision of grating 4288 causes separation of light impinging thereon according to its wavelength, such that multi-spectral light exiting from end 4284 of core 4262 is focused at multiple locations on electro-optic component 4260 in accordance with the wavelengths of components thereof.

Reference is now made to FIG. 70, which is a simplified sectional illustration of an electro-optic integrated circuit constructed and operative in accordance with yet another preferred embodiment of the present invention. The embodiment of FIG. 70 corresponds generally to that described hereinabove with respect to FIG. 68D, other than in that a mirror with multiple concave reflective surfaces is provided rather than a mirror with a single such reflective surface. As seen in FIG. 70, light from an optical fiber 4316, having a core 4318, is directed onto an electro-optic component 4320 by a partially flat and partially concave mirror assembly 4330, preferably mounted parallel to one of the rough inclined surfaces 4332 defined by a notch 4333 in a substrate 4334.

Mirror assembly 4330 preferably comprises a glass substrate 4335 having formed thereon a plurality of curved portions 4336 over which is formed a curved metallic layer or a dichroic filter layer 4338. Mirror assembly 4330 also defines a reflective surface 4340, which is disposed on a planar surface 4342 generally opposite layer 4338. Preferably, the mirror assembly 4330 is securely held in place partially by any suitable adhesive 4343, such as epoxy, and partially by an optical adhesive 4344, such as OG 146, manufactured by Epoxy Technology, 14 Fortune Drive, Billerica, Mass. 01821, USA, whose refractive index preferably is precisely matched to that of core 4318 of the optical fiber 4316 and identical to an adhesive used to fill an optical via 4346. It is appreciated that optical adhesive 4344 may be employed throughout instead of adhesive 4343. The optical adhesive 4344 preferably fills the interstices between the roughened surface 4332 defined by notch 4333 and surface 4342 of mirror assembly 4330.

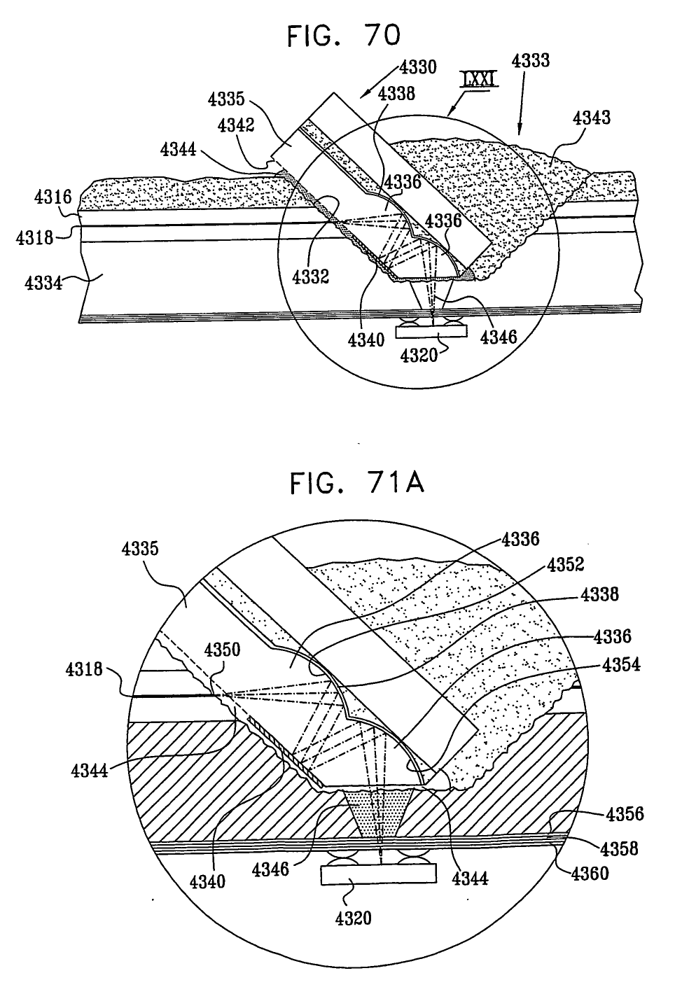

Reference is now made to FIG. 71A, which is an enlarged simplified optical illustration of a portion of FIG. 70. Here it is seen that a generally uninterrupted optical path is defined for light, preferably in the wavelength range of 400-1650 nm, from an end 4350 of core 4318, through adhesive 4344, substrate 4335 and first curved portion 4336, to a curved reflective surface 4352 of layer 4338 and thence through first curved portion 4336 and substrate 4335 to reflective surface 4340, from reflective surface 4340 through substrate 4335 and second curved portion 4336 to another curved reflective surface 4354 of layer 4338 and thence through second curved portion 4336, substrate 4335, adhesive 4344, optical via 4346 and dielectric layers 4356, 4358 and 4360, which are substantially transparent to this light.

It is noted that the index of refraction of adhesive 4344 is close to but not identical to that of substrate 4335. In the embodiment of FIG. 71A, the operation of curved layer 4338 and reflective surface 4340 is to focus light exiting from end 4350 of core 4318 onto the electro-optic component 4320.

Reference is now made to FIG. 71B, which is an enlarged simplified optical illustration of a portion of FIG. 70, in accordance with a further embodiment of the present invention. In this embodiment, the curvature of curved layer 4338 produces collimation rather than focusing of the light exiting from end 4350 of core 4318 onto the electro-optic component 4320.

Reference is now made to FIG. 71C, which is an enlarged simplified optical illustration of a portion of FIG. 70, in accordance with yet another embodiment of the present invention, wherein a reflective grating 4362 replaces reflective surface 4340 (FIG. 70). The additional provision of grating 4362 causes separation of light impinging thereon according to its wavelength, such that multi-spectral light exiting from end 4350 of core 4318 is focused at multiple locations on electro-optic component 4320 in accordance with the wavelengths of components thereof.

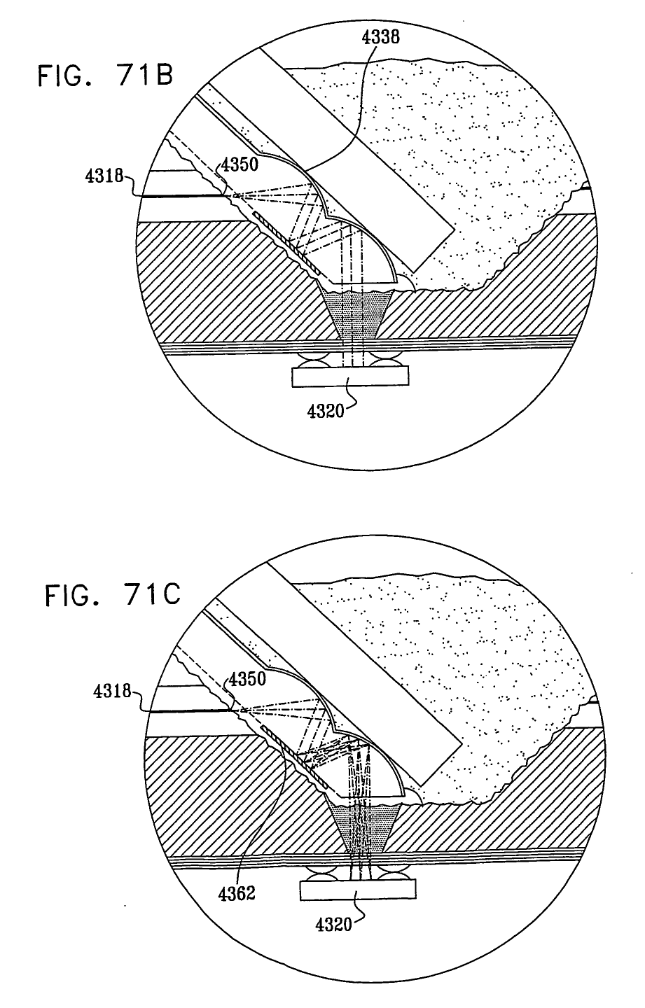

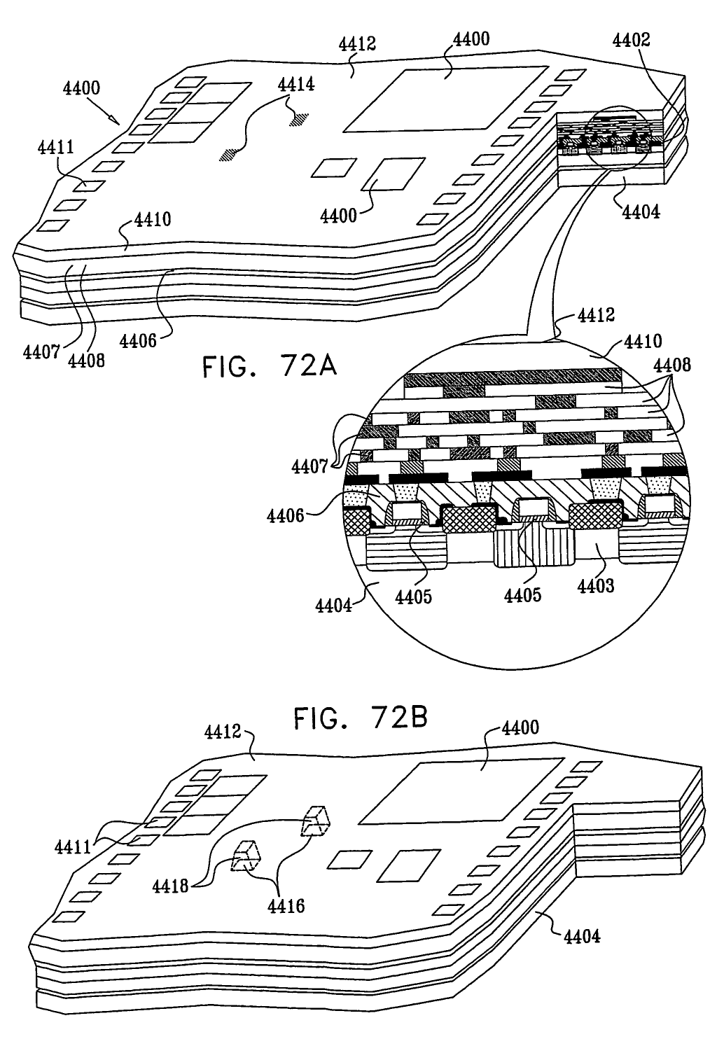

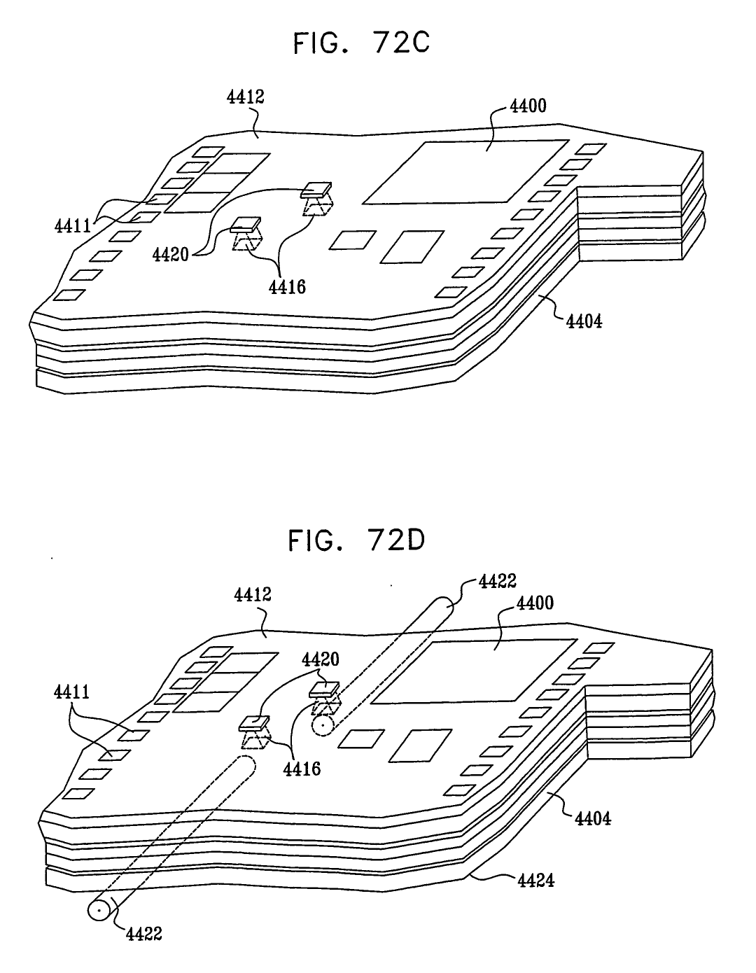

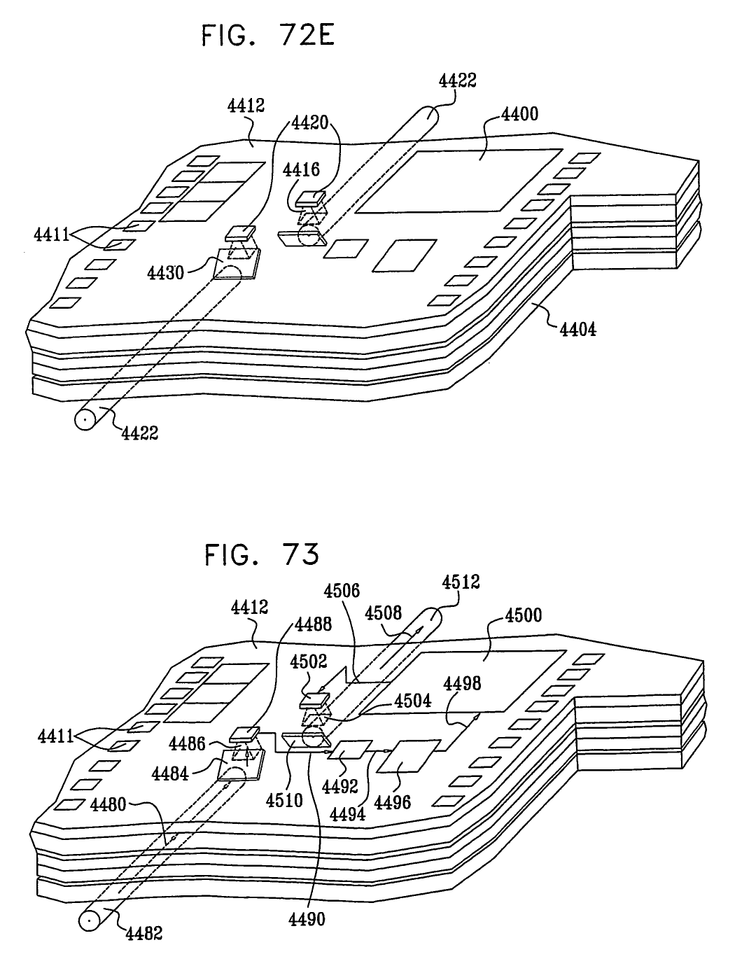

Reference is now made to FIGS. 72A, 72B, 72C, 72D and 72E, which are simplified pictorial illustrations of stages in the production of an electro-optic integrated circuit, constructed and operative in accordance with still another preferred embodiment of the present invention.

As seen in FIG. 72A, one or more semiconductor functional blocks 4400 are preferably formed onto a first surface 4402 of an optional epitaxial layer 4403 of a substrate 4404. The epitaxial layer 4403 is typically formed of silicon and has a thickness of between 2-10 microns, while the substrate 4404 is typically formed of silicon and has a thickness of 200-1000 microns. Semiconductor functional blocks 4400 are preferably formed onto substrate 4404 by conventional photolithographic and thin film processing techniques employed in the production of integrated circuits. Semiconductor functional blocks 4400 preferably include transistors 4405 formed in layer 4403, covered by a dielectric layer 4406, over which are typically formed a plurality of metal conductive layers 4407 interspersed with dielectric layers 4408, covered by a top passivation layer 4410. The dielectric layers are preferably transparent to light preferably in both the visible and the infrared bands within at least part of the wavelength range of 400-1650 nin. Vias 4411, connected to at least one conductive layer 4407, extend through layer 4410 to the top surface 4412. One or more semiconductor functional blocks 4400 are preferably formed on substrate 4404.

FIG. 72A also shows locations 4414 of openings 4416 formed, as shown in FIG. 72B, by removing portions of substrate 4404. It is noted that locations 4414 do not underlie vias 4411. Preferably, the entire thickness of the substrate 4404 is removed at locations 4414, leaving dielectric layers 4406 and 4408 and conductive layers 4407 intact. Alternatively, dielectric layer 4406 may also be removed, leaving some or all of dielectric layers 4408 intact. The removal of substrate 4404 may be achieved by using conventional etching techniques and, preferably, provides a volume of dimensions of around 100 to 200 microns in width and 1000 to 3000 microns in length. The openings 4416 are filled with an optical adhesive 4418, such as OG 146, manufactured by Epoxy Technology, 14 Fortune Drive, Billerica, Mass. 01821, USA, whose refractive index preferably is precisely matched to that of the cores of optical fibers, commercially available from manufacturers such as Dow Corning of the U.S.A.

As seen in FIG. 72C, integrated circuit chips 4420 are preferably located above openings 4416. These chips may be operatively engaged with vias (not shown) by being soldered to bumps (not shown), as illustrated for example in FIG. 63E, thus creating an optoelectronic integrated circuit, wherein integrated circuit chips 4420 reside above the substrate of the integrated circuit.

As seen in FIG. 72D, one or more fibers 4422 are fixed underneath a bottom surface 4424 of substrate 4404, preferably by an adhesive (not shown), similarly to that shown in FIGS. 67C and 67D. Multiple fibers 4422 may be identical, similar or different and need not be arranged in a mutually aligned spatial relationship.

As shown in FIG. 72E, it is seen that a mirror 4430, typically of the type illustrated in any of FIGS. 68C-71C, is preferably mounted in operative engagement with each fiber 4422.

Reference is now made to FIG. 73, which is a simplified functional illustration of a preferred embodiment of the structure of FIG. 72E. As seen in FIG. 73, a high frequency optical signal 4480, typically of frequency 10 to 40 GHz, passes through an optical fiber 4482 and is reflected by a mirror 4484 through a recess 4486 onto a diode 4488, which is located above the recess 4486. An output electrical signal 4490 from diode 4488 may be supplied to an amplifier 4492, which may be formed on the silicon substrate circuitry. The amplified output 4494 of amplifier 4492 may be provided to a serializer/deserializer 4496, which may be formed on the silicon substrate circuitry.

An output signal 4498 from serializer/deserializer 4496 is preferably fed to one or more semiconductor functional blocks 4500 for further processing. A laser 4502, which may be located above a recess 4504, may employ an electrical output 4506 from functional block 4500 to produce a modulated light beam 4508, which is reflected by a mirror 4510 through recess 4504 to pass through a fiber 4512. It is appreciated that electro-optic integrated circuit devices 4488 and 4502 may be configured to operate as either a light transmitter or a light receiver or both.

It is appreciated that in addition to the substrate materials described hereinabove, the substrates may comprise silicon, silicon germanium, silicon on sapphire, silicon on insulator (SOI), gallium arsenide, indium phosphide or any other suitable material.

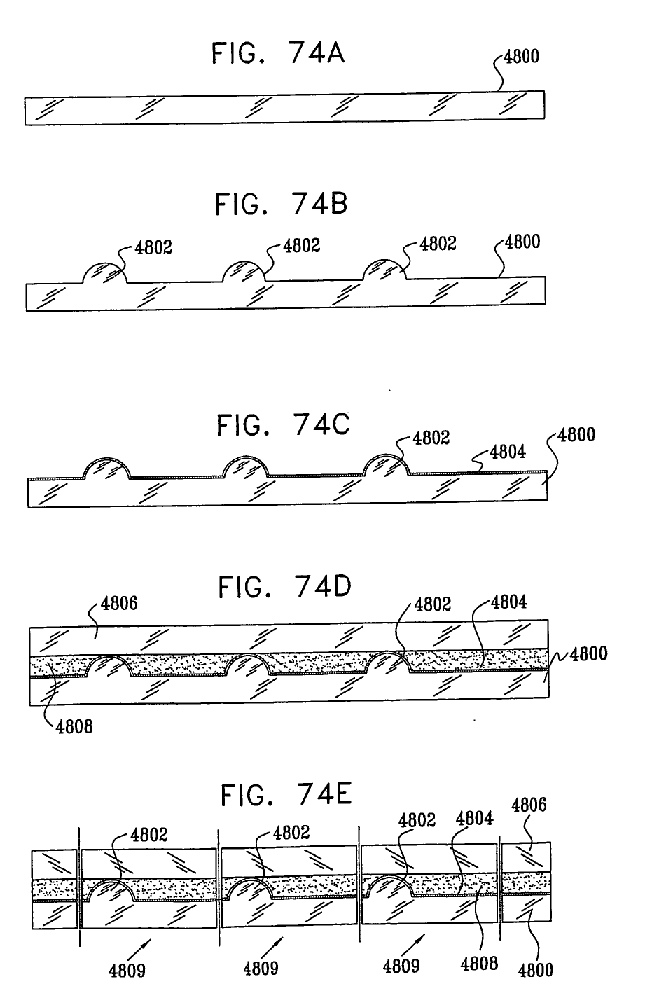

Reference is now made to FIGS. 74A, 74B, 74C, 74D and 74E, which are simplified illustrations of a method for fabricating optical elements employed in the embodiments of FIGS. 62-73 and FIGS. 81A-87 in accordance with one embodiment of the present invention. FIG. 74A shows a glass substrate 4800, typically of thickness 200-400 microns. Substrate 4800 has formed thereon an array of microlenses 4802, typically formed of photoresist, as seen in FIG. 74B. The microlenses 4802 preferably have an index of refraction that is identical or very close to that of substrate 4800. The microlenses may be formed by one or more conventional techniques, such as photolithography and thermal reflow, photolithography using of a grey scale mask, jet printing and pattern transfer onto the substrate by etching.

A thin metal layer 4804, typically aluminum, is formed over the substrate 4800 and microlenses 4802 as seen in FIG. 74C, typically by evaporation or sputtering. A glass cover layer 4806 is preferably formed over the array of microlenses 4802 and sealed thereover by an adhesive 4808 in FIG. 74D. The substrate 4800, the metal layer 4804 formed thereon and the glass cover layer 4806 and associated adhesive 4808 are then diced by conventional techniques, as shown in FIG. 74E, thereby defining individual optical elements 4809, each including a curved portion defined by microlens 4802.

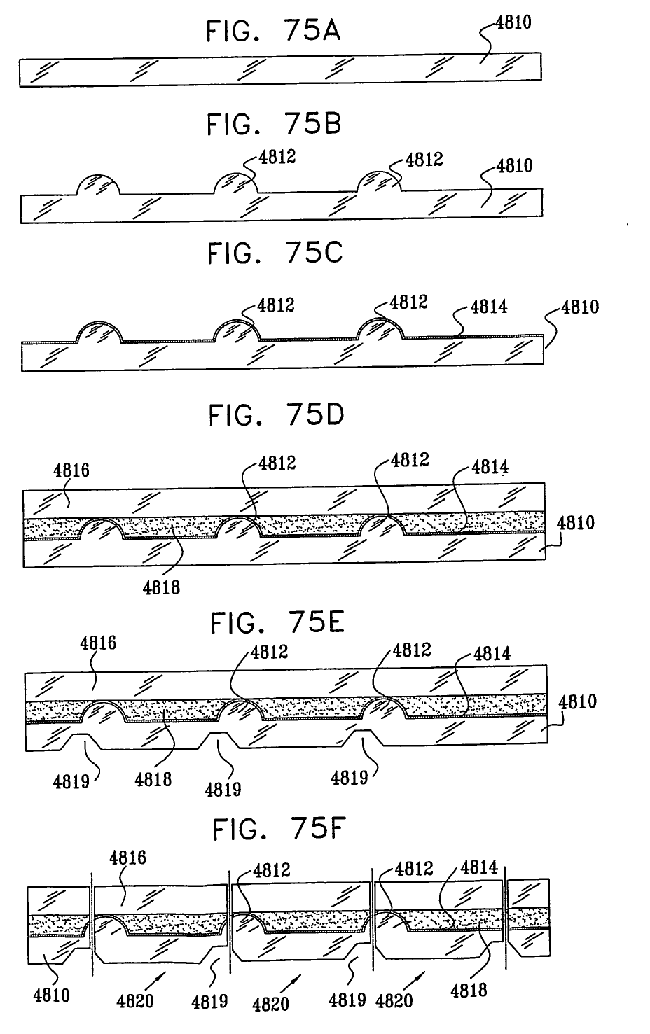

Reference is now made to FIGS. 75A, 75B, 75C, 75D, 75E and 75F, which are simplified illustrations of a method for fabricating optical elements employed in the embodiments of FIGS. 62-73 and FIGS. 81A-87 in accordance with another embodiment of the present invention. A glass substrate 4810, typically of thickness 200-400 microns, seen in FIG. 75A, has formed thereon an array of microlenses 4812, typically formed of photoresist, as seen in FIG. 75B. The microlenses 4812 preferably have an index of refraction that is identical or very close to that of substrate 4810. The microlenses may be formed by one or more conventional techniques, such as photolithography and thermal reflow, photolithography using of a grey scale mask, jet printing and pattern transfer onto the substrate by etching.

A thin metal layer 4814, typically aluminum, is formed over the substrate 4810 and microlenses 4812 as seen in FIG. 75C, typically by evaporation or sputtering. A glass cover layer 4816 is preferably formed over the array of microlenses 4812 and sealed thereover by an adhesive 4818 as seen in FIG. 75D. The substrate 4810 is then notched from underneath by conventional techniques. As seen in FIG. 75E, notches 4819 are preferably formed at locations partially underlying microlenses 4812.

Following notching, the substrate 4810, the microlenses 4812, the metal layer 4814 formed thereon, the glass cover layer 4816 and the adhesive 4818 are diced by conventional techniques, as shown in FIG. 75F, at locations intersecting inclined walls of the notches 4819, thereby defining individual optical elements 4820, each including a curved portion defined by part of microlens 4812.

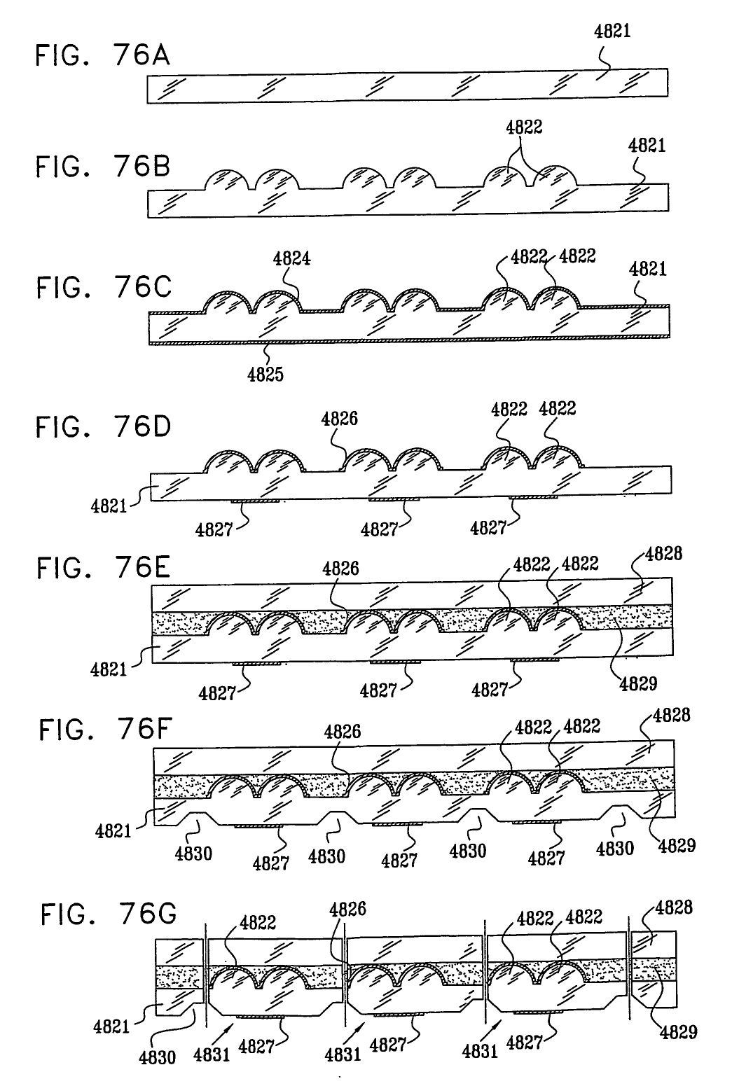

Reference is now made to FIGS. 76A, 76B, 76C, 76D, 76E, 76F and 76G, which are simplified illustrations of a method for fabricating optical elements employed in the embodiments of FIGS. 62-73 and FIGS. 81A-87 in accordance with yet another embodiment of the present invention. A glass substrate 4821, typically of thickness 200-400 microns, seen in FIG. 76A, has formed thereon an array of microlenses 4822, typically formed of photoresist, as seen in FIG. 76B. The microlenses 4822 preferably have an index of refraction that is identical or very close to that of substrate 4821. The microlenses may be formed by one or more conventional techniques, such as photolithography and thermal reflow, photolithography using of a grey scale mask, jet printing and pattern transfer onto the substrate by etching.

A thin metal layer 4824, typically aluminum, is formed over the substrate 4821 and microlenses 4822 as seen in FIG. 76C, typically by evaporation or sputtering. An additional metal layer 4825, typically aluminum, is similarly formed on an opposite surface of substrate 4821. Metal layers 4824 and 4825 are patterned typically by conventional photolithographic techniques to define respective reflective surfaces 4826 and 4827 as seen in FIG. 76D. A glass cover layer 4828 is preferably formed over the array of microlenses 4822 and sealed thereover by an adhesive 4829 as seen in FIG. 76E.

The substrate 4821 is notched from underneath by conventional techniques. As seen in FIG. 76F, notches 4830 need not be at locations partially underlying microlenses 4822. Following notching, the substrate 4821, the microlenses 4822, the metal layers 4824 and 4825 (FIG. 76C), the glass cover layer 4828 and the adhesive 4829 are diced by conventional techniques, as shown in FIG. 76G, at locations intersecting inclined walls of the notches 4830, thereby defining individual optical elements 4831, each including curved reflective portion 4826 defined by a pair of microlenses 4822, as well as flat reflective surface 4827.

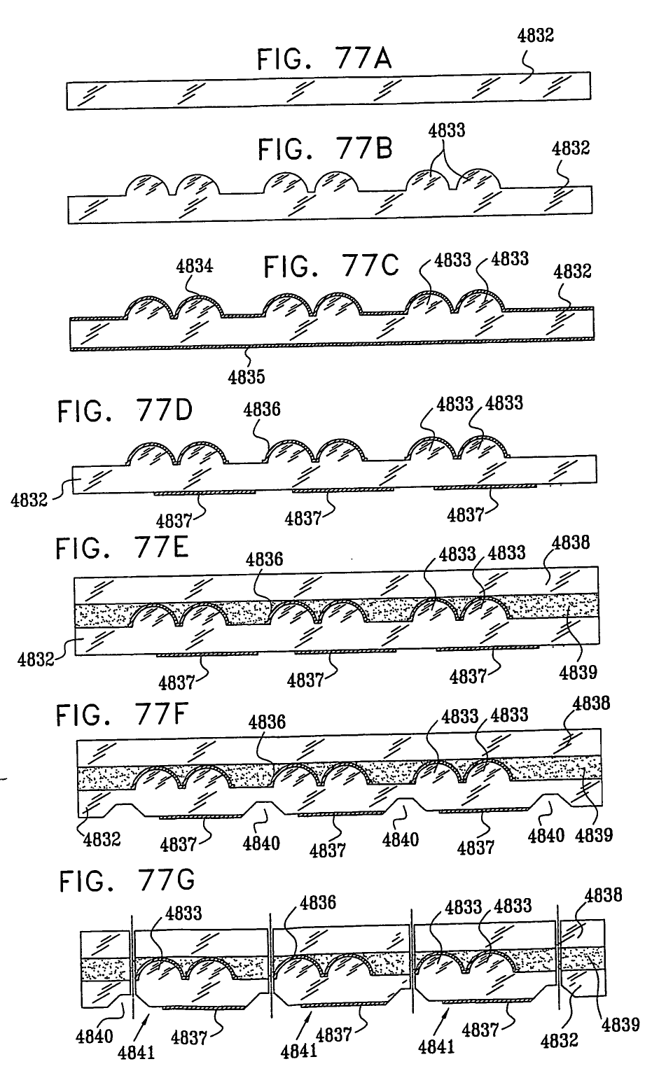

Reference is now made to FIGS. 77A, 77B, 77C, 77D, 77E, 77F and 77G, which are simplified illustrations of a method for fabricating optical elements employed in the embodiments of FIGS. 62-73 and FIGS. 81A-87 in accordance with still another embodiment of the present invention. A glass substrate 4832, typically of thickness 200-400 microns, seen in FIG. 77A, has formed thereon an array of pairs of microlenses 4833, typically formed of photoresist, as seen in FIG. 77B. The microlenses 4833 preferably have an index of refraction that is identical or very close to that of substrate 4832. The microlenses may be formed by one or more conventional techniques, such as photolithography and thermal reflow, photolithography using of a grey scale mask, jet printing and pattern transfer onto the substrate by etching.

A thin metal layer 4834, typically aluminum, is formed over the substrate 4832 and pairs of microlenses 4833, as seen in FIG. 77C, typically by evaporation or sputtering. An additional metal layer 4835, typically aluminum, is similarly formed on an opposite surface of substrate 4832. Metal layers 4834 and 4835 are patterned, typically by conventional photolithographic techniques, to define respective reflective surfaces 4836 and 4837 as seen in FIG. 77D. A glass cover layer 4838 is preferably formed over the array of microlenses 4833 and sealed thereover by an adhesive 4839 as seen in FIG. 77E.

The substrate 4832 is notched from underneath by conventional techniques, defining notches 4840, as seen in FIG. 77F. Following notching, the substrate 4832, the microlenses 4833, the metal layers 4834 and 4835 (FIG. 77C), the glass cover layer 4838 and the adhesive 4839 are diced by conventional techniques, as shown in FIG. 77G, at locations intersecting inclined walls of the notches 4840, thereby defining individual optical elements 4841, each including curved reflective surface 4836 defined by a pair of microlenses 4833, as well as flat reflective surface 4837.

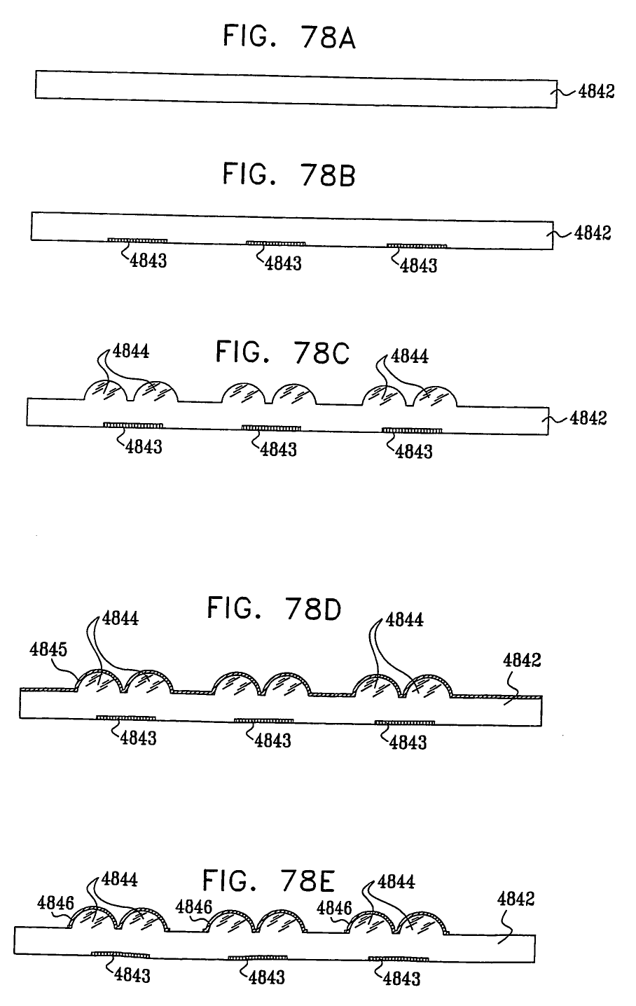

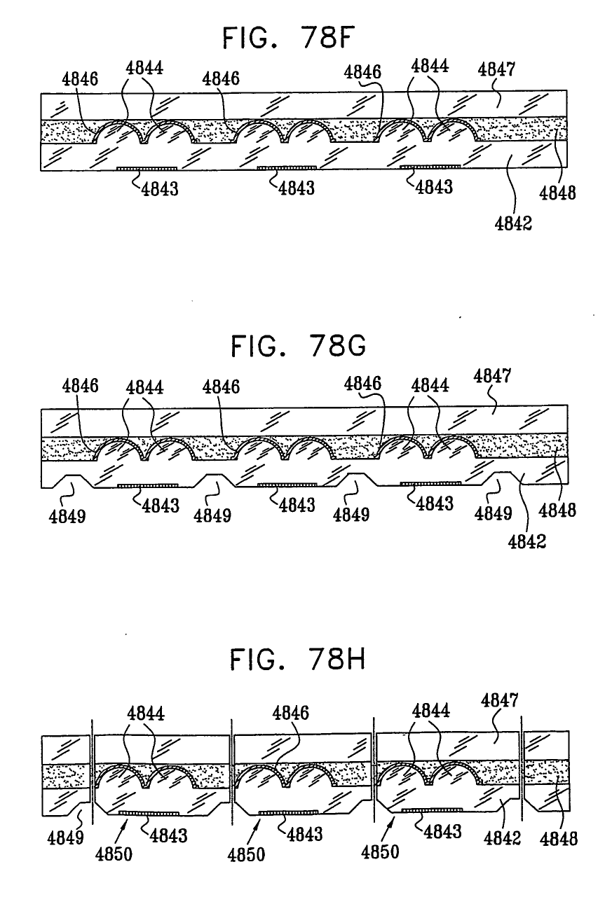

Reference is now made to FIGS. 78A, 78B, 78C, 78D, 78E, 78F, 78G and 78H, which are simplified illustrations of a method for fabricating optical elements employed in the embodiments of FIGS. 62-73 and FIGS. 81A-87 in accordance with a further embodiment of the present invention. A glass substrate 4842, typically of thickness 200-400 microns, seen in FIG. 78A, has formed in an underside surface thereof an array of reflective diffraction gratings 4843, as seen in FIG. 78B, typically by etching. Alternatively, the gratings 4843 may be formed on the surface of the substrate 4842, typically by lithography or transfer. An array of pairs of microlenses 4844, typically formed of photoresist, is formed on an opposite surface of substrate 4842, as seen in FIG. 78C. The microlenses 4844 preferably have an index of refraction that is identical or very close to that of substrate 4842. The microlenses may be formed by one or more conventional techniques, such as photolithography and thermal reflow, photolithography using of a grey scale mask, jet printing and pattern transfer onto the substrate by etching.

A thin metal layer 4845, typically aluminum, is formed over the substrate 4842 and pairs of microlenses 4844 as seen in FIG. 78D, typically by evaporation or sputtering. Metal layer 4845 is preferably patterned, typically by conventional photolithographic techniques, to define a reflective surface 4846, as seen in FIG. 78E. A glass cover layer 4847 is preferably formed over the array of microlenses 4844 and sealed thereover by an adhesive 4848 as seen in FIG. 78F.

The substrate 4842 is notched from underneath by conventional techniques, defining notches 4849, as seen in FIG. 78G. Following notching, the substrate 4842, the microlenses 4844, the metal layer 4845 (FIG. 78D), the glass cover layer 4847 and the adhesive 4848 are diced by conventional techniques, as shown in FIG. 78H, at locations intersecting inclined walls of the notches 4849, thereby defining individual optical elements 4850, each including curved reflective portion 4846 defined by a pair of microlenses 4844 as well as flat reflective grating 4843.

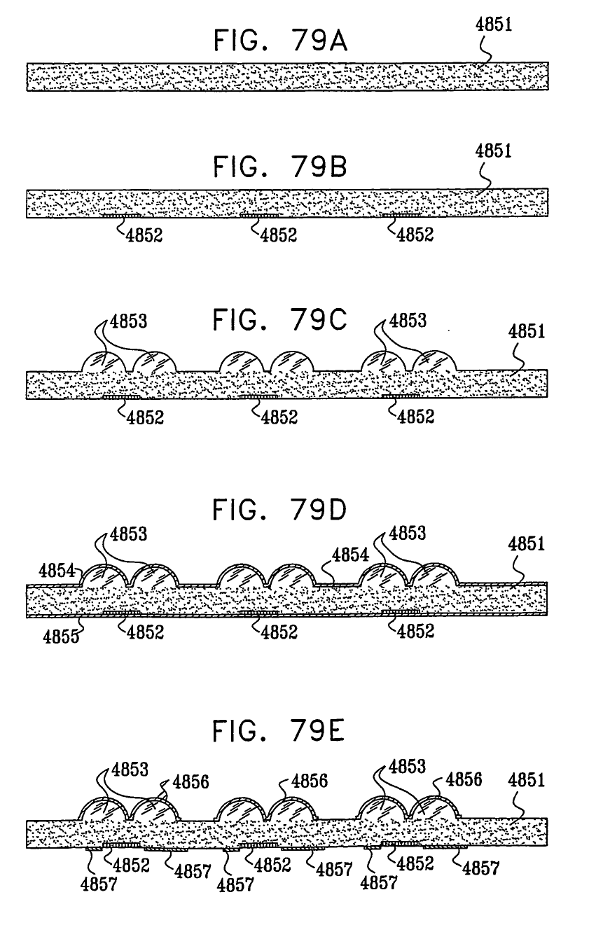

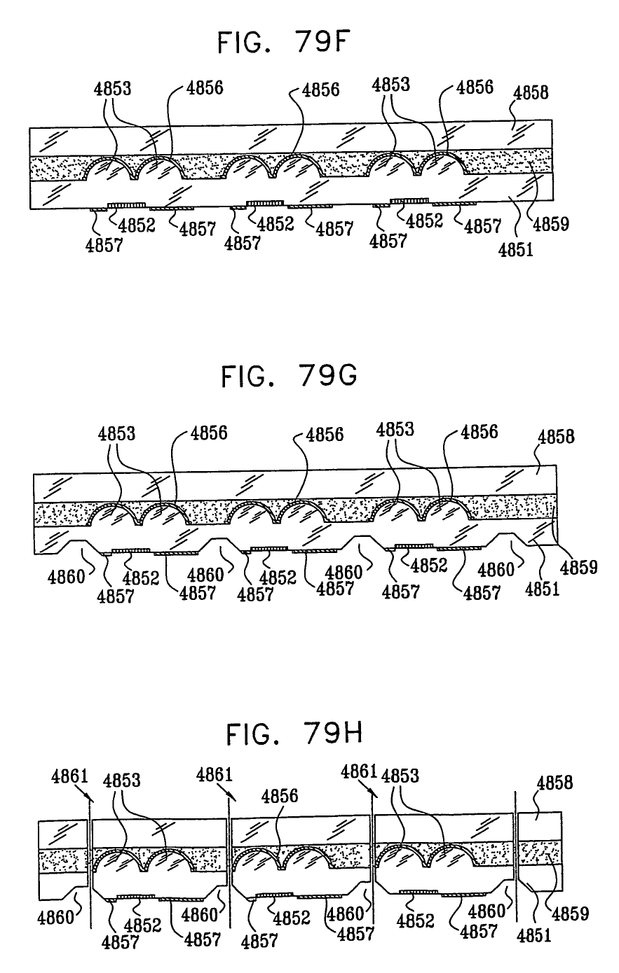

Reference is now made to FIGS. 79A, 79B, 79C, 79D, 79E, 79F, 79G and 79H, which are simplified illustrations of a method for fabricating optical elements employed in the embodiments of FIGS. 62-73 and FIGS. 81A-87 in accordance with yet a further embodiment of the present invention. A glass substrate 4851, typically of thickness 200-400 microns, seen in FIG. 79A, has formed in an underside surface thereof an array of reflective diffraction gratings 4852, as seen in FIG. 79B, typically by etching. Alternatively, the gratings 4852 may be formed on the surface of the substrate 4851, typically by lithography or transfer. An array of pairs of microlenses 4853, typically formed of photoresist, is formed on an opposite surface of substrate 4851, as seen in FIG. 79C. The microlenses 4853 preferably have an index of refraction that is identical or very close to that of substrate 4851. The microlenses may be formed by one or more conventional techniques, such as photolithography and thermal reflow, photolithography using of a grey scale mask, jet printing and pattern transfer onto the substrate by etching.

A thin metal layer 4854, typically aluminum, is formed over the substrate 4851 and pairs of microlenses 4853 as seen in FIG. 79D, typically by evaporation or sputtering. An additional metal layer 4855 is similarly formed on an opposite surface of the substrate 4851. Metal layers 4854 and 4855 are preferably patterned, typically by conventional photolithographic techniques, to define respective reflective surfaces 4856 and 4857, as seen in FIG. 79E. A glass cover layer 4858 is preferably formed over the array of microlenses 4853 and sealed thereover by an adhesive 4859 as seen in FIG. 79F.

The substrate 4851 is notched from underneath by conventional techniques, defining notches 4860, as seen in FIG. 79G. Following notching, the substrate 4851, the microlenses 4853, the metal layers 4854 and 4855 (FIG. 79D), the glass cover layer 4858 and the adhesive 4859 are diced by conventional techniques, as shown in FIG. 79H, at locations intersecting inclined walls of the notches 4860, thereby defining individual optical elements 4861, each including curved reflective surface 4856 defined by a pair of microlenses 4853 as well as flat reflective grating 4852 and flat reflective surfaces 4857.

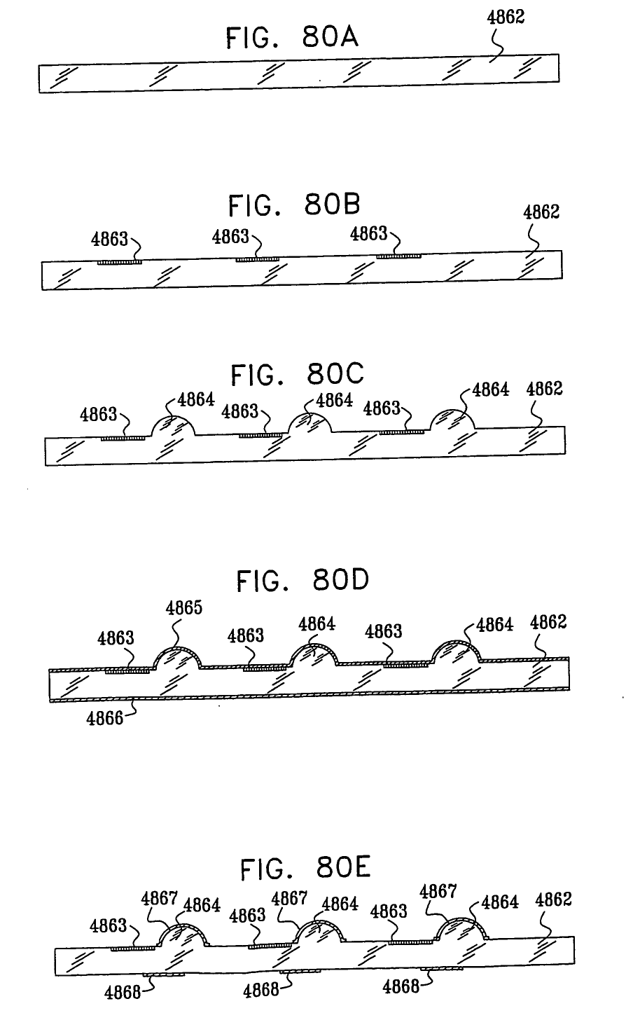

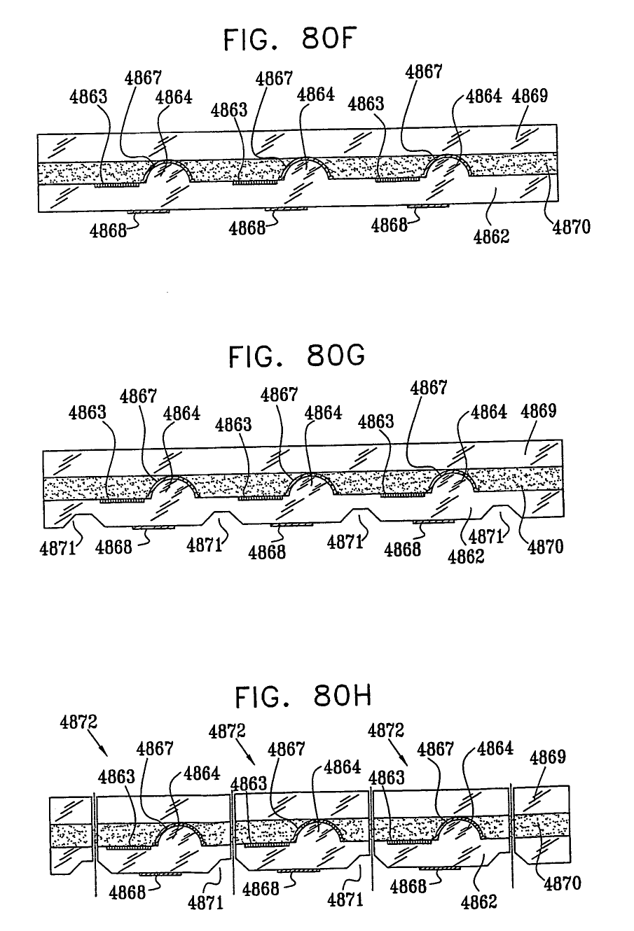

Reference is now made to FIGS. 80A, 80B, 80C, 80D, 80E, 80F, 80G and 80H, which are simplified illustrations of a method for fabricating optical elements employed in the embodiments of FIGS. 62-73 and FIGS. 81A-87 in accordance with still a further embodiment of the present invention. A glass substrate 4862, typically of thickness 200-400 microns, seen in FIG. 80A, has formed therein an array of reflective diffraction gratings 4863, as seen in FIG. 80B, typically by etching. Alternatively, the gratings 4863 may be formed on the surface of the substrate 4862, typically by lithography or transfer. An array of microlenses 4864, typically formed of photoresist, is formed on the same surface of substrate 4862, as seen in FIG. 80C. The microlenses 4864 preferably have an index of refraction which is identical or very close to that of substrate 4862. The microlenses may be formed by one or more conventional techniques, such as photolithography and thermal reflow, photolithography using of a grey scale mask, jet printing and pattern transfer onto the substrate by etching.

A thin metal layer 4865, typically aluminum, is formed over the substrate 4862 and microlenses 4864 as seen in FIG. 80D, typically by evaporation or sputtering. An additional metal layer 4866 is similarly formed on an opposite surface of the substrate 4862. Metal layers 4865 and 4866 are preferably patterned, typically by conventional photolithographic techniques, to define respective reflective surfaces 4867 and 4868, as seen in FIG. 80E. A glass cover layer 4869 is preferably formed over the array of microlenses 4864 and sealed thereover by an adhesive 4870 as seen in FIG. 80F.

The substrate 4862 is notched from underneath by conventional techniques, defining notches 4871, as seen in FIG. 80G. Following notching, the substrate 4862, the microlenses 4864, the metal layers 4865 and 4866 (FIG. 80D), the glass cover layer 4869 and the adhesive 4870 are diced by conventional techniques, as shown in FIG. 80H, at locations intersecting inclined walls of the notches 4871, thereby defining individual optical elements 4872, each including curved reflective surface 4867 defined by microlens 4864 as well as flat reflective grating 4863 and a flat reflective surface 4868.

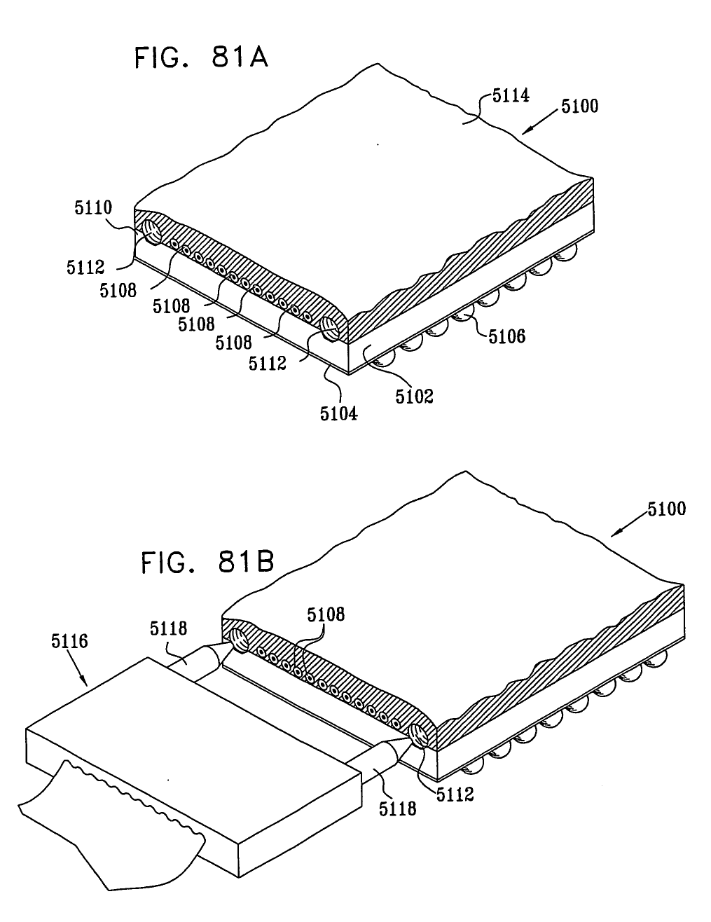

Reference is now made to FIGS. 81A and 81B, which are simplified pictorial illustrations of a packaged electro-optic integrated circuit 5100, having integrally formed therein an optical connector and electrical connections, alone and in conjunction with a conventional optical connector.

As seen in FIGS. 81A and 81B, a packaged electro-optic integrated circuit 5100 is provided in accordance with a preferred embodiment of the present invention, preferably in accordance with the teachings presented hereinabove with reference to FIGS. 1A-51 and 62-80H, and includes a semiconductor substrate 5102, typically silicon, silicon germanium, gallium arsenide or indium phosphide. Electrical circuitry (not shown) is formed, as by conventional photolithographic and thin film processing techniques generally used for the manufacturing production of CMOS and other integrated circuits, over one surface of substrate 5102 and is encapsulated by a layer 5104 of a protective material such as silicon dioxide, silicon nitride, silicon oxy-nitride, or BCB, commercially available from Dow Corning of the U.S.A., or any other suitable passivation layer. An array 5106 of electrical connections, preferably in the form of conventional solder bumps, communicates with the electrical circuitry via conductive pathways (not shown) extending through the protective material of layer 5104.

Formed on a surface of substrate 5102 opposite to that adjacent layer 5104 there are defined optical pathways (not shown) which communicate with an array of optical fibers 5108, whose ends are aligned along an edge 5110 of the substrate 5102. Preferably, physical alignment bores 5112 are aligned with the array of optical fibers 5108. The bores 5112 are preferably defined by cylindrical elements, which, together with the optical fibers 5108 and the optical pathways, are encapsulated by a layer 5114 of protective material, preferably epoxy.

FIG. 81B shows a conventional MT type optical connector 5116, such as an MT connector manufactured by SENKO Advanced Components, Inc. of Marlborough, Mass., USA, arranged for mating contact with the packaged electro-optic circuit 5100, wherein alignment pins 5118 of connector 5116 are arranged to seat in alignment bores 5112 of the electro-optic circuit 5100. Optical fiber ends (not shown) of connector 5116 are arranged in butting aligned relationship with the ends of the array 5108 of optical fibers in packaged electro-optic circuit 5100.

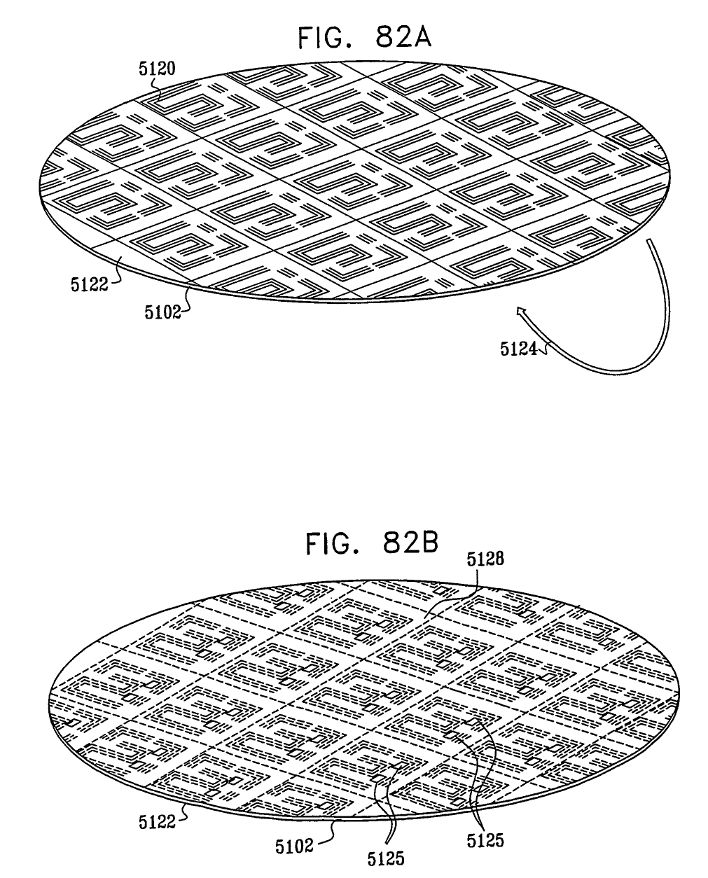

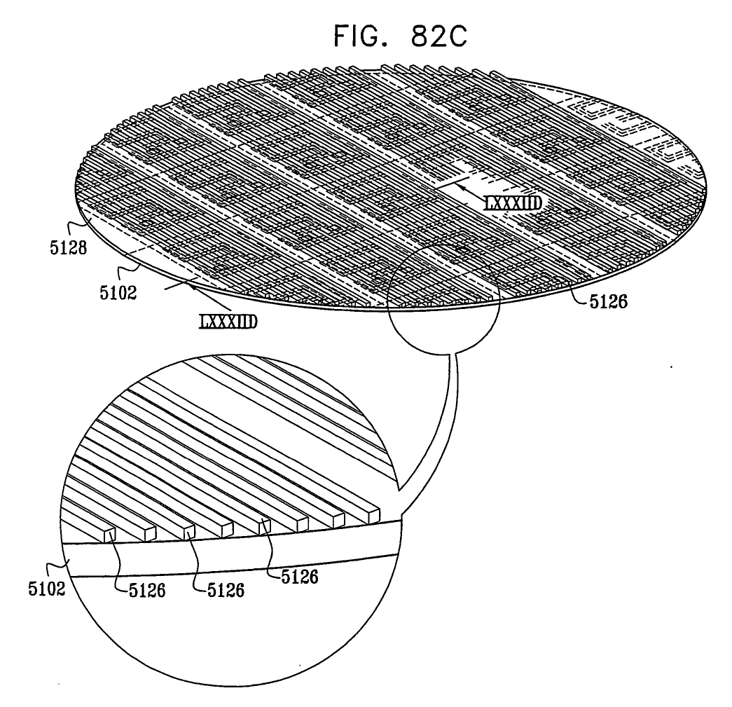

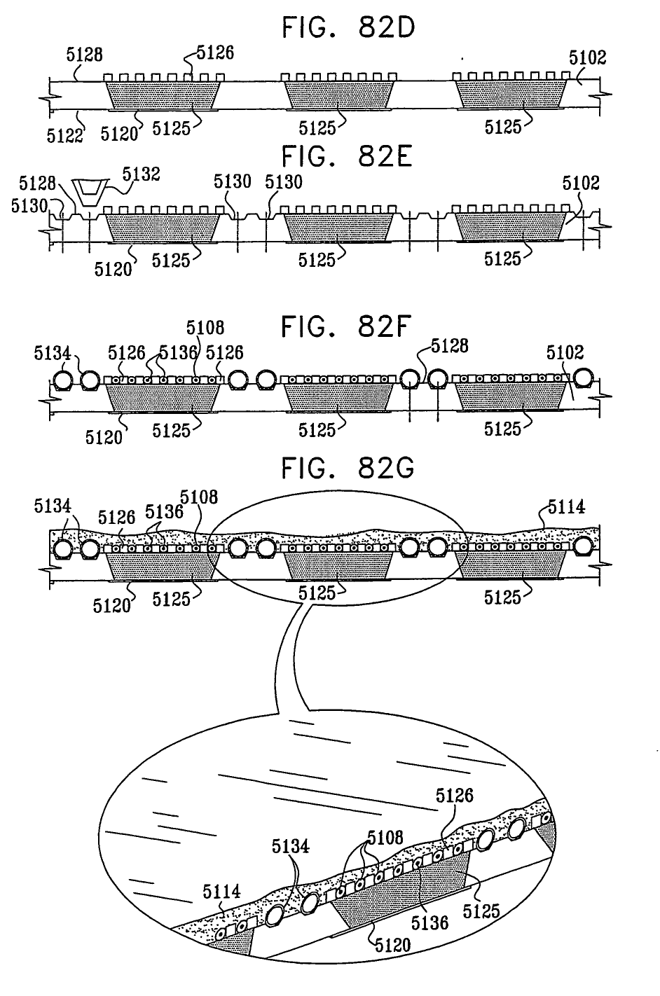

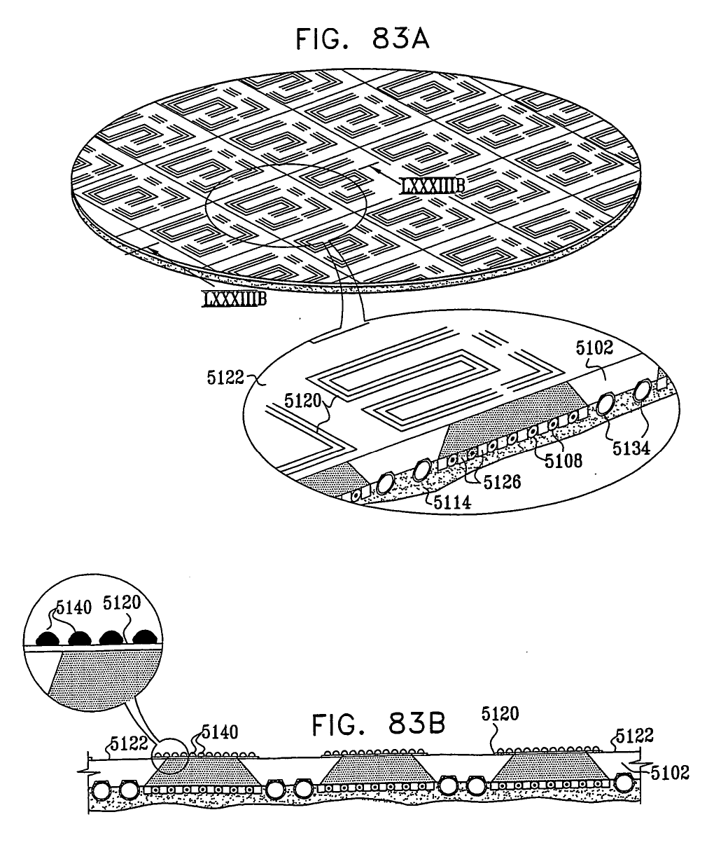

Reference is now made to FIGS. 82A, 82B, 82C, 82D, 82E, 82F and 82G, which are simplified pictorial and sectional illustrations of a plurality of stages in the manufacture of the packaged electro-optic circuit of FIGS. 81A and 81B. Turning to FIG. 82A, it is seen that electrical circuits 5120 are preferably formed onto a first surface 5122 of substrate 5102. Substrate 5102 is preferably of thickness between 200-1000 microns. The electrical circuits 5120 are preferably formed by conventional photolithographic and other thin film techniques employed in the production of CMOS and other integrated circuits.

The substrate shown in FIG. 82A is turned over, as indicated by an arrow 5124, and as shown in FIG. 82B, an array of holes 5125 extending partially or totally through the semiconductor substrate 5102 is formed, such as by conventional photolithographic techniques, on a second surface 5128, opposite surface 5122 of substrate 5102. Following an etching process, the holes are filled with an optical adhesive (not shown), such as OG 146, manufactured by Epoxy Technology, 14 Fortune Drive, Billerica, Mass. 01821, USA, whose refractive index preferably is precisely matched to that of cores of conventionally manufactured optical fibers. This results in an array of optical vias, formed as described hereinabove with reference to FIGS. 63A-63C, through the substrate 5102, which are transparent to light within at least part of the wavelength range of 400-1650 nm.

As shown in FIG. 82C, an array of parallel, spaced, elongate optical fiber positioning elements 5126 is preferably formed, such as by conventional photolithographic techniques, over second surface 5128 of substrate 5102. Turning to FIG. 82D, which is a simplified sectional illustration taken along the lines LXXXIID-LXXXIID in FIG. 82C, it is appreciated that the positions of the arrays of optical adhesive filled holes 5125 and positioning elements 5126 on surface 5128 are preferably precisely coordinated with the positions of the electrical circuits 5120 on first surface 5122 of the substrate 5102.

Turning to FIG. 82E, it is seen that notches 5130 are preferably formed on surface 5128, as by means of a dicing blade 5132, to precisely position and accommodate alignment bore defining cylinders 5134, as shown in FIG. 82F. FIG. 82F illustrates that the centers of alignment bore defining cylinders 5134 preferably lie in the same plane as the centers 5136 of optical fibers 5108 which are precisely positioned between elements 5126 on surface 5128. FIG. 82G illustrates encapsulation of the fibers 5108, the cylinders 5134 and the positioning elements 5126 by layer 5114 of protective material, preferably epoxy.

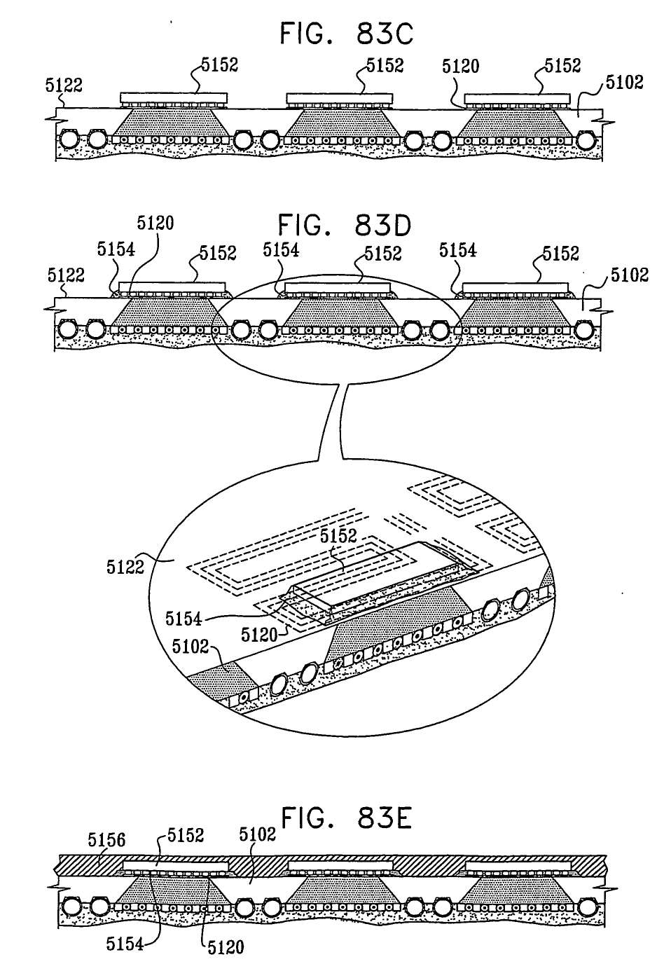

Reference is now made to FIGS. 83A, 83B, 83C, 83D and 83E, which are simplified pictorial and sectional illustrations of a further plurality of stages in the manufacture of the packaged electro-optic circuit of FIGS. 81A and 81B. FIG. 83A shows the wafer of FIG. 82G turned over.

FIG. 83B is a sectional illustration of the wafer of FIG. 83A along lines LXXXIIIB-LXXXIIIB. As shown in FIG. 83B, a multiplicity of bumps 5140, preferably gold or solder bumps, are formed onto electrical circuits 5120 lying on surface 5122.

A plurality of integrated circuits 5152 are mounted onto the multiplicity of bumps 5140 by standard flip chip attachment techniques, as seen in FIG. 83C. Integrated circuits 5152 may be electrical or electro-optic integrated circuits, as appropriate.

FIG. 83D illustrates the application of underfill material 5154, such as OG 146, manufactured by Epoxy Technology, 14 Fortune Drive, Billerica, Mass. 01821, USA, at the gap between integrated circuits 5152 and electrical circuits 5120 as well as substrate 5102. If integrated circuits 5152 include electro-optic devices, the underfill material 5154 should be transparent as appropriate.

As shown in FIG. 83E, an encapsulation layer 5156, such as a layer of BCB or solder mask or other encapsulating material, is preferably formed over integrated circuits 5152, electrical circuits 5120, substrate 5102 and underfill material 5154.

For the purposes of the following discussion, it is assumed that at least some, if not all, of the integrated circuits 5152 are electro-optic devices. It is appreciated that additional integrated circuits (not shown), which are not electro-optic devices, may be electrically connected to the electrical circuits 5120 on substrate 5102 either by flip chip or by other techniques, such as wire bonding.

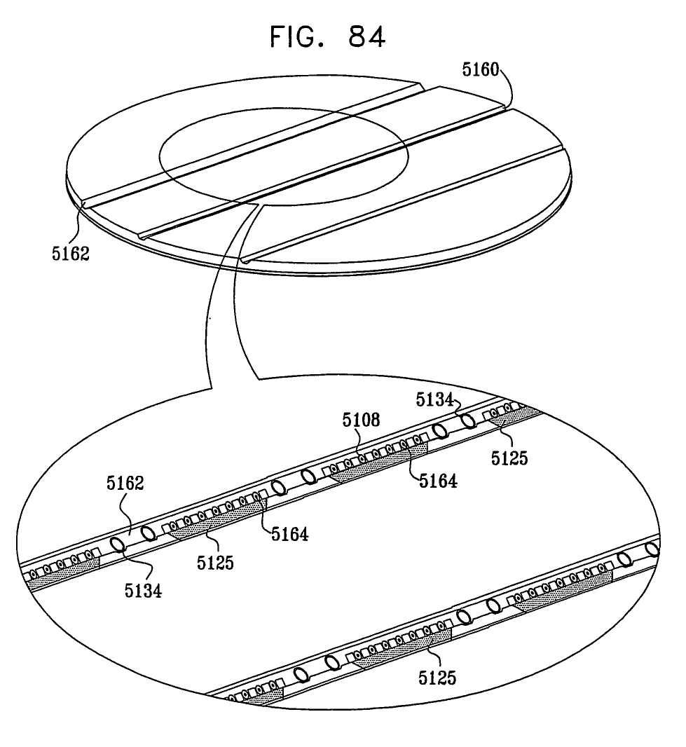

Reference is now made to FIG. 84 which is a simplified pictorial illustration corresponding to sectional illustration 68B.

FIG. 84 illustrates the wafer of FIG. 83E, turned over and notched along lines extending perpendicularly to the array of optical fibers 5108, producing notches 5160, which have an inclined cut 5162, extending entirely through at least a core 5164 of each fiber 5108 and extending at least partially through cylindrical elements 5134 and optical adhesive filled holes 5125.

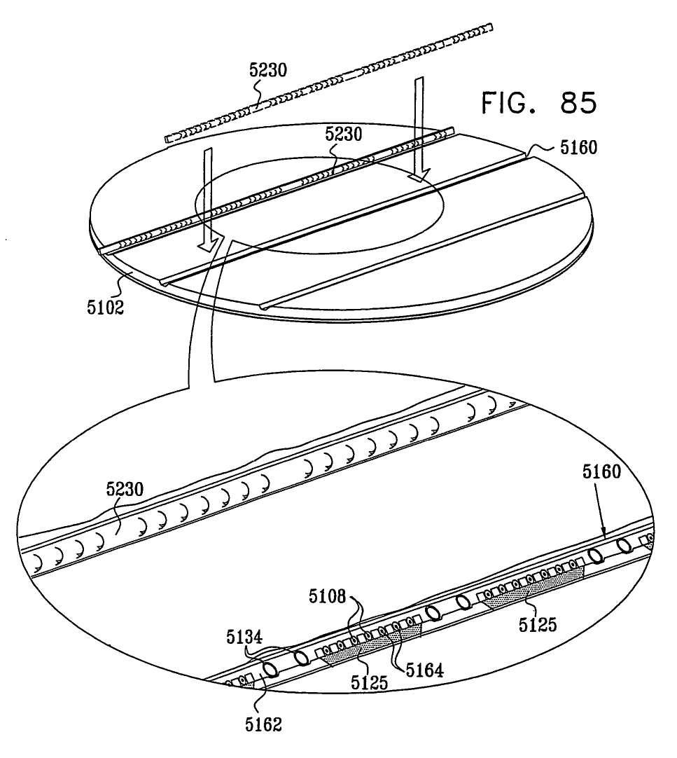

Reference is now made to FIG. 85, which is a simplified pictorial illustration corresponding to sectional illustrations of FIGS. 68C, 68D and 70. FIG. 85 illustrates the wafer of FIG. 84, with partially flat and partially concave mirror assembly 5230 mounted thereon, parallel to one of the inclined cuts 5162 defined by notch 5160, as described hereinabove with reference to FIG. 84. It is appreciated that mirror assembly 5230 extends along the entire length of substrate 5102.

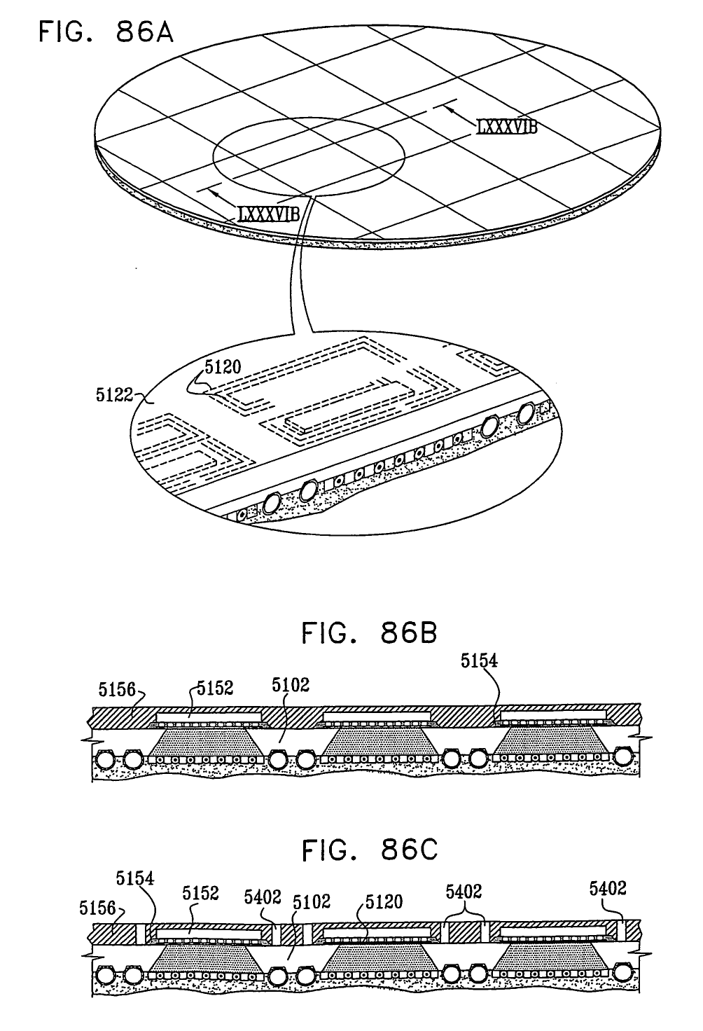

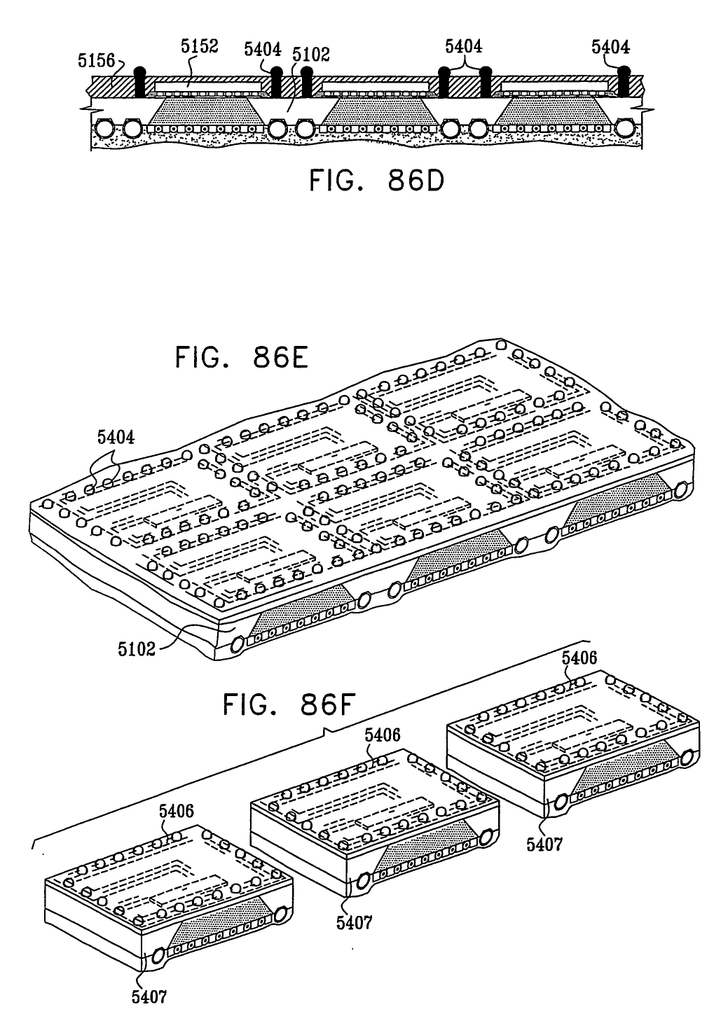

Reference is now made to FIGS. 86A, 86B, 86C, 86D, 86E and 86F, which are simplified pictorial and sectional illustrations of a further plurality of stages in the manufacture of the packaged electro-optic circuit of FIGS. 81A and 81B. FIG. 86A shows the wafer of FIG. 85 turned over. FIG. 86B is a sectional illustration of the wafer of FIG. 86A along lines LXXXVIB-LXXXVIB. FIG. 86C illustrates the formation of holes 5402 by conventional techniques, such as the use of lasers or photolithography, which communicate through layer 5156 with electrical circuits 5120 on substrate 5102. FIG. 86D shows the formation of solder bumps 5404 in holes 5402.

Following the formation of solder bumps 5404 in holes 5402, the wafer, a section of which is shown in FIG. 86E, is preferably diced, providing a plurality of packaged electro-optic circuit chips 5406, as illustrated in FIG. 86F. Following dicing of substrate 5102 into a plurality of packaged electro-optic circuit chips 5406, an optical edge surface 5407 of each of the plurality of packaged electro-optic circuit chips 5406 is polished to provide an optical quality planar surface. It is appreciated that the planar surface defined by the polishing may be either parallel to the plane defined by the dicing, or at any suitable angle.

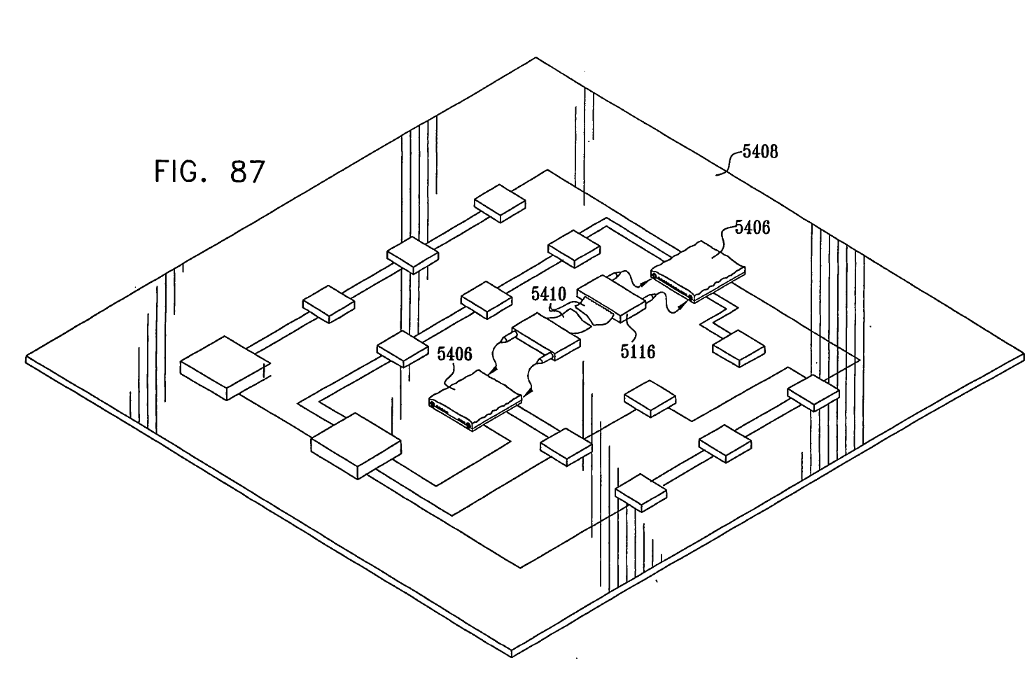

Reference is now made to FIG. 87, which shows packaged electro-optic integrated circuit chips 5406 mounted on a conventional electrical circuit board 5408 and being interconnected by a conventional optical fiber ribbon 5410 and associated conventional optical fiber connectors 5116.

It will be appreciated by persons skilled in the art that the present invention is not limited by what has been particularly shown and described hereinabove. Rather the scope of the present invention includes both combinations and sub combinations of the various features described hereinabove as well as variations and modifications which would occur to persons skilled in the art upon reading the specification and which are not in the prior art.

1. An electro-optic integrated circuit comprising:
an integrated circuit substrate;
at least one optical signal providing element; and
at least one discrete reflecting optical element, mounted onto said integrated circuit substrate, cooperating with said at least one optical signal providing element and being operative to direct light from said at least one optical signal providing element.

2. An electro-optic integrated circuit comprising:
an integrated circuit substrate;
at least one optical signal receiving element; and
at least one discrete reflecting optical element mounted onto said integrated circuit substrate and cooperating with said at least one optical signal receiving element and being operative to direct light to said at least one optical signal receiving element.

3. An electro-optic integrated circuit comprising:
an integrated circuit substrate defining a planar surface;
at least one optical signal providing element; and
at least one reflecting optical element having an optical axis which is neither parallel nor perpendicular to said planar surface, said element cooperating with said at least one optical signal providing element and being operative to direct light from said at least one optical signal providing element.

4. An electro-optic integrated circuit according to claim 3 and wherein said at least one reflecting optical element includes a flat reflective surface.

5. An electro-optic integrated circuit according to claim 3 and wherein said at least one reflecting optical element includes a concave mirror.

6. An electro-optic integrated circuit according to claim 3 and wherein said at least one reflecting optical element includes a partially flat and partially concave mirror.

7. An electro-optic integrated circuit according to claim 6 and wherein said partially concave mirror includes a mirror with multiple concave reflective surfaces.

8. An electro-optic integrated circuit according to claim 3 and wherein said at least one reflecting optical element includes reflective elements formed on opposite surfaces of an optical substrate.

9. An electro-optic integrated circuit according to claim 8 and wherein at least one of said reflective elements includes a flat reflective surface.

10. An electro-optic integrated circuit according to claim 8 and wherein at least one of said reflective elements includes a concave mirror.

11. An electro-optic integrated circuit according to claim 8 and wherein at least one of said reflective elements includes a partially flat and partially concave mirror.

12. An electro-optic integrated circuit according to claim 11 and wherein said partially concave mirror includes a mirror with multiple concave reflective surfaces.

13. An electro-optic integrated circuit according to claim 3 and wherein said at least one reflecting optical element is operative to focus light received from said at least one optical signal providing element.

14. An electro-optic integrated circuit according to claim 3 and wherein said at least one reflecting optical element is operative to collimate light received from said at least one optical signal providing element.

15. An electro-optic integrated circuit according to claim 3 and wherein said at least one reflecting optical element is operative to collimate at least one of multiple colors of light received from said at least one optical signal providing element.

16. An electro-optic integrated circuit according to claim 3 and wherein said at least one optical signal providing element comprises an optical fiber.

17. An electro-optic integrated circuit according to claim 3 and wherein said at least one optical signal providing element comprises a laser diode.

18. An electro-optic integrated circuit according to claim 3 and wherein said at least one optical signal providing element comprises a waveguide.

19. An electro-optic integrated circuit according to claim 3 and wherein said at least one optical signal providing element is operative to convert an electrical signal to an optical signal.

20. An electro-optic integrated circuit according to claim 3 and wherein said at least one optical signal providing element is operative to transmit an optical signal.

21. An electro-optic integrated circuit according to claim 3 and wherein said at least one optical signal providing element also comprises an optical signal receiving element.

22. An electro-optic integrated circuit according to claim 3 and wherein said at least one optical signal providing element is operative to generate an optical signal.

23. An electro-optic integrated circuit according to claim 3 and also comprising at least one optical signal receiving element, said at least one reflecting optical element cooperating with said at least one optical signal receiving element and being operative to direct light to said at least one optical signal receiving element.

24. An electro-optic integrated circuit according to claim 23 and wherein said at least one optical signal receiving element comprises an optical fiber.

25. An electro-optic integrated circuit according to claim 23 and wherein said at least one optical signal receiving element comprises a diode detector.

26. An electro-optic integrated circuit according to claim 23 and wherein said at least one optical signal receiving element is operative to convert an optical signal to an electrical signal.

27. An electro-optic integrated circuit according to claim 23 and wherein said at least one optical signal receiving element is operative to transmit an optical signal.

28. An electro-optic integrated circuit according to claim 23 and wherein said at least one optical signal receiving element also comprises an optical signal providing element.

29. An electro-optic integrated circuit comprising:
an integrated circuit substrate defining a planar surface;
at least one optical signal receiving element; and
at least one reflecting optical element having an optical axis which is neither parallel nor perpendicular to said planar surface, said element cooperating with said at least one optical signal receiving element and being operative to direct light to said at least one optical signal receiving element.

30. An electro-optic integrated circuit according to claim 29 and wherein said at least one reflecting optical element includes a reflective grating.

31. An electro-optic integrated circuit according to claim 29 and wherein said at least one reflecting optical element includes reflective elements formed on opposite surfaces of an optical substrate.

32. An electro-optic integrated circuit according to claim 31 and wherein at least one of said reflective elements includes a reflective grating.

33. An electro-optic integrated circuit according to claim 29 and wherein said at least one reflecting optical element is operative to focus light received by said at least one optical signal receiving element.

34. An electro-optic integrated circuit according to claim 29 and wherein said at least one reflecting optical element is operative to focus at least one of multiple colors of light received by said at least one optical signal receiving element.

35. An electro-optic integrated circuit according to claim 29 and wherein said at least one optical signal receiving element comprises an optical fiber.

36. An electro-optic integrated circuit according to claim 29 and wherein said at least one optical signal receiving element is operative to convert an optical signal to an electrical signal.

37. A method for producing an electro-optic integrated circuit comprising:
providing an integrated circuit substrate;
mounting at least one optical signal providing element onto said integrated circuit substrate;
mounting at least one optical signal receiving element onto said integrated circuit substrate; and
providing optical alignment, between said at least one optical signal providing element and said at least one optical signal receiving element, subsequent to mounting thereof, by suitably positioning along an optical path extending therebetween, at least one intermediate optical element and fixing said at least one intermediate optical element to said integrated circuit substrate.

38. A method for producing an electro-optic integrated circuit according to claim 37 and wherein said at least one intermediate optical element includes a flat reflective surface.

39. A method for producing an electro-optic integrated circuit according to claim 37 and wherein said at least one intermediate optical element includes a concave mirror.

40. A method for producing an electro-optic integrated circuit according to claim 37 and wherein said at least one intermediate optical element includes a partially flat and partially concave mirror.

41. A method for producing an electro-optic integrated circuit according to claim 40 and wherein said partially concave mirror includes a mirror with multiple concave reflective surfaces.

42. A method for producing an electro-optic integrated circuit according to claim 37 and wherein said at least one intermediate optical element includes a reflective grating.

43. A method for producing an electro-optic integrated circuit according to claim 37 and wherein said at least one intermediate optical element includes reflective elements formed on opposite surfaces of an optical substrate.

44. A method for producing an electro-optic integrated circuit according to claim 37 and wherein said at least one intermediate optical element is operative to focus light received from said at least one optical signal providing element by said at least one optical signal receiving element.

45. A method for producing an electro-optic integrated circuit according to claim 37 and wherein said at least one intermediate optical element is operative to collimate light received from said at least one optical signal providing element by said at least one optical signal receiving element.

46. A method for producing an electro-optic integrated circuit according to claim 37 and wherein said at least one intermediate optical element is operative to focus at least one of multiple colors of light received from said at least one optical signal providing element by said at least one optical signal receiving element.

47. A method for producing an electro-optic integrated circuit according to claim 37 and wherein said at least one intermediate optical element is operative to collimate at least one of multiple colors of light received from said at least one optical signal providing element by said at least one optical signal receiving element.

48. A method for producing an electro-optic integrated circuit according to claim 37 and wherein said at least one optical signal providing element is operative to convert an electrical signal to an optical signal.

49. A method for producing an electro-optic integrated circuit according to claim 37 and wherein said at least one optical signal providing element is operative to transmit an optical signal.

50. A method for producing an electro-optic integrated circuit according to claim 37 and wherein said at least one optical signal providing element also comprises an optical signal receiving element.

51. A method for producing an electro-optic integrated circuit according to claim 37 and wherein said at least one optical signal providing element is operative to generate an optical signal.

52. A method for producing an electro-optic integrated circuit according to claim 37 and wherein said at least one optical signal receiving element is operative to convert an optical signal to an electrical signal.

53. A method for producing an electro-optic integrated circuit according to claim 37 and wherein said at least one optical signal receiving element is operative to transmit an optical signal.

54. A method for producing an electro-optic integrated circuit according to claim 37 and wherein said at least one intermediate optical element, when fixed to said substrate, has an optical axis which is neither parallel nor perpendicular to a planar surface of said integrated circuit substrate.

55. A method for producing an electro-optic integrated circuit comprising:
providing an integrated circuit substrate;
mounting at least one optical signal providing element on said integrated circuit substrate; and
mounting at least one discrete reflecting optical element onto said integrated circuit substrate to cooperate with said at least one optical signal providing element and to direct light from said at least one optical signal providing element.

56. A method for producing an electro-optic integrated circuit comprising:
providing an integrated circuit substrate;
mounting at least one optical signal receiving element on said integrated circuit substrate; and
mounting at least one discrete reflecting optical element onto said integrated circuit substrate to cooperate with said at least one optical signal receiving element and to direct light to said at least one optical signal receiving element.

57. A method for producing an electro-optic integrated circuit comprising:
providing an integrated circuit substrate defining a planar surface;
mounting at least one optical signal providing element on said integrated circuit substrate; and
mounting at least one reflecting optical element onto said integrated circuit substrate to cooperate with said at least one optical signal providing element and to direct light from said at least one optical signal providing element,
wherein an optical axis of said at least one reflecting optical element is neither parallel nor perpendicular to said planar surface.

58. A method for producing an electro-optic integrated circuit according to claim 57 and wherein said at least one reflecting optical element includes a flat reflective surface.

59. A method for producing an electro-optic integrated circuit according to claim 57 and wherein said at least one reflecting optical element includes a concave mirror.

60. A method for producing an electro-optic integrated circuit according to claim 57 and wherein said at least one reflecting optical element includes a partially flat and partially concave mirror.

61. A method for producing an electro-optic integrated circuit according to claim 60 and wherein said partially concave mirror includes a mirror with multiple concave reflective surfaces.

62. A method for producing an electro-optic integrated circuit according to claim 57 and wherein said at least one reflecting optical element includes a reflective grating.

63. A method for producing an electro-optic integrated circuit according to claim 57 and wherein said at least one reflecting optical element includes reflective elements formed on opposite surfaces of an optical substrate.

64. A method for producing an electro-optic integrated circuit according to claim 63 and wherein at least one of said reflective elements includes a flat reflective surface.

65. A method for producing an electro-optic integrated circuit according to claim 63 and wherein at least one of said reflective elements includes a concave mirror.

66. A method for producing an electro-optic integrated circuit according to claim 63 and wherein at least one of said reflective elements includes a partially flat and partially concave mirror.

67. A method for producing an electro-optic integrated circuit according to claim 66 and wherein said partially concave mirror includes a mirror with multiple concave reflective surfaces.

68. A method for producing an electro-optic integrated circuit according to claim 57 and wherein said at least one reflecting optical element is operative to focus light received from said at least one optical signal providing element.

69. A method for producing an electro-optic integrated circuit according to claim 57 and wherein said at least one reflecting optical element is operative to collimate light received from said at least one optical signal providing element.

70. A method for producing an electro-optic integrated circuit according to claim 57 and wherein said at least one reflecting optical element is operative to collimate at least one of multiple colors of light received from said at least one optical signal providing element.

71. A method for producing an electro-optic integrated circuit according to claim 57 and wherein said at least one optical signal providing element comprises an optical fiber.

72. A method for producing an electro-optic integrated circuit according to claim 57 and wherein said at least one optical signal providing element comprises a laser diode.

73. A method for producing an electro-optic integrated circuit according to claim 57 and wherein said at least one optical signal providing element comprises a waveguide.

74. A method for producing an electro-optic integrated circuit according to claim 57 and wherein said at least one optical signal providing element is operative to convert an electrical signal to an optical signal.

75. A method for producing an electro-optic integrated circuit according to claim 57 and wherein said at least one optical signal providing element is operative to transmit an optical signal.

76. A method for producing an electro-optic integrated circuit according to claim 57 and wherein said at least one optical signal providing element also comprises an optical signal receiving element.

77. A method for producing an electro-optic integrated circuit according to claim 57 and wherein said at least one optical signal providing element is operative to generate an optical signal.

78. A method for producing an electro-optic integrated circuit according to claim 57 and also comprising mounting at least one optical signal receiving element on said integrated circuit substrate, said at least one reflecting optical element cooperating with said at least one optical signal receiving element and being operative to direct light to said at least one optical signal receiving element.

79. A method for producing an electro-optic integrated circuit according to claim 78 and wherein said at least one optical signal receiving element comprises an optical fiber.

80. A method for producing an electro-optic integrated circuit according to claim 78 and wherein said at least one optical signal receiving element comprises a diode detector.

81. A method for producing an electro-optic integrated circuit according to claim 78 and wherein said at least one optical signal receiving element is operative to convert an optical signal to an electrical signal.

82. A method for producing an electro-optic integrated circuit according to claim 78 and wherein said at least one optical signal receiving element is operative to transmit an optical signal.

83. A method for producing an electro-optic integrated circuit according to claim 78 and wherein said at least one optical signal receiving element also comprises an optical signal providing element.

84. A method for producing an electro-optic integrated circuit comprising:
providing an integrated circuit substrate defining a planar surface;
mounting at least one optical signal receiving element on said integrated circuit substrate; and
mounting at least one reflecting optical element onto said integrated circuit substrate to cooperate with said at least one optical signal receiving element and to direct light to said at least one optical signal receiving element,
wherein an optical axis of said at least one reflecting optical element is neither parallel nor perpendicular to said planar surface.

85. A method for producing an electro-optic integrated circuit according to claim 84 and wherein said at least one reflecting optical element includes a reflective grating.

86. A method for producing an electro-optic integrated circuit according to claim 84 and wherein said at least one reflecting optical element includes reflective elements formed on opposite surfaces of an optical substrate.

87. A method for producing an electro-optic integrated circuit according to claim 86 and wherein at least one of said reflective elements includes a reflective grating.

88. A method for producing an electro-optic integrated circuit according to claim 84 and wherein said at least one reflecting optical element is operative to focus light received by said at least one optical signal receiving element.

89. A method for producing an electro-optic integrated circuit according to claim 84 and wherein said at least one reflecting optical element is operative to focus at least one of multiple colors of light received by said at least one optical signal receiving element.

90. A method for producing an electro-optic integrated circuit according to claim 84 and wherein said at least one optical signal receiving element comprises an optical fiber.

91. A method for producing an electro-optic integrated circuit according to claim 84 and wherein said at least one optical signal receiving element is operative to convert an optical signal to an electrical signal.

92. An integrated circuit comprising:
a first integrated circuit substrate having first and second planar surfaces, said first planar surface having first electrical circuitry formed thereon and said second planar surface having formed therein at least one recess; and
at least one second integrated circuit substrate having second electrical circuitry formed thereon, said at least one second integrated circuit substrate being located at least partially in said at least one recess, said second electrical circuitry communicating with said first electrical circuitry.

93. An integrated circuit according to claim 92 and wherein said first electrical circuitry includes electro-optic components.

94. An integrated circuit according to claim 92 and wherein said second electrical circuitry includes electro-optic components.

95. An integrated circuit according to claim 92 and wherein said second electrical circuitry communicating with said first electrical circuitry includes communicating via an optical communication path.

96. An integrated circuit according to claim 95 and wherein said optical communication path includes optical coupling through free space.

97. An integrated circuit comprising:
a first integrated circuit substrate having first and second planar surfaces, said first planar surface having first electrical circuitry formed thereon and said second planar surface having formed therein at least one recess; and
at least one second substrate, said at least one second substrate being located at least partially in said at least one recess, said second substrate containing at least one element communicating with said first electrical circuitry.

98. A method for producing an integrated circuit comprising:
providing a first integrated circuit substrate, with first and second planar surfaces;
forming first electrical circuitry on said first planar surface;
forming at least one recess in said second planar surface;
providing at least one second integrated circuit substrate;
forming second electrical circuitry on said at least one second integrated circuit substrate; and
locating said at least one second integrated circuit substrate at least partially in said at least one recess, said second electrical circuitry communicating with said first electrical circuitry.

99. A method for producing an integrated circuit according to claim 98 and wherein said first electrical circuitry includes electro-optic components.

100. A method for producing an integrated circuit according to claim 98 and wherein said second electrical circuitry includes electro-optic components.

101. A method for producing an integrated circuit according to claim 98 and wherein said second electrical circuitry communicating with said first electrical circuitry includes communicating via an optical communication path.

102. A method for producing an integrated circuit according to claim 101 and wherein said optical communication path includes optical coupling through free space.

103. A method for producing an integrated circuit comprising:
providing a first integrated circuit substrate;
forming first electrical circuitry on said first substrate;
forming at least one recess in said first substrate;
providing at least one second integrated circuit substrate;
forming second electrical circuitry on said at least one second integrated circuit substrate; and
locating said at least one second integrated circuit substrate at least partially in said at least one recess, said second electrical circuitry communicating with said first electrical circuitry.

104. A method for producing an integrated circuit according to claim 103 and wherein said first electrical circuitry includes electro-optic components.

105. A method for producing an integrated circuit according to claim 103 and wherein said second electrical circuitry includes electro-optic components.

106. A method for producing an integrated circuit according to claim 103 and wherein said second electrical circuitry communicating with said first electrical circuitry includes communicating via an optical communication path.

107. A method for producing an integrated circuit according to claim 106 and wherein said optical communication path includes optical coupling through free space.

108. A method for producing an integrated circuit comprising:
providing a first integrated circuit substrate, with first and second planar surfaces;
forming first electrical circuitry on said first planar surface;
forming at least one recess in said second planar surface;
providing at least one second substrate; and
locating said at least one second substrate at least partially in said at least one recess, said second substrate containing at least one element communicating with said first electrical circuitry.

109. An integrated circuit comprising:
a silicon integrated circuit substrate having electrical signal processing circuitry formed thereon and at least one discrete optical element mounted thereon,
said electrical signal processing circuitry including an electrical signal input and an electrical signal output and
said at least one discrete optical element including an optical input and an optical output.

110. An integrated circuit according to claim 109 and wherein said optical element is operative to convert said electrical signal output into said optical input.

111. An integrated circuit according to claim 109 and wherein said electrical signal processing circuitry is operative to convert said optical output into said electrical signal input.

112. An integrated circuit according to claim 109 and wherein said electrical signal processing circuitry and said discrete optical element are located on a single planar surface of said substrate.

113. An integrated circuit according to claim 109 and wherein said electrical signal processing circuitry and said discrete optical element are located on different planar surfaces of said substrate.

114. A method for producing an integrated circuit comprising:
providing a silicon integrated circuit substrate;
forming electrical signal processing circuitry on said substrate; and
mounting at least one discrete optical element on said substrate,
said electrical signal processing circuitry including an electrical signal input and an electrical signal output and
said at least one discrete optical element including an optical input and an optical output.

115. A method for producing an integrated circuit according to claim 114 and wherein said optical element is operative to convert said electrical signal output into said optical input.

116. A method for producing an integrated circuit according to claim 114 and wherein said electrical signal processing circuitry is operative to convert said optical output into said electrical signal input.

117. A method for producing an integrated circuit according to claim 114 and wherein said electrical signal processing circuitry and said discrete optical element are located on a single planar surface of said substrate.

118. A method for producing an integrated circuit according to claim 114 and wherein said electrical signal processing circuitry and said discrete optical element are located on different planar surfaces of said substrate.

119. An optical connector comprising a plurality of optical elements defining at least one optical input path and at least one optical output path, said at least one optical input path and said at least one optical output path being non-coaxial.

120. An optical connector according to claim 119 and wherein at least one of said plurality of optical elements includes a concave mirror.

121. An optical connector according to claim 119 and wherein at least one of said plurality of optical elements includes a mirror with multiple concave reflective surfaces.

122. An optical connector according to claim 119 and wherein at least one of said plurality of optical elements includes a reflective grating.

123. An optical connector according to claim 119 and wherein at least one of said plurality of optical elements includes reflective elements formed on opposite surfaces of an optical substrate.

124. An optical connector according to claim 119 and wherein at least one of said plurality of optical elements is operative to focus light.

125. An optical connector according to claim 119 and wherein at least one of said plurality of optical elements is operative to collimate light.

126. An optical connector according to claim 119 and wherein at least one of said plurality of optical elements is operative to focus at least one of multiple colors of light.

127. An optical connector according to claim 119 and wherein at least one of said plurality of optical elements is operative to collimate at least one of multiple colors of light.

128. A method for producing an optical connector comprising:
providing a plurality of optical elements;
defining at least one optical input path through at least one of said plurality of optical elements; and
defining at least one optical output path through at least one of said plurality of optical elements,
said at least one optical input path and said at least one optical output path being non-coaxial.

129. A method for producing an optical connector according to claim 128 and wherein at least one of said plurality of optical elements includes a concave mirror.

130. A method for producing an optical connector according to claim 128 and wherein at least one of said plurality of optical elements includes a mirror with multiple concave reflective surfaces.

131. A method for producing an optical connector according to claim 128 and wherein at least one of said plurality of optical elements includes a reflective grating.

132. A method for producing an optical connector according to claim 128 and wherein at least one of said plurality of optical elements includes reflective elements formed on opposite surfaces of an optical substrate.

133. A method for producing an optical connector according to claim 128 and wherein at least one of said plurality of optical elements is operative to focus light.

134. A method for producing an optical connector according to claim 128 and wherein at least one of said plurality of optical elements is operative to collimate light.

135. A method for producing an optical connector according to claim 128 and wherein at least one of said plurality of optical elements is operative to focus at least one of multiple colors of light.

136. A method for producing an optical connector according to claim 128 and wherein at least one of said plurality of optical elements is operative to collimate at least one of multiple colors of light.

137. An optical reflector comprising:
an optical substrate;
at least one microlens formed on a surface of said optical substrate; and
a first reflective surface formed over said at least one microlens.

138. An optical reflector according to claim 137 and wherein said first reflective surface is also formed over at least a portion of said surface of said optical substrate.

139. An optical reflector according to claim 137 and also comprising at least one second reflective surface formed on at least a portion of an opposite surface of said substrate.

140. An optical reflector according to claim 137 and wherein at least a portion of said first reflective surface comprises a grating.

141. An optical reflector according to claim 139 and wherein at least a portion of said second reflective surface comprises a grating.

142. An optical reflector according to claim 137 and also comprising a notch formed in said opposite surface of said substrate.

143. An optical reflector according to claim 139 and also comprising a notch formed in said opposite surface of said substrate.

144. An optical reflector according to claim 137 and wherein said at least one microlens is formed by photolithography and thermal reflow forming.

145. An optical reflector according to claim 137 and wherein said at least one microlens is formed by photolithography using a grey scale mask forming.

146. An optical reflector according to claim 137 and wherein said at least one microlens is formed by jet printing formation.

147. An optical reflector according to claim 137 and wherein said at least one microlens has an index of refraction which closely approximates that of said optical substrate.

148. A method for producing an optical reflector comprising:
providing an optical substrate;
forming at least one microlens on a surface of said optical substrate;
coating said at least one microlens with a reflective material; and
dicing said substrate.

149. A method for producing an optical reflector according to claim 148 and wherein said coating also comprises coating at least a portion of said surface of said substrate.

150. A method for producing an optical reflector according to claim 148 and also comprising coating at least a portion of an opposite surface of said substrate with a reflective material prior to dicing said substrate.

151. A method for producing an optical reflector according to claim 148 and also comprising forming a grating on at least a portion of said surface prior to coating thereof.

152. A method for producing an optical reflector according to claim 150 and also comprising forming a grating on at least a portion of said opposite surface prior to coating thereof.

153. A method for producing an optical reflector according to claim 148 and also comprising forming a notch in an opposite surface of said substrate prior to dicing said substrate.

154. A method for producing an optical reflector according to claim 150 and also comprising forming a notch in an opposite surface of said substrate prior to dicing said substrate.

155. A method for producing an optical reflector according to claim 148 and wherein said forming comprises photolithography and thermal reflow forming.

156. A method for producing an optical reflector according to claim 148 and wherein said forming comprises photolithography using a grey scale mask forming.

157. A method for producing an optical reflector according to claim 148 and wherein said forming comprises jet printing formation.

158. A method for producing an optical reflector according to claim 148 and wherein said at least one microlens has an index of refraction which closely approximates that of said optical substrate.

159. A packaged electro-optical integrated circuit having integrally formed therein an optical connector to an optical fiber.

160. A packaged electro-optical integrated circuit according to claim 159 and wherein said optical connector comprises a pair of elongate locating pin sockets formed over a silicon substrate of said integrated circuit, and extending generally parallel to a surface thereof.

161. A packaged electro-optical integrated circuit according to either of claims 159 and 160 and wherein said optical connector comprises a linear array of optical fiber ends arranged to have abutment surfaces generally coplanar with an edge of said packaged electro-optical integrated circuit.

162. A method for wafer scale production of an electro-optic circuit having integrally formed therein an optical connector and electrical connections comprising:
wafer scale formation of a multiplicity of electro-optical circuits onto a substrate;
wafer scale provision of at least one optical waveguide on said substrate;
wafer scale mounting of at least one integrated circuit component onto said substrate;
wafer scale formation of at least one optical pathway providing an optical connection between said at least one integrated circuit component and said at least one optical waveguide;
wafer scale formation of at least one mechanical alignment bore on said substrate;
wafer scale formation of at least one packaging layer over at least one surface of said substrate; and
thereafter, dicing of said substrate to define a multiplicity of electro-optic circuits, each having integrally formed therein an optical connector.

163. A method according to claim 162 and wherein an end of said at least one optical waveguide defines an optical connector interface.

164. A method for wafer scale production of an electro-optical circuit according to claim 162 and wherein said substrate comprises a silicon substrate having formed thereon a multiplicity of integrated circuits.

165. A method of mounting an integrated circuit onto an electrical circuit comprising:
forming an integrated circuit with a multiplicity of electrical connection pads which generally lie along a mounting surface of the integrated circuit;
forming an electrical circuit with a multiplicity of electrical connection contacts which generally protrude from a mounting surface of the electrical circuit; and
employing at least a conductive adhesive to electrically and mechanically join said multiplicity of electrical connection pads to said multiplicity of electrical connection contacts.

166. A method according to claim 165 wherein said integrated circuit is an electro-optical circuit, and the method also comprises providing an optically transparent underfill layer intermediate said mounting surface of said integrated circuit and said mounting surface of said electrical circuit.

167. A method for wafer scale production of an electro-optical circuit comprising:
wafer scale formation of a multiplicity of electro-optical circuits onto an active surface of a substrate; and
wafer scale provision of at least one optical via on said substrate.

168. A method for wafer scale production of an electro-optical circuit according to claim 167 and wherein said wafer scale provision of said at least one optical via comprises:
etching said substrate on a non-active surface thereof at a location opposite a region of said active surface generally free of circuitry, thereby to define at least one cavity whose bottom surface is translucent; and
filling said at least one cavity with a transparent material.

169. A method for wafer scale production of an electro-optical circuit according to either of claims 167 and 168 and also comprising attaching a semiconductor element in optical engagement with said at least one optical via.

170. A method for wafer scale production of an electro-optical circuit according to claim 168 and wherein said transparent material has an index of refraction similar to that employed along at least one optical path in said electro-optical circuit communicating therewith.

171. A method for wafer level production of a electro-optical circuit comprising:
forming electrical circuitry on a first side of a wafer;
forming an optical assembly on a second side of said wafer; and
forming an optical connection between said first and second sides of said wafer, through said wafer, thereby providing optical communication between said electrical circuitry and said optical assembly through said wafer.

172. A method for wafer level production of an electro-optical circuit according to claim 171 and also comprising dicing said wafer to define a multiplicity of integrated circuits each having formed thereon electrical circuitry on a first side of said integrated circuit, an optical assembly on a second side of said integrated circuit and an optical connection between said first and second sides of said integrated circuit, thereby providing optical communication between said electrical circuitry and said optical assembly.
